(19) United States
(12) Patent Application Publication
(10) Pub. No.: US 2025/0060622 A1
(43) Pub. Date: Feb. 20, 2025

(54) OPTICAL FILM AND VIEWING ANGLE CONTROL SYSTEM

(71) Applicant: FUJIFILM Corporation, Tokyo (JP)

(72) Inventor: Eiichiro AMINAKA, Kanagawa (JP)

(73) Assignee: FUJIFILM Corporation, Tokyo (JP)

(21) Appl. No.: 18/823,141

(22) Filed: Sep. 3, 2024

Related U.S. Application Data
(63) Continuation of application No. PCT/JP2023/009002, filed on Mar. 9, 2023.

(30) Foreign Application Priority Data
Mar. 15, 2022 (JP) 2022-039885

(51) Int. Cl. G02F 1/13; G02B 27/01; G02F 1/13363

(52) U.S. Cl. CPC G02F 1/1323; G02F 1/13363; G02B 27/017; G02B 27/0172; G02B 2027/0178

(57) ABSTRACT

An optical film includes light absorption anisotropic layers containing a dichroic substance, and at least one interlayer disposed between the light absorption anisotropic layers, in which all of the light absorption anisotropic layers have an absorption axis parallel to a thickness direction, thicknesses of the light absorption anisotropic layers are all 3.0 μm or less, a total thickness of the light absorption anisotropic layers is 4.0 μm or more, a total value calculated by multiplying a ratio of a content of the dichroic substance with respect to a mass of the light absorption anisotropic layer by the thickness of the light absorption anisotropic layer is 1.10 μm or more, and the interlayer is a layer in which an in-plane retardation at a wavelength of 550 nm is 25 nm or less and an absolute value of a thickness-direction retardation at the wavelength of 550 nm is 25 nm or less.

### CROSS-REFERENCE TO RELATED APPLICATIONS

This application is a Continuation of PCT International Application No. PCT/JP2023/009002 filed on Mar. 9, 2023, which was published under PCT Article 21(2) in Japanese, and which claims priority under 35 U.S.C. § 119(a) to Japanese Patent Application No. 2022-039885 filed on Mar. 15, 2022. The above applications are hereby expressly incorporated by reference, in their entirety, into the present application.

### BACKGROUND OF THE INVENTION

### 1. Field of the Invention

The present invention relates to an optical film and a viewing angle control system.

### 2. Description of the Related Art

As an optical filter, an optical film which transmits light from a direction perpendicular to a surface (front direction) and shields light from an oblique direction inclined with respect to the surface has been used.

For example, JP2008-165201A discloses an optical film including a polarizing film on both surfaces of a retardation film, in which the polarizing film includes at least a polarizer, and an absorption axis of the polarizer is aligned substantially perpendicular to a surface of the polarizing film.

In addition, WO2019/054099A discloses an optical film including a first anisotropic absorbing layer, a first retardation layer, and a second anisotropic absorbing layer in this order.

### SUMMARY OF THE INVENTION

As a result of studying a laminate (viewing angle control system) obtained by laminating the optical films disclosed in JP2008-165201A and WO2019/054099A and a polarizer having an absorption axis in an in-plane direction, the present inventor has found that, in a case of being viewed from an angle inclined by 250 from a normal direction of the laminate, a transmittance from a direction (azimuth) in which light is to be shielded may be increased, or colored light leakage may be observed.

An object of the present invention is to provide an optical film in which, in a case of being viewed from an angle inclined by 25° from a normal direction of a laminate in which a polarizer having an absorption axis in an in-plane direction is laminated, a transmittance from a direction in which light is to be shielded is low, and coloration of light leakage can be suppressed, and to provide a viewing angle control system.

As a result of intensive studies to achieve the above-described object, the present inventor has found that, by using an optical film having a plurality of specific light absorption anisotropic layers and an interlayer which satisfies a predetermined retardation, in a case of viewing a laminate in which a polarizer having an absorption axis in an in-plane direction is laminated at an angle inclined by 250 from a normal direction of the laminate, it is possible to reduce a transmittance from a direction in which light is to be shielded and to suppress coloration of light leakage, and has completed the present invention.

That is, the present inventor has found that the above-described objects can be achieved by employing the following configurations.

[1] An optical film comprising:
a plurality of light absorption anisotropic layers containing a dichroic substance; and
at least one interlayer disposed between the plurality of light absorption anisotropic layers,
in which all of the plurality of light absorption anisotropic layers have an absorption axis parallel to a thickness direction,
thicknesses of the plurality of light absorption anisotropic layers are all 3.0 μm or less,
a total thickness of the plurality of light absorption anisotropic layers is 4.0 μm or more,
with regard to the plurality of light absorption anisotropic layers, a total value calculated by multiplying a ratio of a content of the dichroic substance with respect to a mass of the light absorption anisotropic layer by the thickness of the light absorption anisotropic layer is 1.10 μm or more, and
the interlayer is a layer in which an in-plane retardation at a wavelength of 550 nm is 25 nm or less and an absolute value of a thickness-direction retardation at the wavelength of 550 nm is 25 nm or less.

[2] The optical film according to [1],
in which alignment degrees of the plurality of light absorption anisotropic layers are all 0.93 or more.

[3] The optical film according to [1] or [2],
in which the interlayer is an alignment layer or a barrier layer.

[4] A viewing angle control system comprising:
the optical film according to any one of [1] to [3]; and
a polarizer having an absorption axis in an in-plane direction.

[5] An image display device comprising:
a display element; and
the viewing angle control system according to [4],
in which the viewing angle control system is disposed on at least one main surface of the display element.

[6] The image display device according to [5], in which the plurality of light absorption anisotropic layers included in the viewing angle control system are arranged on a viewing side with respect to the polarizer included in the viewing angle control system.

According to the present invention, it is possible to provide an optical film in which, in a case of being viewed from an angle inclined by 250 from a normal direction of a laminate in which a polarizer having an absorption axis in an in-plane direction is laminated, a transmittance from a direction in which light is to be shielded is low, and coloration of light leakage can be suppressed, and to provide a viewing angle control system.

### BRIEF DESCRIPTION OF THE DRAWINGS

FIG. 1 is a schematic view showing an example of a head-mounted display according to the embodiment of the present invention.

FIG. 2 is a schematic diagram showing an example of a configuration of a light guide plate for an augmented reality (AR) glass.

FIG. 3 is a schematic diagram showing a plan view of an evaluation system of the head-mounted display according to the embodiment of the present invention.

### DESCRIPTION OF THE PREFERRED EMBODIMENTS

Hereinafter, the present invention will be described in detail.

The description of configuration requirements described below may be made based on typical embodiments of the present invention, but the present invention is not limited to such embodiments.

Any numerical range expressed using “to” in the present specification refers to a range including the numerical values before and after the “to” as a lower limit value and an upper limit value, respectively.

In addition, in the present specification, substances corresponding to respective components may be used alone or in combination of two or more kinds thereof. Here, in a case where two or more kinds of substances corresponding to respective components are used in combination, the content of the components indicates the total content of the substances used in combination unless otherwise specified.

In addition, in the present specification, “(meth)acrylate” denotes “acrylate” or “methacrylate”, “(meth)acryl” denotes “acryl” or “methacryl”, and “(meth)acryloyl” denotes “acryloyl” or “methacryloyl”.

In addition, in the present specification, concepts of a liquid crystal composition and a liquid crystal compound also include those that no longer exhibit liquid crystallinity due to curing or the like.

In addition, in the present specification, a relationship between angles (for example, “orthogonal”, “parallel”, and the like) is intended to include a range of errors acceptable in the art to which the present invention belongs. Specifically, it means that an angle is within an error range of less than ±100 with respect to the exact angle, and the error with respect to the exact angle is preferably within a range of ±5° or less and more preferably within a range of ±3° or less.

In addition, in the present specification, Re(λ) and Rth(λ) respectively represent an in-plane retardation at a wavelength λ and a thickness-direction retardation at a wavelength λ. Unless otherwise specified, the wavelength λ is 550 nm.

In the present invention, Re(λ) and Rth(λ) are values measured at the wavelength of λ in AxoScan (manufactured by Axometrics, Inc.). By inputting an average refractive index ((nx+ny+nz)/3) and a film thickness (d (μm)) in AxoScan,
Slow axis direction (°)

Re(λ)=R0(λ), and

Rth(λ)=((nx+ny)/2−nz)×d
are calculated.

Although R0 (λ) is displayed as a numerical value calculated by AxoScan, it means Re (λ).

In addition, in the present specification, the refractive indices nx, ny, and nz are measured using an Abbe refractometer (NAR-4T, manufactured by Atago Co., Ltd.) and using a sodium lamp (λ=589 nm) as a light source. In addition, in a case of measuring the wavelength dependence, it can be measured with a multi-wavelength Abbe refractometer DR-M2 (manufactured by Atago Co., Ltd.) in combination with a dichroic filter.

In addition, values in Polymer Handbook (John Wiley & Sons, Inc.) and catalogs of various optical films can be used. The values of the average refractive index of main optical films are exemplified below: cellulose acylate (1.48), cycloolefin polymer (1.52), polycarbonate (1.59), polymethylmethacrylate (1.49), and polystyrene (1.59).

A substituent W used in the present specification represents any of the following groups.

Examples of the substituent W include a halogen atom, an alkyl group having 1 to 20 carbon atoms, a halogenated alkyl group having 1 to 20 carbon atoms, a cycloalkyl group having 1 to 20 carbon atoms, an alkylcarbonyl group having 1 to 10 carbon atoms, an alkyloxycarbonyl group having 1 to 10 carbon atoms, an alkylcarbonyloxy group having 1 to 10 carbon atoms, an alkylamino group having 1 to 10 carbon atoms, an alkylaminocarbonyl group, an alkoxy group having 1 to 20 carbon atoms, an alkenyl group having 1 to 20 carbon atoms, an alkynyl group having 1 to 20 carbon atoms, an aryl group having 1 to 20 carbon atoms, a heterocyclic group (also referred to as a hetero ring group), a cyano group, a hydroxy group, a nitro group, a carboxy group, an aryloxy group, a silyloxy group, a heterocyclic oxy group, an acyloxy group, a carbamoyloxy group, an alkoxycarbonyloxy group, an aryloxycarbonyloxy group, an amino group (including an anilino group), an ammonio group, an acylamino group, an aminocarbonylamino group, an alkoxycarbonylamino group, an aryloxycarbonylamino group, a sulfamoylamino group, an alkyl or arylsulfonylamino group, a mercapto group, an alkylthio group, an arylthio group, a heterocyclic thio group, a sulfamoyl group, a sulfo group, an alkyl or arylsulfinyl group, an alkyl or arylsulfonyl group, an acyl group, an aryloxycarbonyl group, an alkoxycarbonyl group, a carbamoyl group, an aryl or heterocyclic azo group, an imide group, a phosphino group, a phosphinyl group, a phosphinyloxy group, a phosphinylamino group, a phosphono group, a silyl group, a hydrazino group, a ureido group, a boronic acid group (—B(OH)₂), a phosphate group (—OPO(OH)₂), a sulfate group (—OSO₃H), and other known substituents.

Details of the substituent are described in paragraph [0023] of JP2007-234651A.

In addition, the substituent W may be a group represented by Formula (W1).

*-LW-SPW-Q (W1)

In Formula (W1), LW represents a single bond or a divalent linking group, SPW represents a divalent spacer group, Q represents Q1 or Q2 in Formula (LC) described later, and * represents a bonding position.

Examples of the divalent linking group represented by LW include —O—, —(CH₂)_{g}—, —(CF₂)_{g}—, —Si(CH₃)₂—, —(Si(CH₃)₂O)_{g}—, —(OSi(CH₃)₂)_{g}— (g represents an integer of 1 to 10), —N(Z)—, —C(Z)═C(Z′)—, —C(Z)═N—, —N═C(Z)—, —C(Z)₂—C(Z′)₂—, —C(O)—, —OC(O)—, —C(O)O—, —O—C(O)O—, —N(Z)C(O)—, —C(O)N(Z)—, —C(Z)═C(Z′)—C(O)O—, —O—C(O)—C(Z)═C(Z′)—, —C(Z)═N—, —N═C(Z)—, —C(Z)═C(Z′)—C(O)N(Z″)—, —N(Z″)—C(O)—C(Z)═C(Z′)—, —C(Z)═C(Z′)—C(O)—S—, —S—C(O)—C(Z)═C(Z′)—, —C(Z)═N—N═C(Z′)— (Z, Z′, and Z″ independently represent a hydrogen atom, an alkyl group having 1 to 4 carbon atoms, a cycloalkyl group, an aryl group, a cyano group, or a halogen atom), —C≡C—, —N═N—, —S—, —S(O)—, —S(O)(O)—, —(O)S(O)O—, —O(O)S(O)O—, —SC(O)—, and —C(O)S—. LW may be a group in which two or more of these groups are combined (hereinafter, also abbreviated as “L-C”).

Examples of the divalent spacer group represented by SPW include a linear, branched, or cyclic alkylene group having 1 to 50 carbon atoms, and a heterocyclic group having 1 to 20 carbon atoms.

The carbon atom of the above-described alkylene group or the carbon atom of the heterocyclic group may be substituted with —O—, —Si(CH₃)₂—, —(Si(CH₃)₂O)_{g}—, —(OSi(CH₃)₂)_{g}— (g represents an integer of 1 to 10), —N(Z)—, —C(Z)═C(Z′)—, —C(Z)═N—, —N═C(Z)—, —C(Z)₂—C(Z′)₂—, —C(O)—, —OC(O)—, —C(O)O—, —O—C(O)O—, —N(Z)C(O)—, —C(O)N(Z)—, —C(Z)═C(Z′)—C(O)O—, —O—C(O)—C(Z)═C(Z′)—, —C(Z)═N—, —N═C(Z)—, —C(Z)═C(Z′)—C(O)N(Z″)—, —N(Z″)—C(O)—C(Z)═C(Z′)—, —C(Z)═C(Z′)—C(O)—S—, —S—C(O)—C(Z)═C(Z′)—, —C(Z)═N—N═C(Z′)— (Z, Z′, and Z″ independently represent a hydrogen atom, an alkyl group having 1 to 4 carbon atoms, a cycloalkyl group, an aryl group, a cyano group, or a halogen atom), —C═C—, —N═N—, —S—, —C(S)—, —S(O)—, —SO₂—, —(O)S(O)O—, —O(O)S(O)O—, —SC(O)—, —C(O)S—, or a group obtained by combining two or more of these groups (hereinafter, also abbreviated as “SP—C”).

The hydrogen atom of the above-described alkylene group or the hydrogen atom of the heterocyclic group may be substituted with a halogen atom, a cyano group, —Z^{H}, —OH, —OZ^{H}, —COOH, —C(O)Z^{H}, —C(O)OZ^{H}, —OC(O)Z^{H}, —OC(O)OZ^{H}, —NZ^{H}Z^{H}′, —NZ^{H}C(O)Z^{H}′, NZ^{H}C(O)OZ^{H}′, —C(O)NZ^{H}Z^{H}′, —OC(O)NZ^{H}Z^{H}′, —NZ^{H}C(O)NZ^{H}′OZ^{H}″, —SH, —SZ^{H}, —C(S)Z^{H}, —C(O)SZ^{H}, or —SC(O)Z^{H} (hereinafter, also abbreviated as “SP—H”). Here, Z^{H} and Z^{H}′ represent an alkyl group having 1 to 10 carbon atoms, a halogenated alkyl group, or -L-CL (L represents a single bond or a divalent linking group, and specific examples of the divalent linking group are the same as those for LW and SPW described above; CL represents a crosslinkable group, examples thereof include a group represented by Q1 or Q2 in Formula (LC) described later, and a crosslinkable group represented by Formulae (P-1) to (P-30) described later is preferable).

### [Optical Film]

The optical film according to the embodiment of the present invention is an optical film including a plurality of light absorption anisotropic layers containing a dichroic substance, and at least one interlayer disposed between the plurality of light absorption anisotropic layers.

In addition, all of the plurality of light absorption anisotropic layers included in the optical film according to the embodiment of the present invention have an absorption axis parallel to a thickness direction, thicknesses thereof are all 3.0 μm or less, and a total thickness thereof is 4.0 μm or more.

In addition, in the optical film according to the embodiment of the present invention, with regard to the plurality of light absorption anisotropic layers, a total value calculated by multiplying a ratio of a content of the dichroic substance with respect to a mass of the light absorption anisotropic layer (content of dichroic substance/mass of light absorption anisotropic layer) by the thickness of the light absorption anisotropic layer (hereinafter, also abbreviated as “dichroic substance-converted total film thickness”) is 1.10 μm or more.

In addition, the interlayer included in the optical film according to the embodiment of the present invention is a layer in which an in-plane retardation at a wavelength of 550 nm is 25 nm or less and an absolute value of a thickness-direction retardation at the wavelength of 550 nm is 25 nm or less.

In the present invention, as described above, by using the optical film including a plurality of light absorption anisotropic layers having an absorption axis parallel to a thickness direction (hereinafter, abbreviated as “specific light absorption anisotropic layer” in this paragraph), in which a thickness of each layer is 3.0 μm or less, the total thickness is 4.0 μm or more, and the dichroic substance-converted total film thickness is 1.10 μm or more, and an interlayer which satisfies a predetermined retardation, in a case of being viewed from an angle inclined by 25° from a normal direction of a laminate in which a polarizer having an absorption axis in an in-plane direction is laminated, a transmittance from a direction in which light is to be shielded is low, and coloration of light leakage can be suppressed.

The reason why these effects are exhibited is not clear in detail, but the present inventor has presumed as follows.

That is, by including the specific light absorption anisotropic layer, since light shielding properties in a case of being viewed from a predetermined azimuth at an angle inclined by 25° from the normal direction of the laminate in which the polarizer having an absorption axis in the in-plane direction is laminated are improved, it is considered that the transmittance from the direction in which light is to be shielded is low. In addition, by including the specific light absorption anisotropic layer, it is possible to solve problems in a case where a film thickness of a single light absorption anisotropic layer is increased (for example, a decrease in aligning properties, a decrease in in-plane uniformity of optical properties, and the like).

In addition, by including the interlayer which satisfies a predetermined retardation, since the presence of the optically anisotropic layer (retardation layer) using a liquid crystal compound, and the like is excluded, it is considered that the coloration of light leakage can be suppressed.

Hereinafter, the light absorption anisotropic layer and the interlayer included in the optical film according to the embodiment of the present invention will be described in detail.

### [Light Absorption Anisotropic Layer]

The plurality of light absorption anisotropic layers included in the optical film according to the embodiment of the present invention have a thickness of 3.0 μm or less for each layer and a total thickness of 4.0 μm or more, and the light absorption anisotropic layer is a light absorption anisotropic layer having an absorption axis parallel to a thickness direction, in which the dichroic substance-converted total film thickness is 1.10 μm or more.

Here, the thickness of each layer of the light absorption anisotropic layers is preferably 1.0 to 3.0 μm and more preferably 2.0 to 3.0 μm.

In addition, the total thickness of the light absorption anisotropic layers is preferably 4.0 to 20.0 μm and more preferably 8.0 to 20.0 μm.

In addition, the dichroic substance-converted total film thickness of the light absorption anisotropic layer is preferably 1.20 to 5.00 μm and more preferably 2.00 to 5.00 μm.

In the present specification, the thickness of the light absorption anisotropic layer refers to an average value of thicknesses of any three points measured in a case where a cross-sectional sliced sample is produced using a microtome and a scanning electron microscope (SEM) image thereof is observed.

In the present invention, from the reason that the transmittance is further lowered in a case of being viewed from a predetermined azimuthal angle at an angle inclined by 250 from the normal direction of the laminate in which the polarizer having an absorption axis in an in-plane direction is laminated, alignment degrees of the plurality of light absorption anisotropic layers are all preferably 0.90 or more, more preferably 0.93 or more, and still more preferably 0.95 or more.

Here, the alignment degree of the light absorption anisotropic layer is calculated by the following method.

Using AxoScan (manufactured by Axometrics, Inc.), a transmittance of the light absorption anisotropic layer at a wavelength of 550 nm is measured. In a case of the measurement, while changing a polar angle, which is an angle of the light absorption anisotropic layer with respect to a normal direction, from 0° to 60° in 5° increments, the transmittance at the wavelength of 550 nm is measured at all azimuthal angles at each polar angle. Next, after removing influence of surface reflection, a transmittance at the azimuthal angle and the polar angle where the transmittance is the highest is defined as Tm (0), and a transmittance at an angle obtained by tilting the polar angle by 40° from the polar angle of the highest transmittance in the azimuthal direction with the highest transmittance is defined as Tm (40). The absorbance is calculated by the following expression based on the obtained Tm (0) and Tm (40), and A (0) and A (40) are calculated.

$$A = - log ( Tm )$$

Here, Tm represents a transmittance and A represents an absorbance.

An alignment degree S defined by the following expression is calculated based on the calculated A (0) and A (40).

$$S = ( 4.6 \times A ( 40 ) - A ( 0 ) ) / ( 4.6 \times A ( 40 ) + 2 \times A ( 0 ) )$$

In the present invention, the light absorption anisotropic layer is preferably a light absorption anisotropic layer containing a dichroic substance, more preferably a light absorption anisotropic layer containing a dichroic substance and a liquid crystal compound, and still more preferably a layer in which an alignment state of the liquid crystal compound and the dichroic substance is fixed.

Such a light absorption anisotropic layer can be formed from a liquid crystal composition containing a liquid crystal compound and a dichroic substance.

In addition, the liquid crystal composition may contain an alignment agent, a solvent, a polymerization initiator, a polymerizable compound, an interface improver, and other additives. Hereinafter, each component will be described.

### <Liquid Crystal Compound>

The liquid crystal composition contains a liquid crystal compound. By containing the liquid crystal compound, the dichroic substance can be aligned with a high alignment degree while the precipitation of the dichroic substances is suppressed.

In addition, the liquid crystal compound contained in the liquid crystal composition can be typically classified into a rod-like type compound and a disk-like type compound depending on the shape thereof.

In addition, the liquid crystal compound is preferably a liquid crystal compound which does not exhibit dichroism in a visible region.

In the following description, the expression “the alignment degree of the light absorption anisotropic layer to be formed is further increased” is also referred to as “the effect of the present invention is more excellent”.

As the liquid crystal compound, any of a low-molecular-weight low-molecular-weight low-molecular-weight liquid crystal compound or a high-molecular-weight liquid crystal compound can be used.

Here, the “low-molecular-weight liquid crystal compound” refers to a liquid crystal compound having no repeating unit in the chemical structure.

In addition, the “high-molecular-weight liquid crystal compound” refers to a liquid crystal compound having a repeating unit in the chemical structure.

Examples of the low-molecular-weight liquid crystal compound include liquid crystal compounds described in JP2013-228706A.

Examples of the high-molecular-weight liquid crystal compound include thermotropic liquid crystalline polymers described in JP2011-237513A. In addition, the high-molecular-weight liquid crystal compound may include a crosslinkable group (such as an acryloyl group and a methacryloyl group) at a terminal.

From the reason that the effect of the present invention is likely to be realized, the liquid crystal compound is preferably a rod-like liquid crystal compound and more preferably a high-molecular-weight liquid crystal compound.

The liquid crystal compound may be used alone or in combination of two or more kinds thereof.

From the viewpoint that the effect of the present invention is more excellent, the liquid crystal compound preferably includes the high-molecular-weight liquid crystal compound, and particularly preferably includes both the high-molecular-weight liquid crystal compound and the low-molecular-weight liquid crystal compound.

It is preferable that the liquid crystal compound includes a liquid crystal compound represented by Formula (LC), or a polymer thereof. The liquid crystal compound represented by Formula (LC) or the polymer thereof is a compound exhibiting liquid crystallinity. The liquid crystallinity may be a nematic phase or a smectic phase, or the liquid crystal compound may exhibit both the nematic phase and the smectic phase, and it is preferable to exhibit at least the nematic phase.

The smectic phase may be a high-order smectic phase. The high-order smectic phase here denotes a smectic B phase, a smectic D phase, a smectic E phase, a smectic F phase, a smectic G phase, a smectic H phase, a smectic I phase, a smectic J phase, a smectic K phase, or a smectic L phase. Among these, a smectic B phase, a smectic F phase, or a smectic I phase is preferable.

In a case where the smectic liquid crystal phase exhibited by the liquid crystal compound is any of these high-order smectic liquid crystal phases, the light absorption anisotropic layer with a higher alignment degree order can be produced. In addition, the light absorption anisotropic layer produced from such a high-order smectic liquid crystal phase with a high alignment degree order is a layer in which a Bragg peak derived from a high-order structure such as a hexatic phase and a crystal phase in X-ray diffraction measurement is obtained. The above-described Bragg peak is a peak derived from a plane periodic structure of molecular alignment, and according to the liquid crystal composition according to the present invention, a light absorption anisotropic layer having a periodic interval of 3.0 to 5.0 Å can be obtained.

Q1-Si-MG-2-Q2 (LC)

In Formula (LC), Q1 and Q2 each independently represent a hydrogen atom, a halogen atom, a linear, branched, or cyclic alkyl group having 1 to 20 carbon atoms, an alkoxy group having 1 to 20 carbon atoms, an alkenyl group having 1 to 20 carbon atoms, an alkynyl group having 1 to 20 carbon atoms, an aryl group having 1 to 20 carbon atoms, a heterocyclic group (also referred to as a hetero ring group), a cyano group, a hydroxy group, a nitro group, a carboxy group, an aryloxy group, a silyloxy group, a heterocyclic oxy group, an acyloxy group, a carbamoyloxy group, an alkoxycarbonyloxy group, an aryloxycarbonyloxy group, an amino group (including an anilino group), an ammonio group, an acylamino group, an aminocarbonylamino group, an alkoxycarbonylamino group, an aryloxycarbonylamino group, a sulfamoylamino group, an alkyl or arylsulfonylamino group, a mercapto group, an alkylthio group, an arylthio group, a heterocyclic thio group, a sulfamoyl group, a sulfo group, an alkyl or arylsulfinyl group, an alkyl or arylsulfonyl group, an acyl group, an aryloxycarbonyl group, an alkoxycarbonyl group, a carbamoyl group, an aryl or heterocyclic azo group, an imide group, a phosphino group, a phosphinyl group, a phosphinyloxy group, a phosphinylamino group, a phosphono group, a silyl group, a hydrazino group, a ureido group, a boronic acid group (—B(OH)₂), a phosphate group (—OPO(OH)₂), a sulfate group (—OSO₃H), or a crosslinkable group represented by any of Formulae (P-1) to (P-30), and it is preferable that at least one of Q1 or Q2 represents a crosslinkable group represented by any of the following formulae.

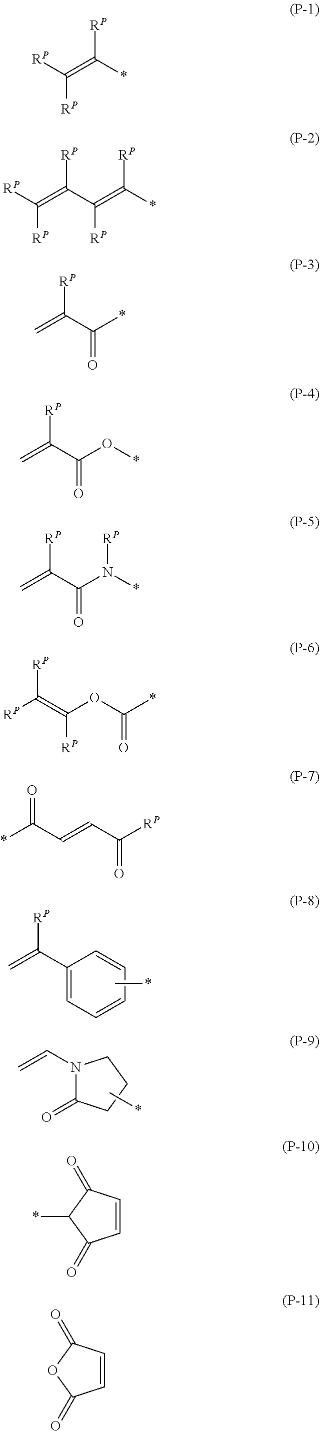

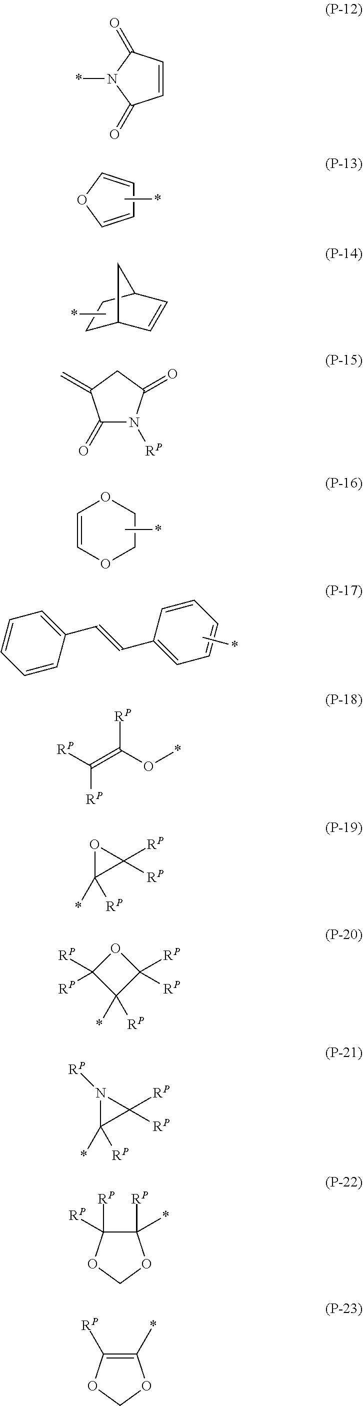

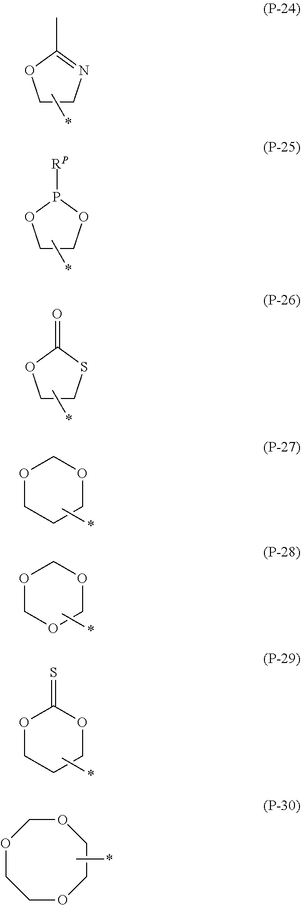

In Formulae (P-1) to (P-30), RP represents a hydrogen atom, a halogen atom, a linear, branched, or cyclic alkylene group having 1 to 10 carbon atoms, a halogenated alkyl group having 1 to 20 carbon atoms, an alkoxy group having 1 to 20 carbon atoms, an alkenyl group having 1 to 20 carbon atoms, an alkynyl group having 1 to 20 carbon atoms, an aryl group having 1 to 20 carbon atoms, a heterocyclic group, a cyano group, a hydroxy group, a nitro group, a carboxy group, an aryloxy group, a silyloxy group, a heterocyclic oxy group, an acyloxy group, a carbamoyloxy group, an alkoxycarbonyloxy group, an aryloxycarbonyloxy group, an amino group (including an anilino group), an ammonio group, an acylamino group, an aminocarbonylamino group, an alkoxycarbonylamino group, an aryloxycarbonylamino group, a sulfamoylamino group, an alkyl or arylsulfonylamino group, a mercapto group, an alkylthio group, an arylthio group, a heterocyclic thio group, a sulfamoyl group, a sulfo group, an alkyl or arylsulfinyl group, an alkyl or arylsulfonyl group, an acyl group, an aryloxycarbonyl group, an alkoxycarbonyl group, a carbamoyl group, an aryl or heterocyclic azo group, an imide group, a phosphino group, a phosphinyl group, a phosphinyloxy group, a phosphinylamino group, a phosphono group, a silyl group, a hydrazino group, a ureido group, a boronic acid group (—B(OH)₂), a phosphate group (—OPO(OH)₂), or a sulfate group (—OSO₃H), and a plurality of RP's may be the same or different from each other.

Examples of a preferred aspect of the crosslinkable group include a radically polymerizable group and a cationically polymerizable group. As the radically polymerizable group, a vinyl group represented by Formula (P-1), a butadiene group represented by Formula (P-2), a (meth)acryloyl group represented by Formula (P-4), a (meth)acrylamide group represented by Formula (P-5), a vinyl acetate group represented by Formula (P-6), a fumaric acid ester group represented by Formula (P-7), a styryl group represented by Formula (P-8), a vinylpyrrolidone group represented by Formula (P-9), a maleic acid anhydride represented by Formula (P-11), or a maleimide group represented by Formula (P-12) is preferable. As the cationically polymerizable group, a vinyl ether group represented by Formula (P-18), an epoxy group represented by Formula (P-19), or an oxetanyl group represented by Formula (P-20) is preferable.

In Formula (LC), S1 and S2 each independently represent a divalent spacer group, and suitable aspects of S1 and S2 include the same structures as those for SPW in Formula (W1), and thus the description thereof will not be repeated.

In Formula (LC), MG represents a mesogen group described below. The mesogen group represented by MG is a group representing a main skeleton of a liquid crystal molecule which contributes to liquid crystal formation. A liquid crystal molecule exhibits liquid crystallinity which is in an intermediate state (mesophase) between a crystal state and an isotropic liquid state. The mesogen group is not particularly limited, and for example, particularly description on pages 7 to 16 of “Flussige Kristalle in Tabellen II” (VEB Deutsche Verlag fur Grundstoff Industrie, Leipzig, 1984) and particularly description in Chapter 3 of “Liquid Crystal Handbook” (Maruzen, 2000) edited by Liquid Crystal Handbook Editing Committee can be referred to.

The mesogen group represented by MG preferably has 2 to 10 cyclic structures and more preferably has 3 to 7 cyclic structures.

Specific examples of the cyclic structure include an aromatic hydrocarbon group, a heterocyclic group, and an alicyclic group.

As the mesogen group represented by MG, from the viewpoint of expressing the liquid crystallinity, adjusting a liquid crystal phase transition temperature, availability of raw materials, and synthetic suitability, and from the viewpoint that the effect of the present invention is more excellent, a group represented by Formula (MG-A) or Formula (MG-B) is preferable, and a group represented by Formula (MG-B) is more preferable.

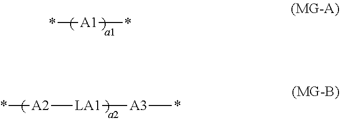

In Formula (MG-A), A1 represents a divalent group selected from the group consisting of an aromatic hydrocarbon group, a heterocyclic group, and an alicyclic group. These groups may be substituted with a substituent such as the above-described substituent W.

It is preferable that the divalent group represented by A1 is a 4- to 15-membered ring. In addition, the divalent group represented by A1 may be a monocyclic ring or a fused ring.

In addition, * represents a bonding position to S1 or S2.

Examples of the divalent aromatic hydrocarbon group represented by A1 include a phenylene group, a naphthylene group, a fluorene-diyl group, an anthracene-diyl group, and a tetracene-diyl group. From the viewpoint of design diversity of the mesogenic skeleton and the availability of raw materials, a phenylene group or a naphthylene group is preferable.

The divalent heterocyclic group represented by A1 may be any of aromatic or non-aromatic, but from the viewpoint of further improving the alignment degree, a divalent aromatic heterocyclic group is preferable.

Examples of atoms other than carbon, constituting the divalent aromatic heterocyclic group, include a nitrogen atom, a sulfur atom, and an oxygen atom. In a case where the aromatic heterocyclic group has a plurality of atoms other than carbon, constituting a ring, these atoms may be the same or different from each other.

Specific examples of the divalent aromatic heterocyclic group include a pyridylene group (pyridine-diyl group), a pyridazine-diyl group, an imidazole-diyl group, a thienylene group (thiophene-diyl group), a quinolylene group (quinoline-diyl group), an isoquinolylene group (isoquinoline-diyl group), an oxazole-diyl group, a thiazole-diyl group, an oxadiazole-diyl group, a benzothiazole-diyl group, a benzothiadiazole-diyl group, a phthalimido-diyl group, a thienothiazole-diyl group, a thiazolothiazole-diyl group, a thienothiophene-diyl group, a thienooxazole-diyl group, and the following structures (II-1) to (II-4).

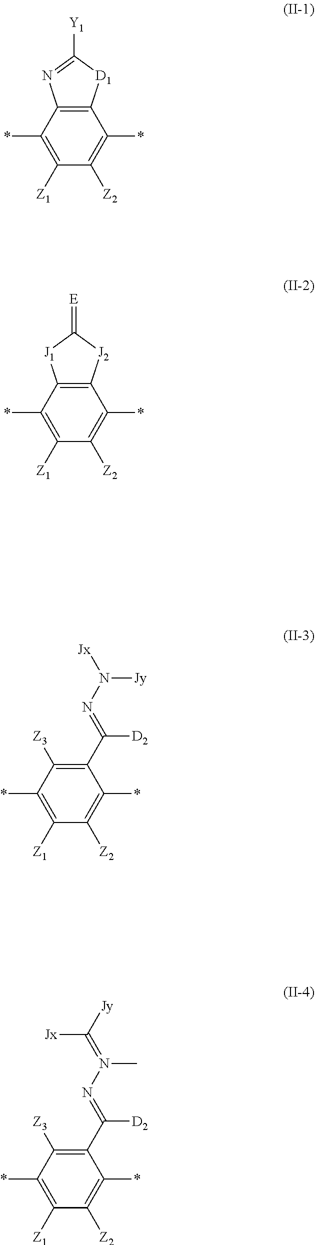

In Formulae (II-1) to (H4), D₁ represents —S—, —O—, or NR¹¹—, in which R¹¹ represents a hydrogen atom or an alkyl group having 1 to 6 carbon atoms; Y₁ represents an aromatic hydrocarbon group having 6 to 12 carbon atoms or an aromatic heterocyclic group having 3 to 12 carbon atoms; Z₁, Z₂, and Z₃ each independently represent a hydrogen atom, an aliphatic hydrocarbon group having 1 to 20 carbon atoms, an alicyclic hydrocarbon group having 3 to 20 carbon atoms, a monovalent aromatic hydrocarbon group having 6 to 20 carbon atoms, a halogen atom, a cyano group, a nitro group, —NR¹²R¹³, or —SR¹², in which Z₁ and Z₂ may be bonded to each other to form an aromatic ring or an aromatic heterocyclic ring, and R¹² and R¹³ each independently represent a hydrogen atom or an alkyl group having 1 to 6 carbon atoms; J₁ and J₂ each independently represent a group selected from the group consisting of —O—, —NR²¹— (R²¹ represents a hydrogen atom or a substituent), —S—, and C(O)—; E represents a hydrogen atom or a non-metal atom of Group 14 to Group 16, to which a substituent may be bonded; Jx represents an organic group having 2 to 30 carbon atoms, which has at least one aromatic ring selected from the group consisting of an aromatic hydrocarbon ring and an aromatic heterocyclic ring; Jy represents a hydrogen atom, an alkyl group having 1 to 6 carbon atoms, which may have a substituent, or an organic group having 2 to 30 carbon atoms, which has at least one aromatic ring selected from the group consisting of an aromatic hydrocarbon ring and an aromatic heterocyclic ring; the aromatic ring of Jx and Jy may have a substituent, Jx and Jy may be bonded to each other to form a ring; and D₂ represents a hydrogen atom or an alkyl group having 1 to 6 carbon atoms, which may have a substituent.

In Formula (II-2), in a case where Y₁ represents an aromatic hydrocarbon group having 6 to 12 carbon atoms, the aromatic hydrocarbon group may be monocyclic or polycyclic. In a case where Y₁ represents an aromatic heterocyclic group having 3 to 12 carbon atoms, the aromatic heterocyclic group may be monocyclic or polycyclic.

In Formula (II-2), in a case where J₁ and J₂ represent —NR²¹—, the substituent as R²¹ can refer to, for example, description in paragraphs 0035 to 0045 of JP2008-107767A, and the content thereof is incorporated in the present specification.

In Formula (II-2), in a case where E represents a non-metal atom of Group 14 to Group 16, to which a substituent may be bonded, ═O, ═S, ═NR′, or ═C(R′)R′ is preferable. R′ represents a substituent, and as the substituent, for example, description in paragraphs [0035] to [0044] of JP2008-107767A can be referred to, and —NZ^{A1}Z^{A2} (Z^{A1} and Z^{A2} each independently represent a hydrogen atom, an alkyl group, or an aryl group) is preferable.

Specific examples of the divalent alicyclic group represented by A1 include a cyclopentylene group and a cyclohexylene group, and the carbon atoms thereof may be substituted with —O—, —Si(CH₃)₂—, —N(Z)— (Z represents a hydrogen atom, an alkyl group having 1 to 4 carbon atoms, a cycloalkyl group, an aryl group, a cyano group, or a halogen atom), —C(O)—, —S—, —C(S)—, —S(O)—, —SO₂—, or a group obtained by combining two or more of these groups.

In Formula (MG-A), a1 represents an integer of 2 to 10. A plurality of A1's may be the same or different from each other.

In Formula (MG-B), A2 and A3 each independently represent a divalent group selected from the group consisting of an aromatic hydrocarbon group, a heterocyclic group, and an alicyclic group. Specific examples and suitable aspects of A2 and A3 are the same as those for A1 in Formula (MG-A), and thus the description thereof will not be repeated.

In Formula (MG-B), a2 represents an integer of 1 to 10, a plurality of A2's may be the same or different from each other, and a plurality of LA1's may be the same or different from each other. From the reason that the effect of the present invention is more excellent, it is more preferable that a2 is 2 or more.

In Formula (MG-B), LA1 represents a single bond or a divalent linking group. Here, in a case where a2 is 1, LA1 is a divalent linking group, and in a case where a2 is 2 or more, at least one of a plurality of LA1's is a divalent linking group.

In Formula (MG-B), the divalent linking group represented by LA1 is the same as LW, and thus the description thereof will not be repeated.

Specific examples of MG include the following structures, and the hydrogen atoms on the aromatic hydrocarbon group, the heterocyclic group, and the alicyclic group in the following structures may be substituted with the substituent W described above.

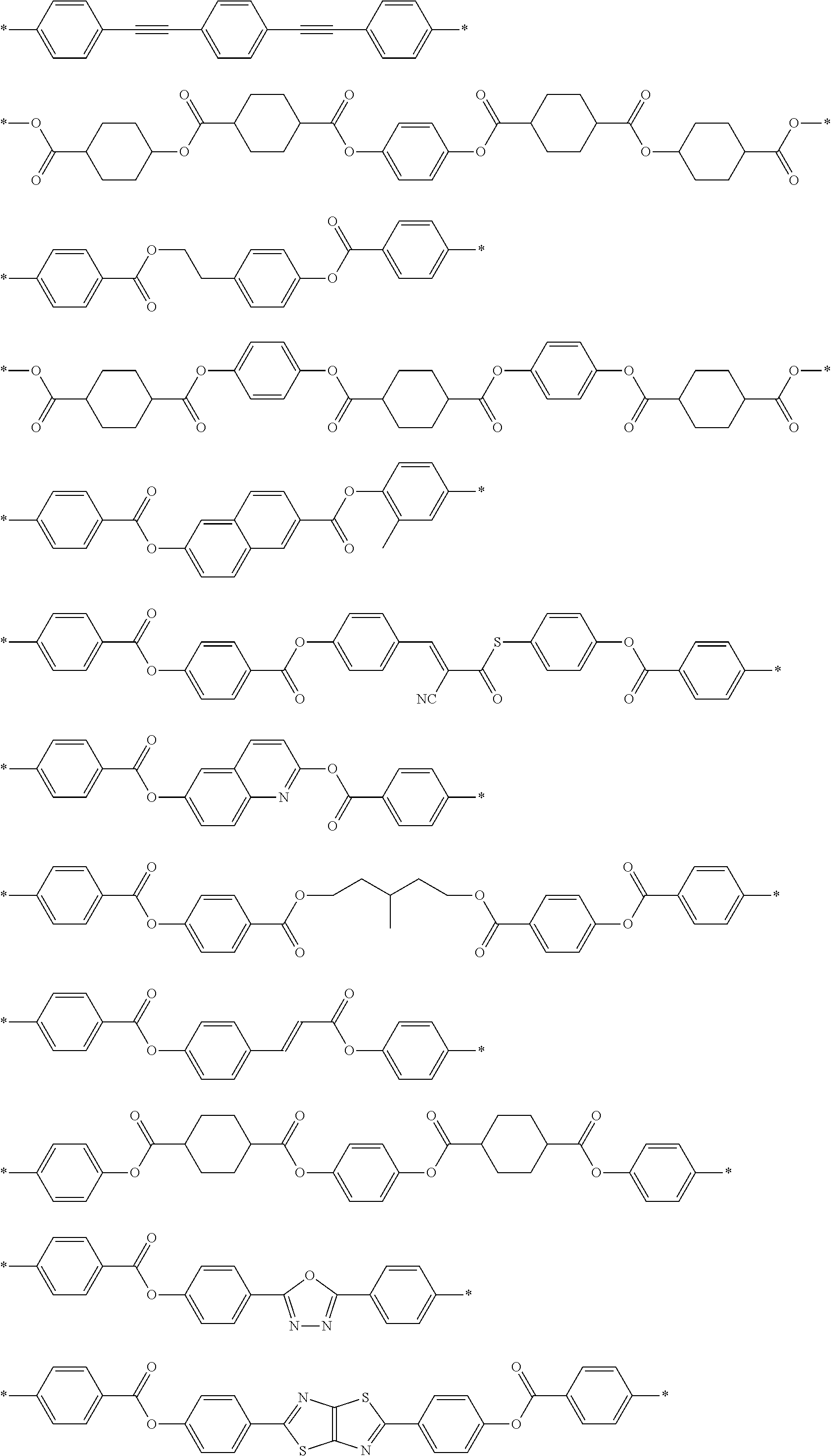

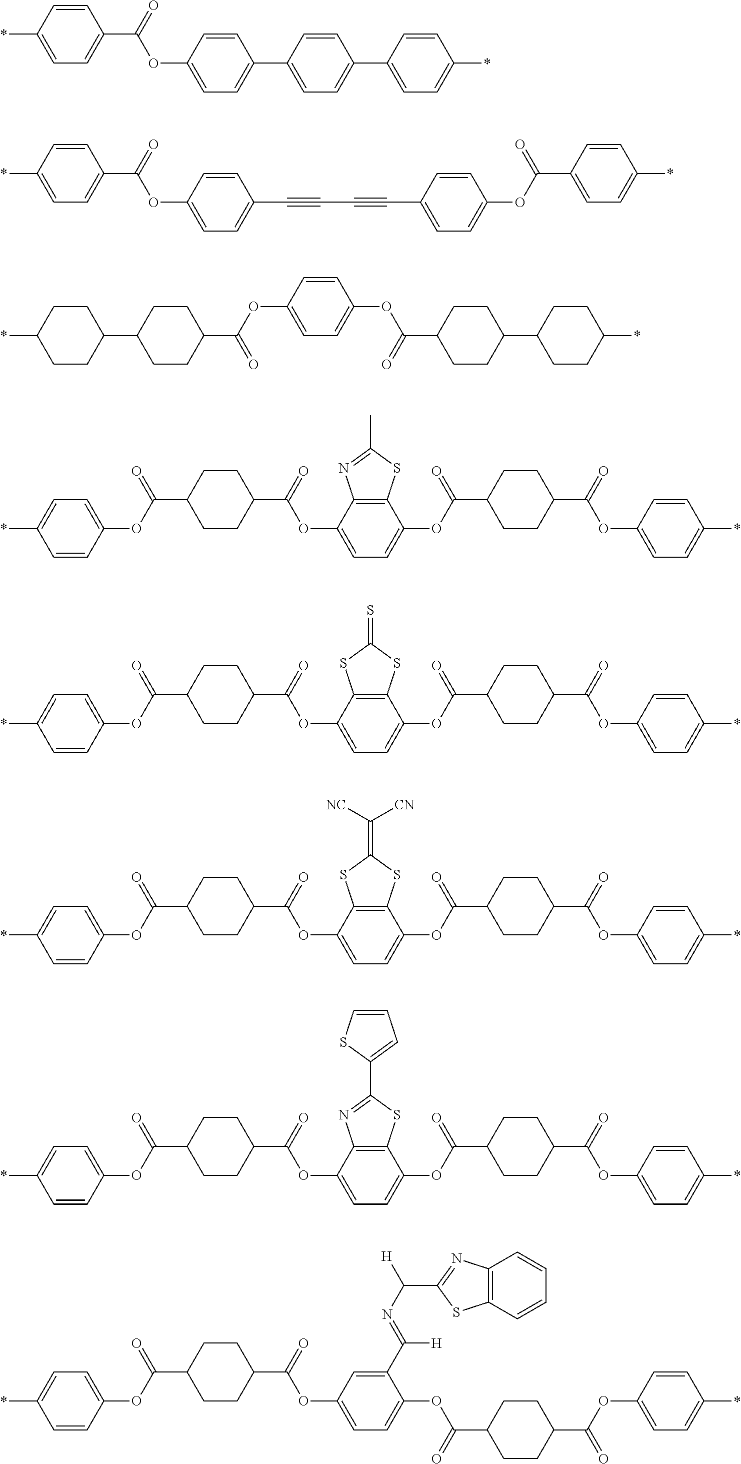

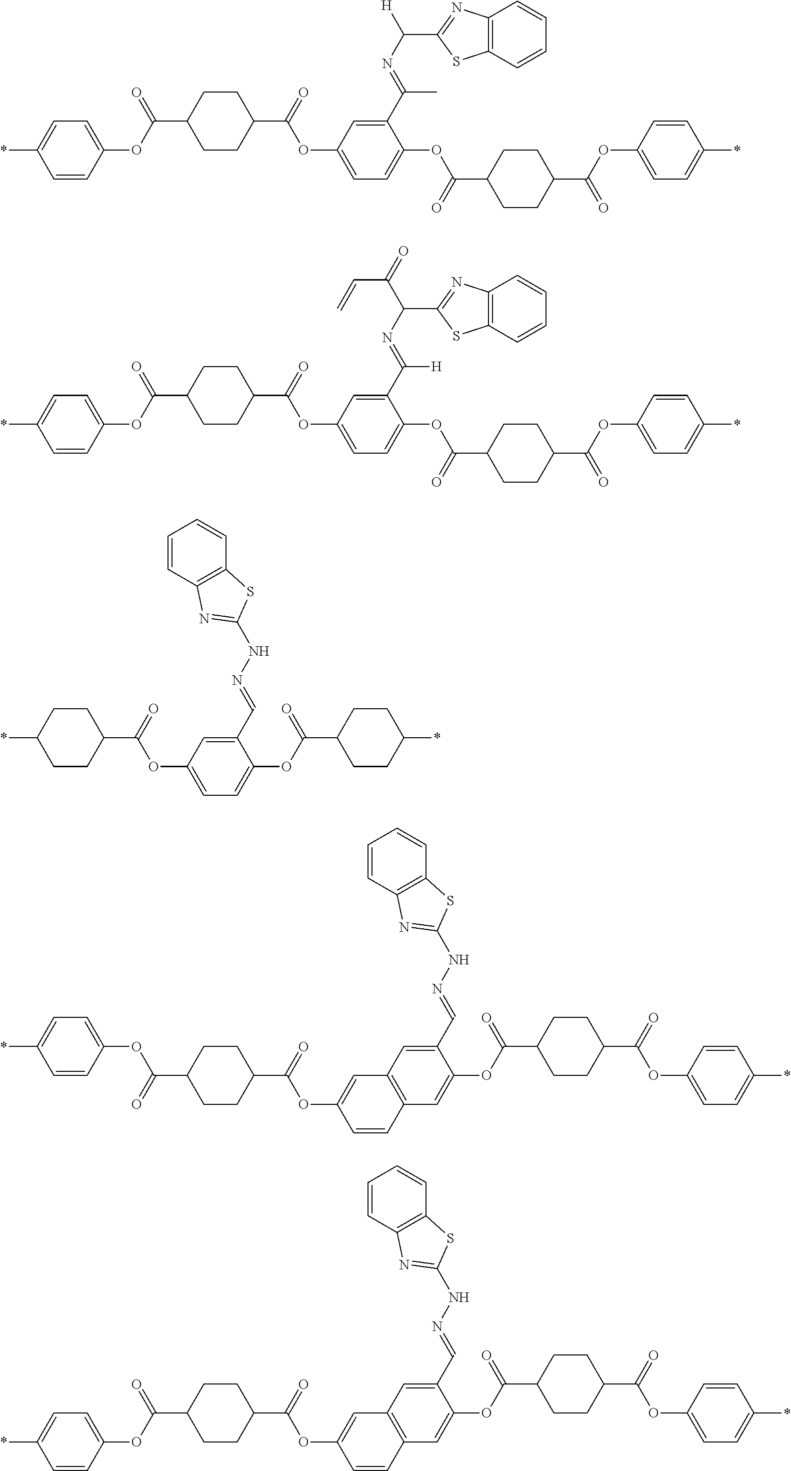

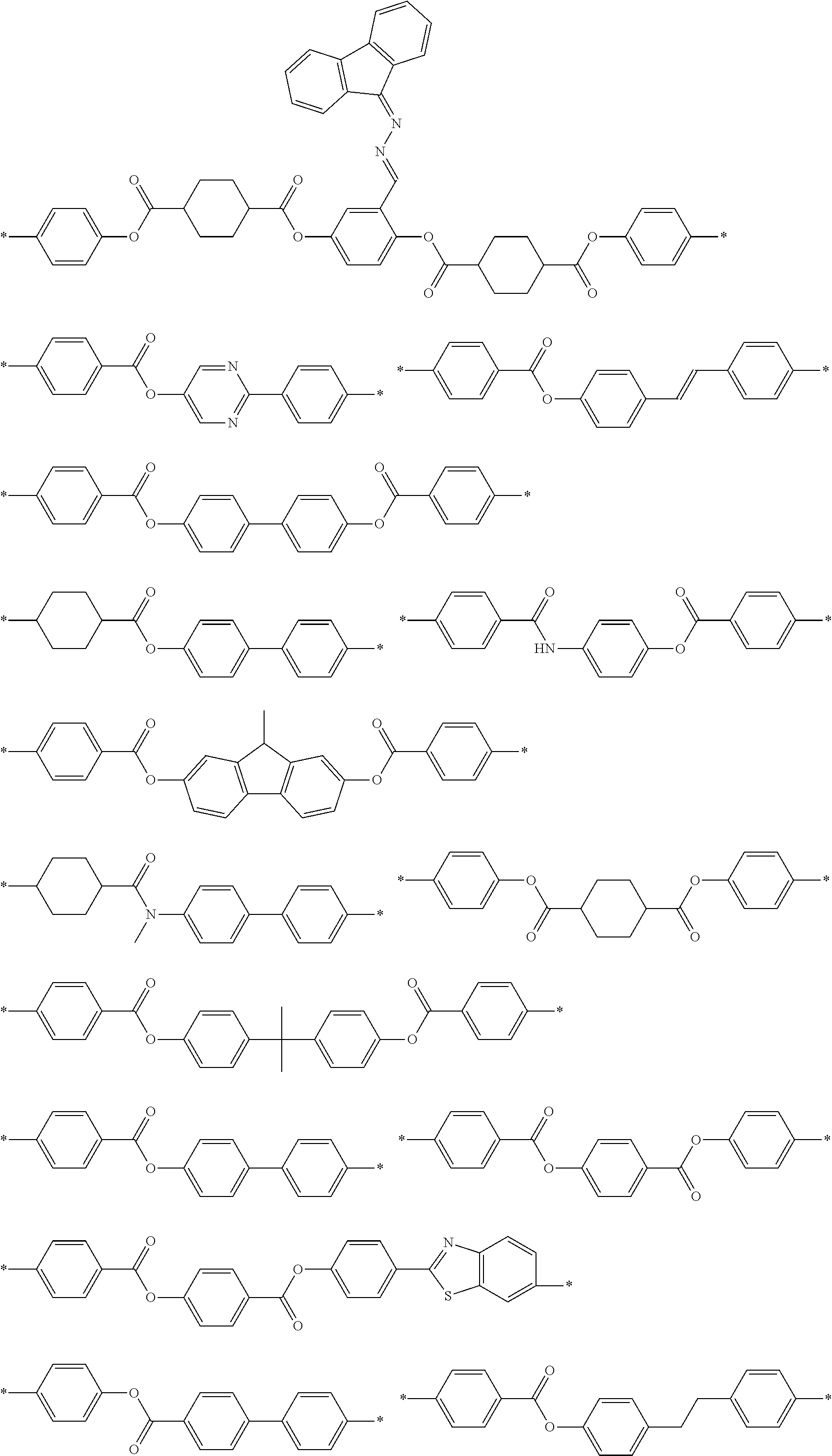

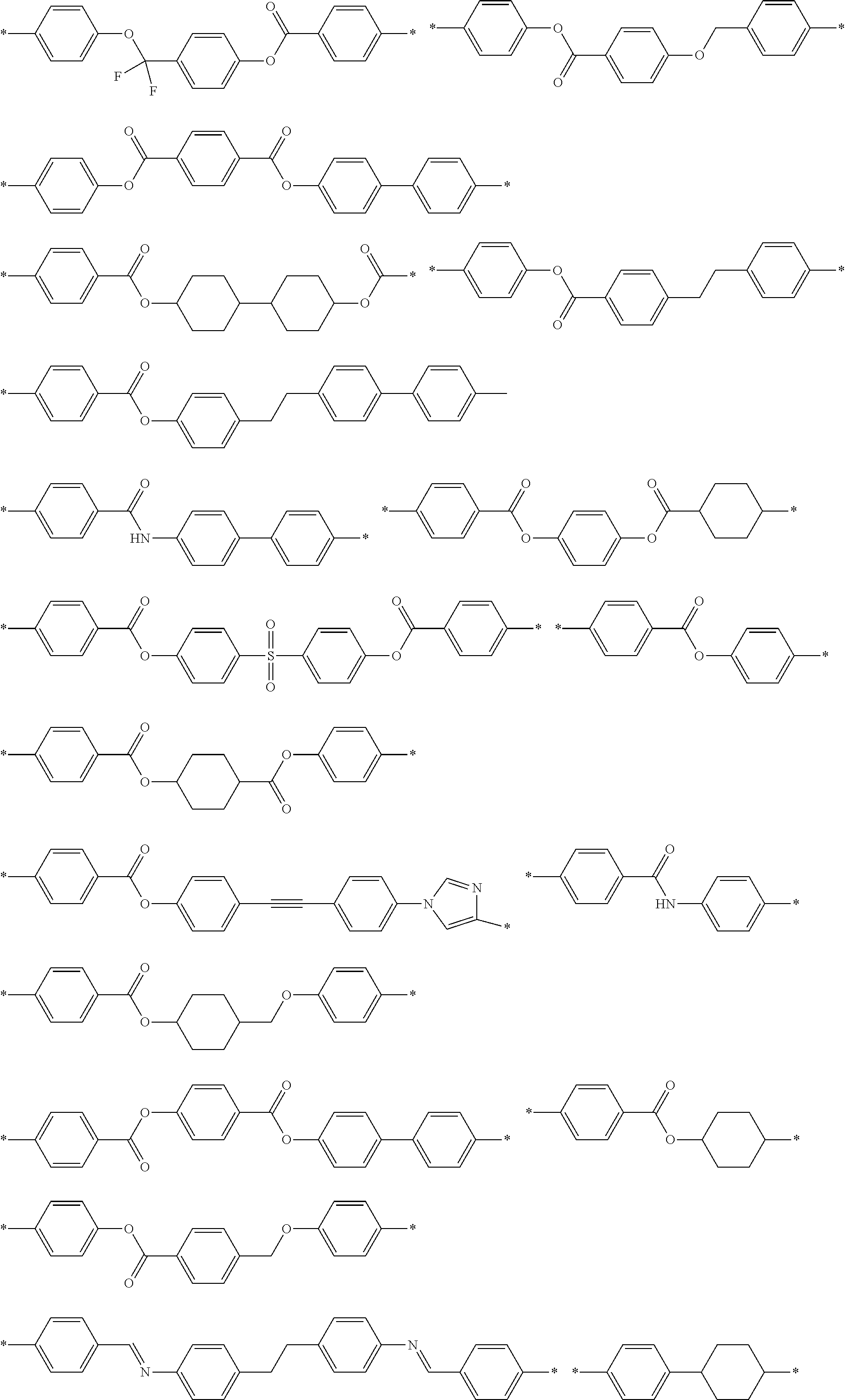

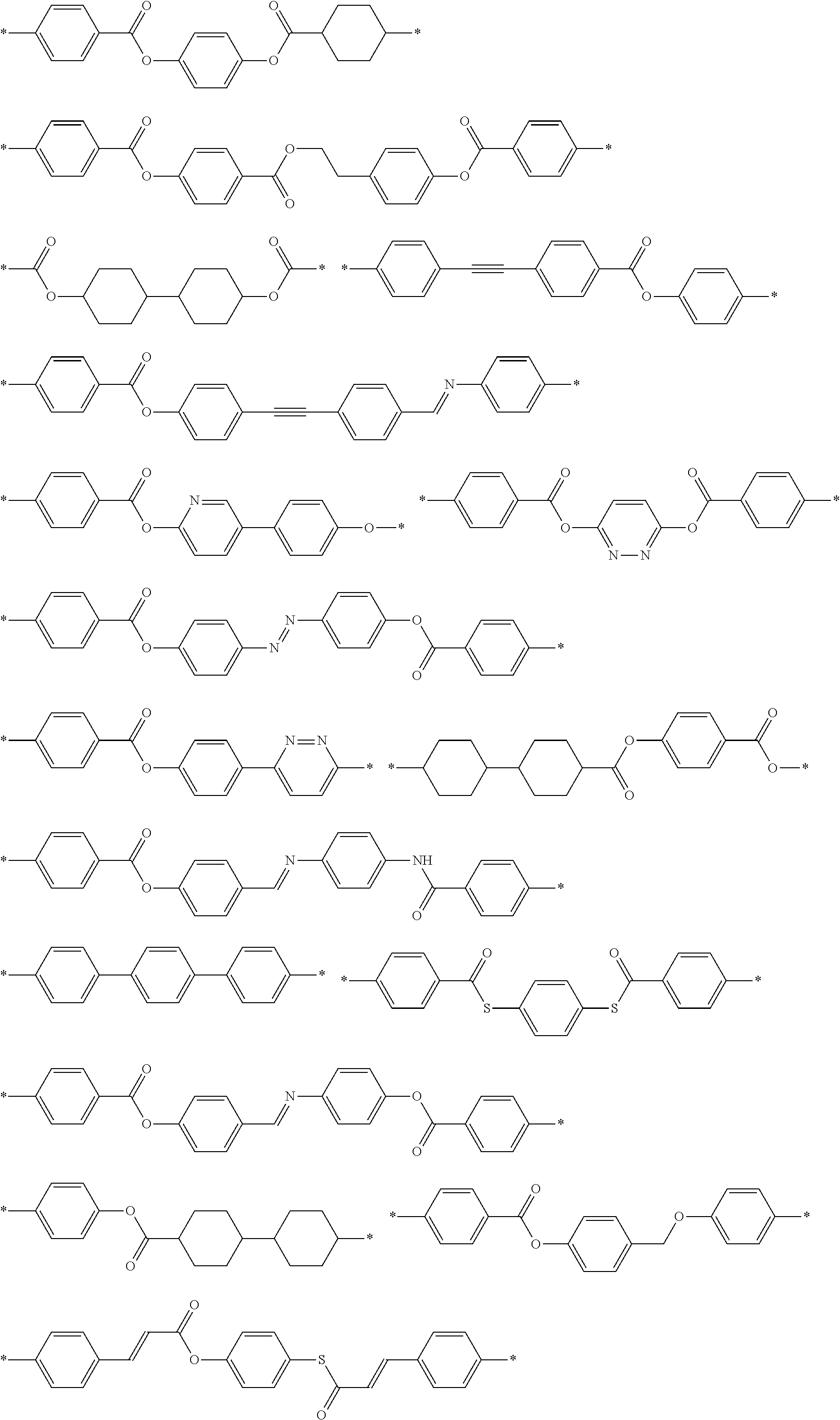

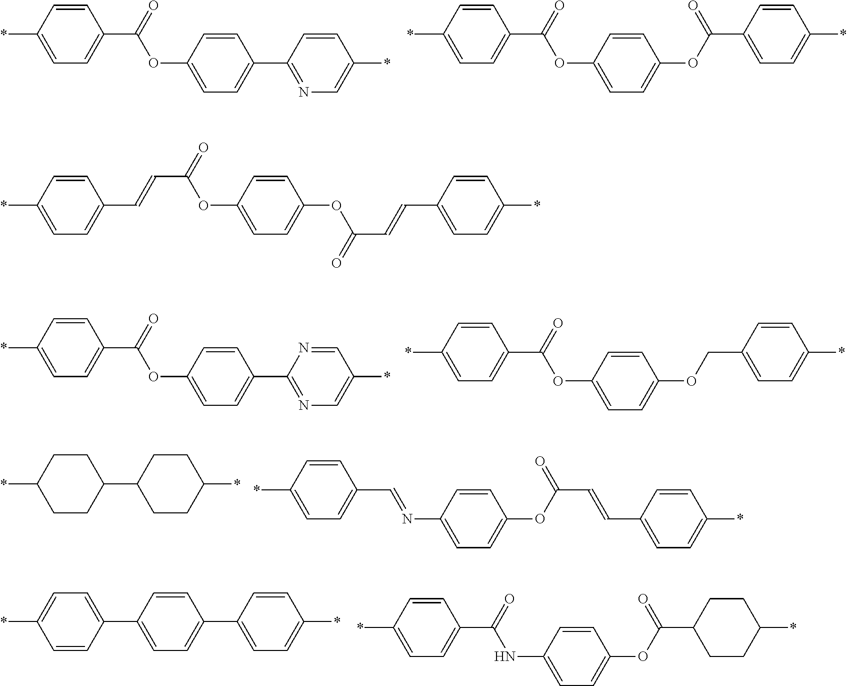

### <Low-Molecular-Weight Liquid Crystal Compound>

In a case where the liquid crystal compound represented by Formula (LC) is the low-molecular-weight liquid crystal compound, examples of preferred aspects of the cyclic structure of the mesogen group MG include a cyclohexylene group, a cyclopentylene group, a phenylene group, a naphthylene group, a fluorene-diyl group, a pyridine-diyl group, a pyridazine-diyl group, a thiophene-diyl group, an oxazole-diyl group, a thiazole-diyl group, and a thienothiophene-diyl group, and the number of cyclic structures is preferably 2 to 10 and more preferably 3 to 7.

Examples of preferred aspects of the substituent W in the mesogen structure include a halogen atom, a halogenated alkyl group, a cyano group, a hydroxy group, a nitro group, a carboxy group, an alkoxy group having 1 to 10 carbon atoms, an alkylcarbonyl group having 1 to 10 carbon atoms, an alkyloxycarbonyl group having 1 to 10 carbon atoms, an alkylcarbonyloxy group having 1 to 10 carbon atoms, an amino group, an alkylamino group having 1 to 10 carbon atoms, an alkylaminocarbonyl group, and a group in which LW in Formula (W1) represents a single bond, SPW represents a divalent spacer group, and Q represents a crosslinkable group represented by any of Formulae (P-1) to (P-30); and as the crosslinkable group, a vinyl group, a butadiene group, a (meth)acryloyl group, a (meth)acrylamide group, a vinyl acetate group, a fumaric acid ester group, a styryl group, a vinylpyrrolidone group, a maleic acid anhydride, a maleimide group, a vinyl ether group, an epoxy group, or an oxetanyl group is preferable.

Preferred aspects of the divalent spacer groups S1 and S2 are the same as those for SPW described above, and thus the description thereof will not be repeated.

In a case where a low-molecular-weight liquid crystal compound exhibiting smectic properties is used, the number of carbon atoms in the spacer group (the number of atoms in a case where the carbon atoms are substituted with “SP—C”) is preferably 6 or more and more preferably 8 or more.

In a case where the liquid crystal compound represented by Formula (LC) is the low-molecular-weight liquid crystal compound, a plurality of low-molecular-weight liquid crystal compounds may be used in combination, and it is preferable that 2 to 6 kinds of low-molecular-weight liquid crystal compounds are used in combination, and it is more preferable that 2 to 4 kinds of low-molecular-weight liquid crystal compounds are used in combination. By using the low-molecular-weight liquid crystal compounds in combination, solubility can be improved, and the phase transition temperature of the liquid crystal composition can be adjusted.

Specific examples of the low-molecular-weight liquid crystal compound include compounds represented by Formulae (LC-1) to (LC-77), but the low-molecular-weight liquid crystal compound is not limited thereto.

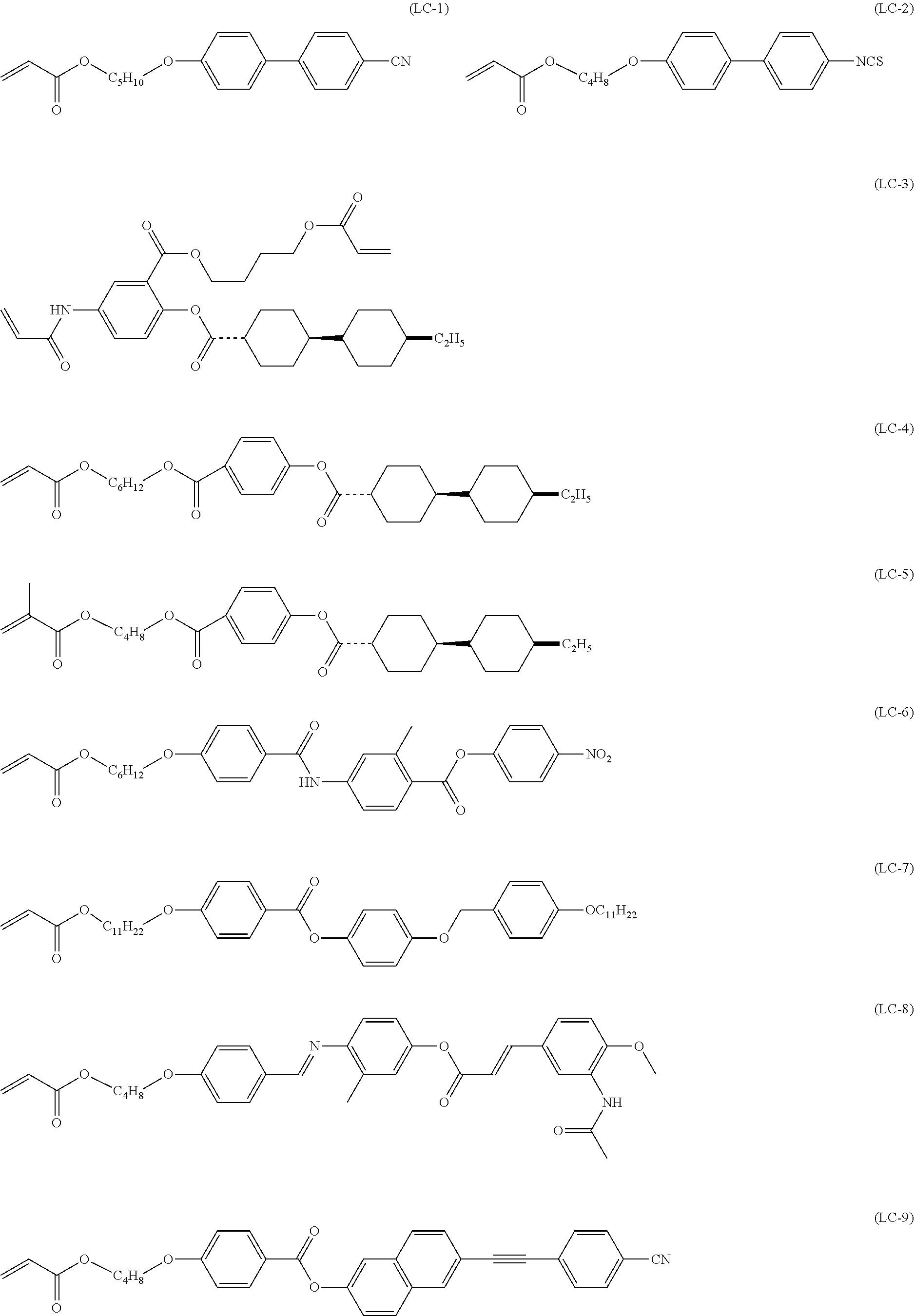

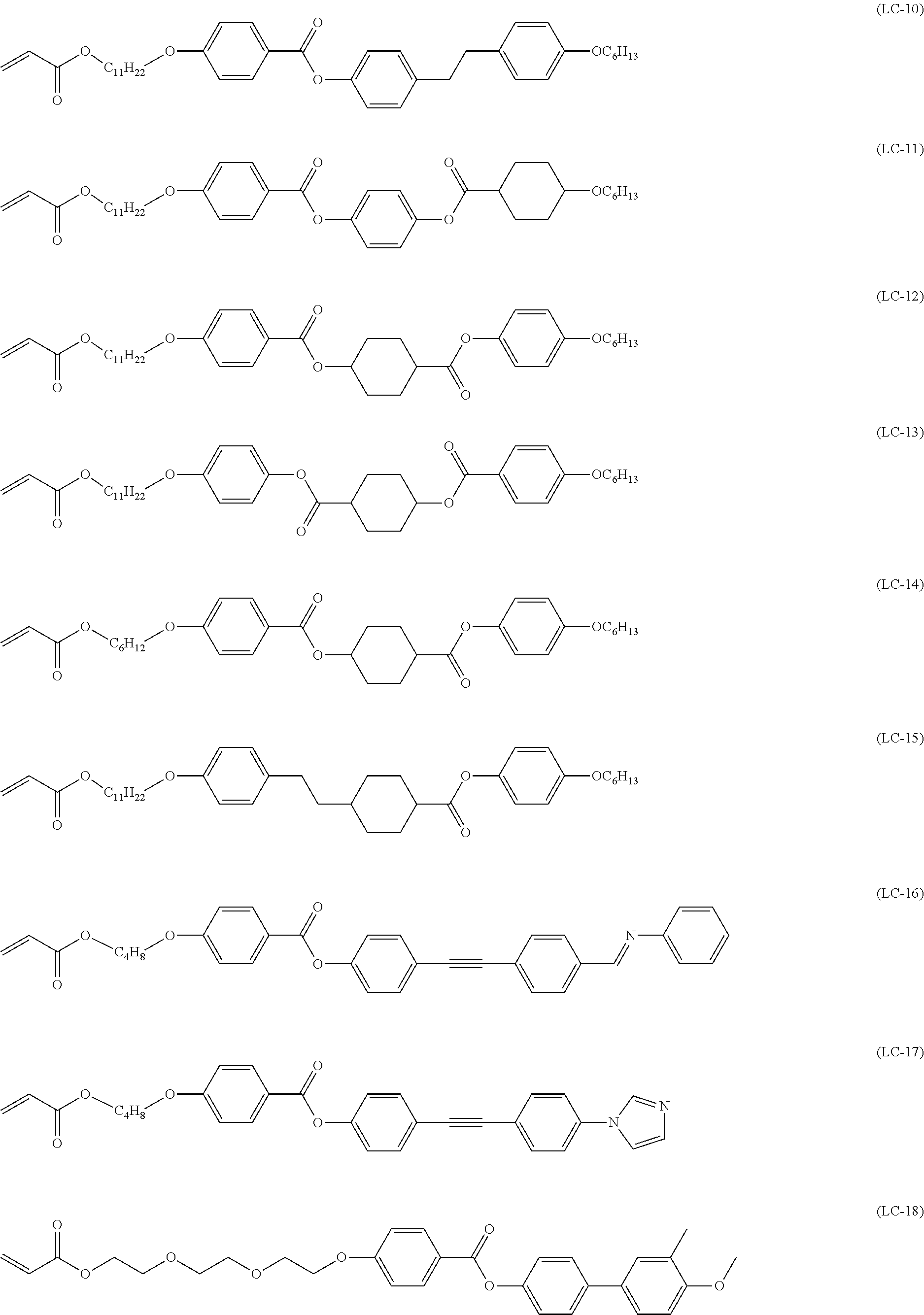

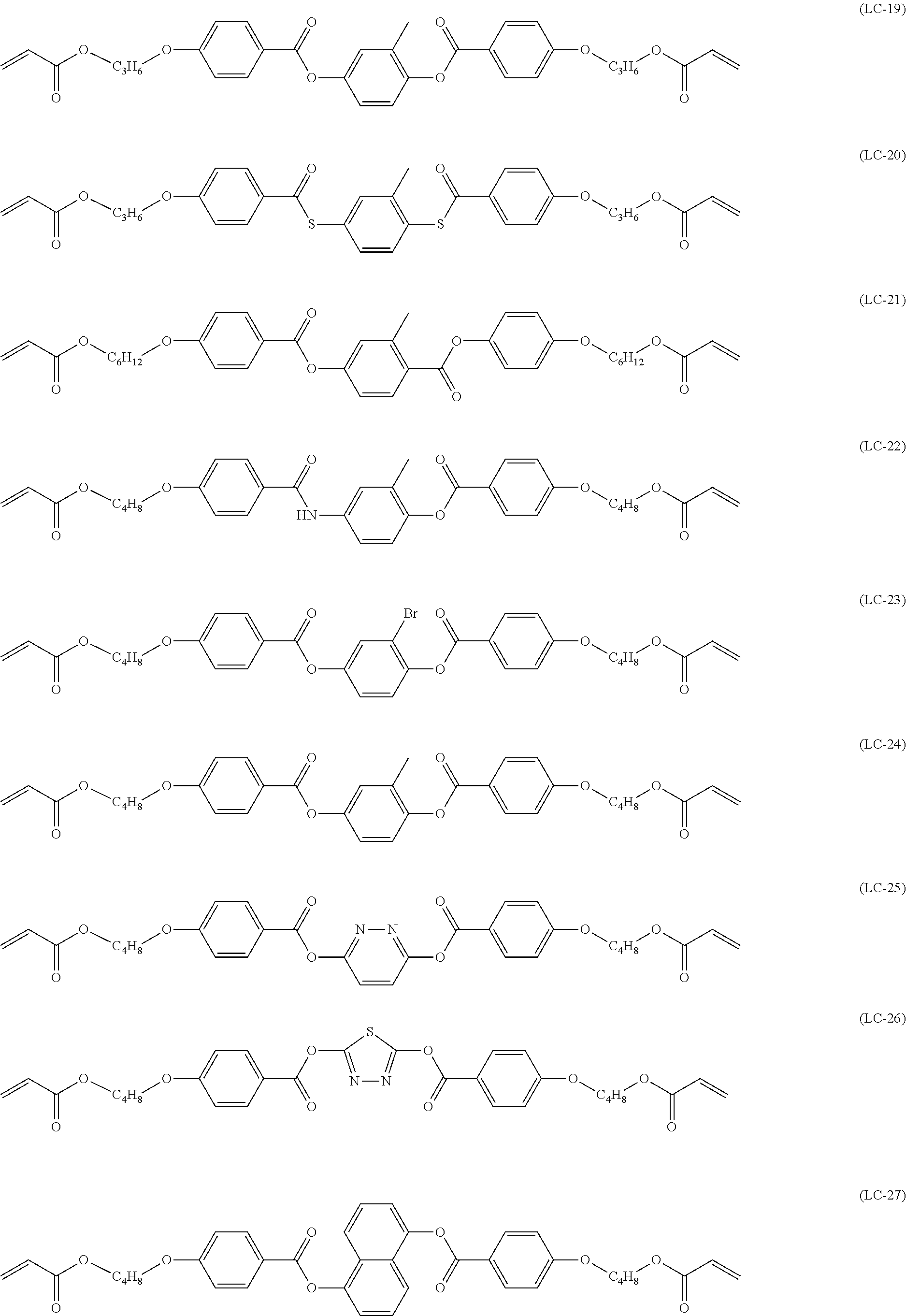

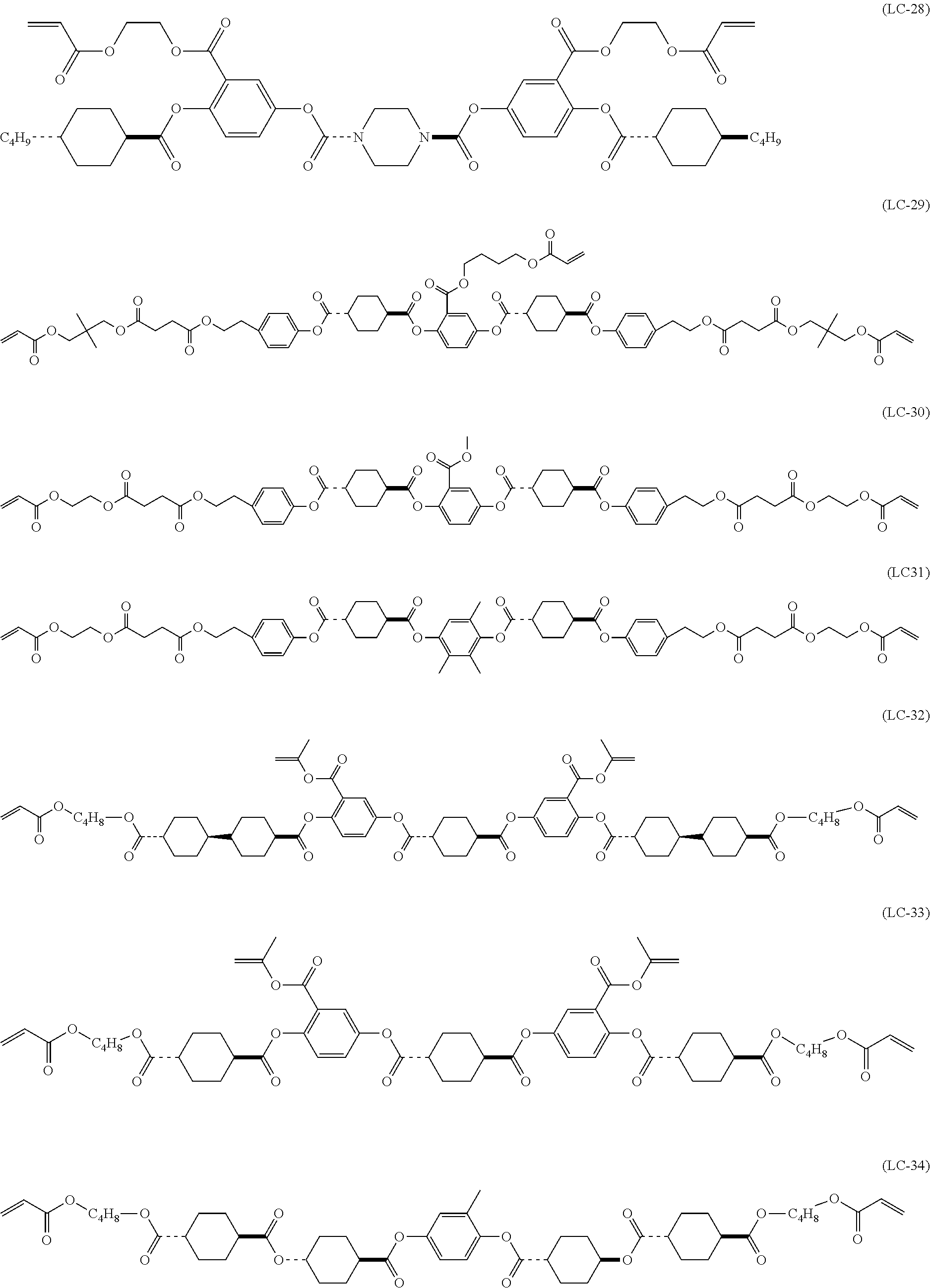

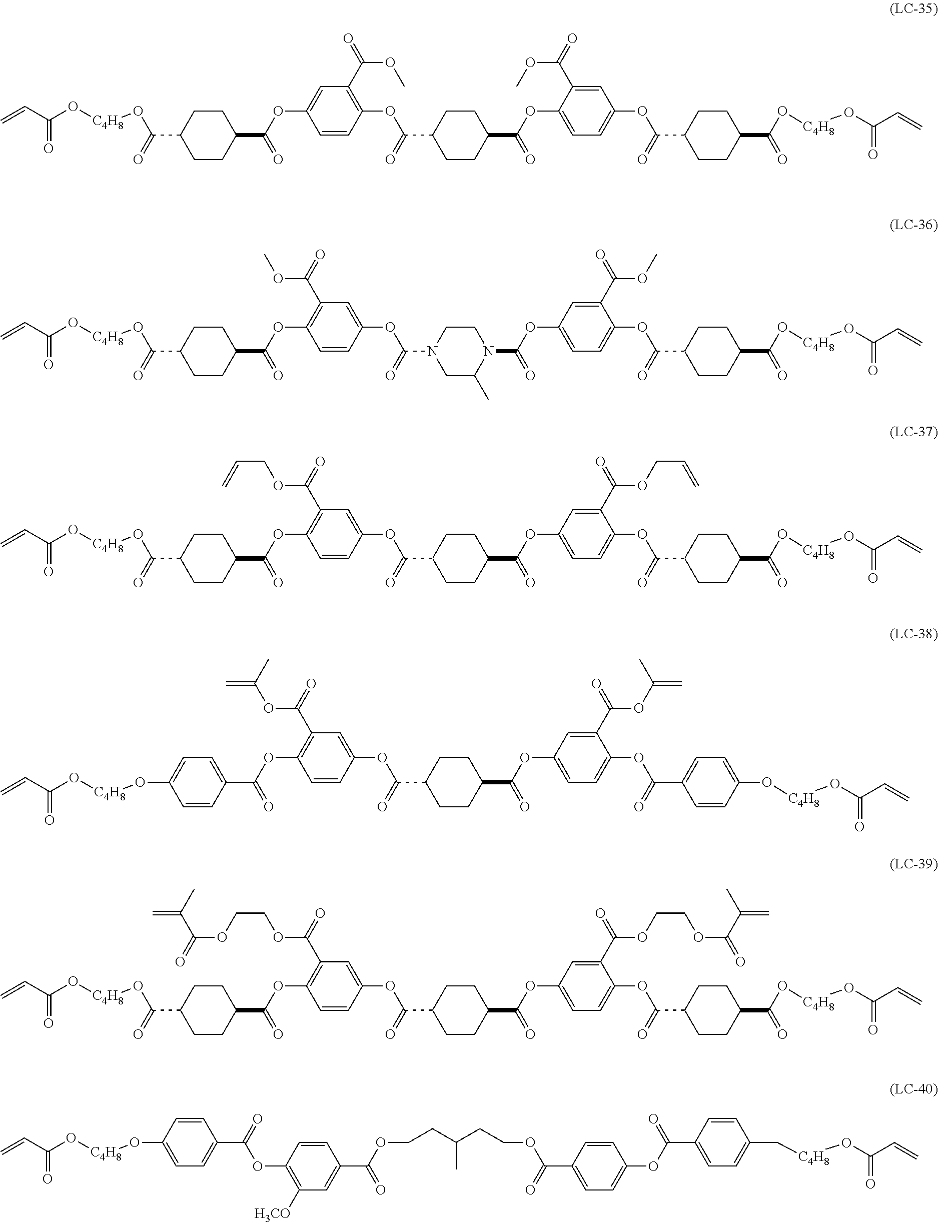

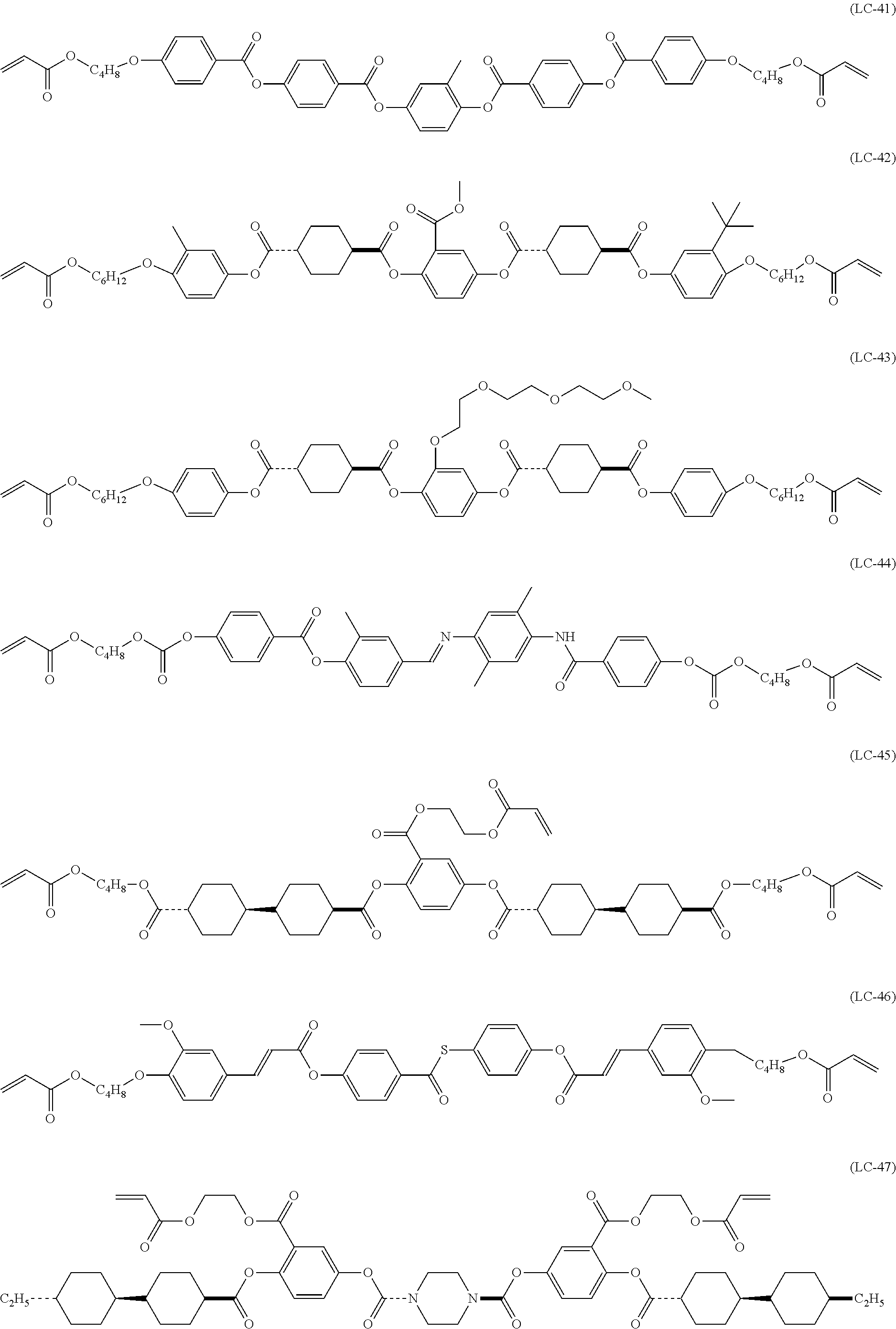

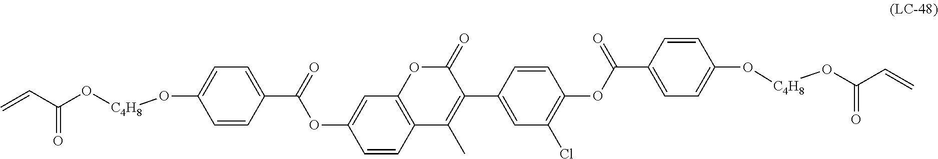

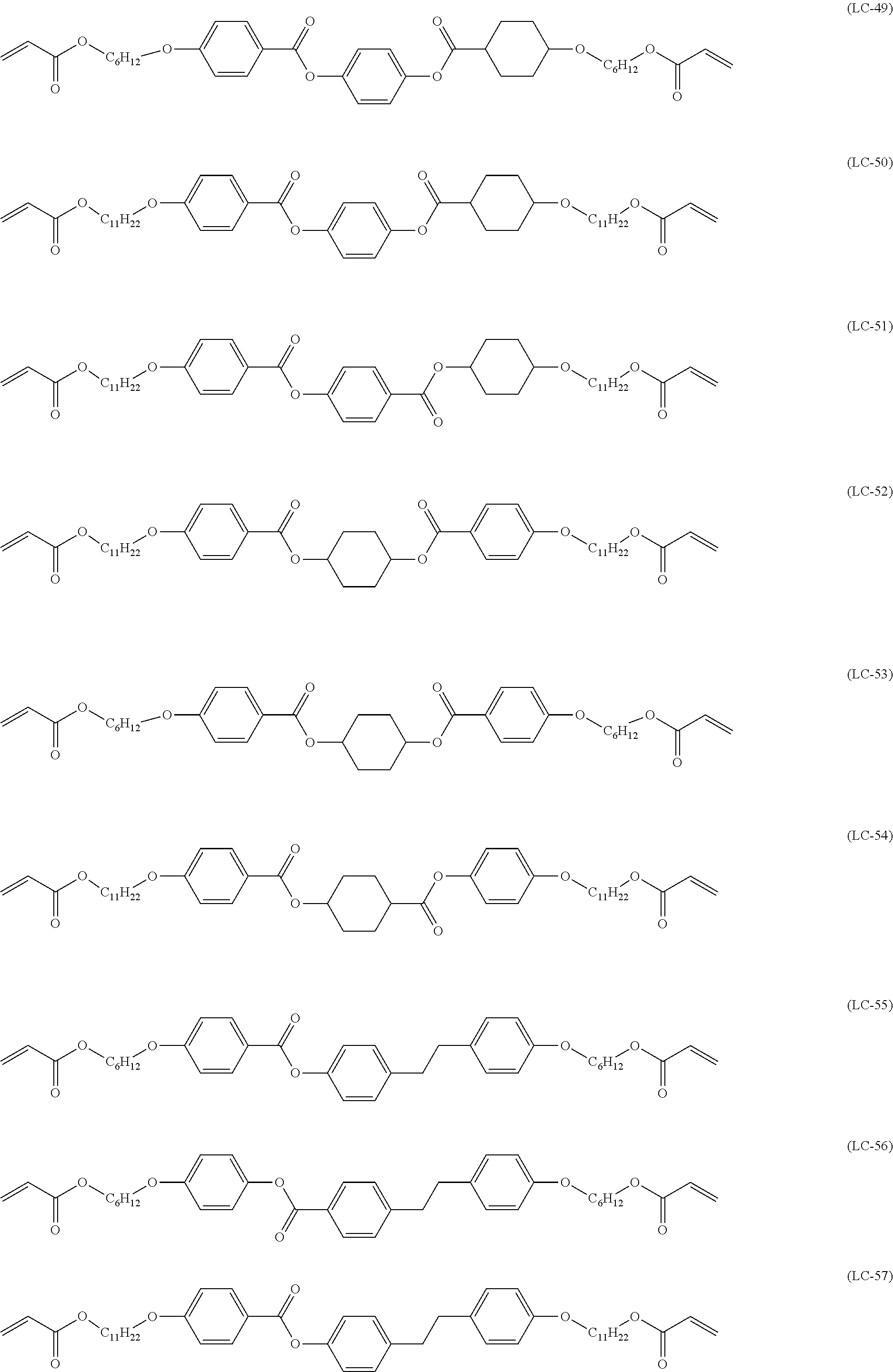

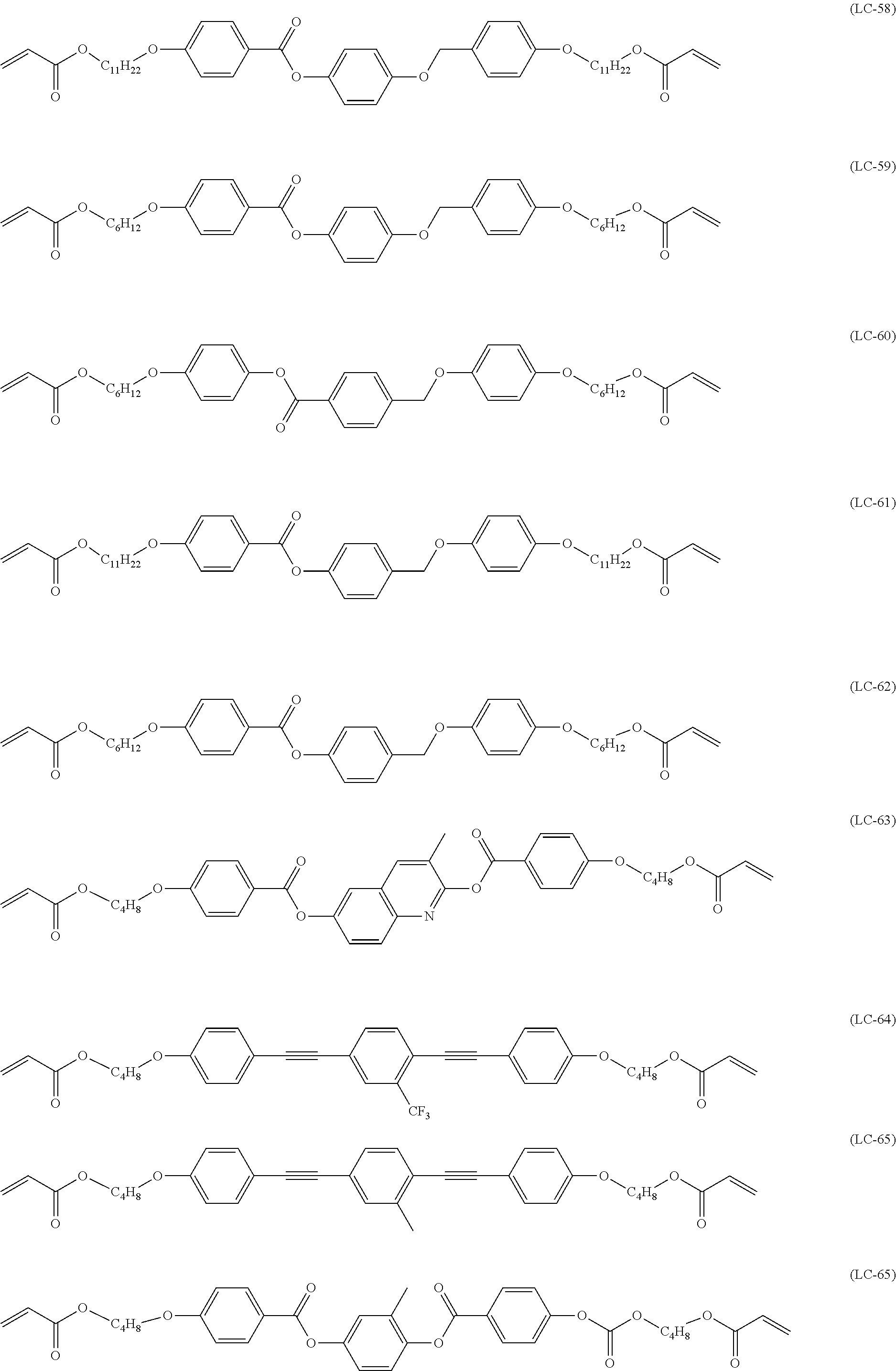

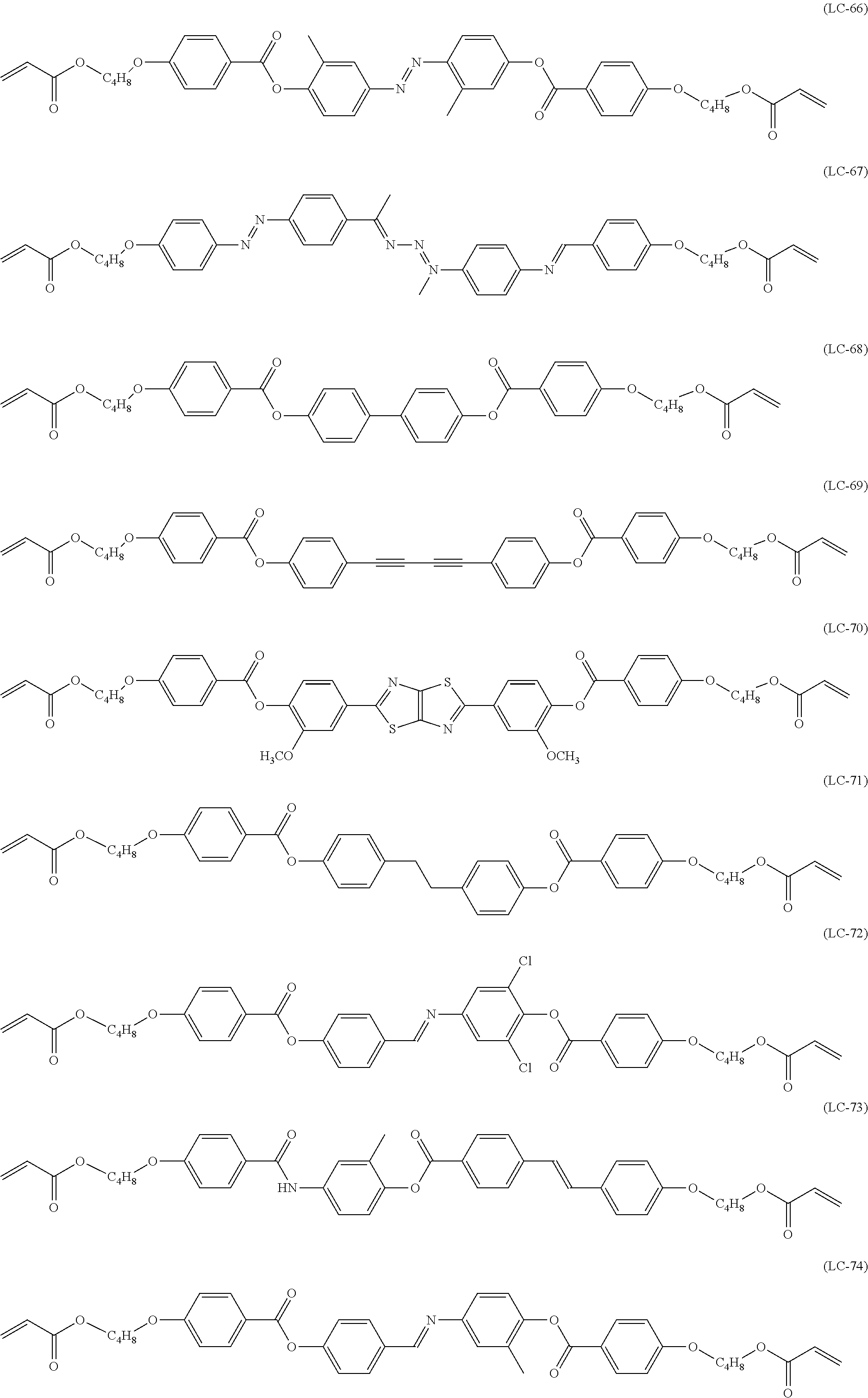

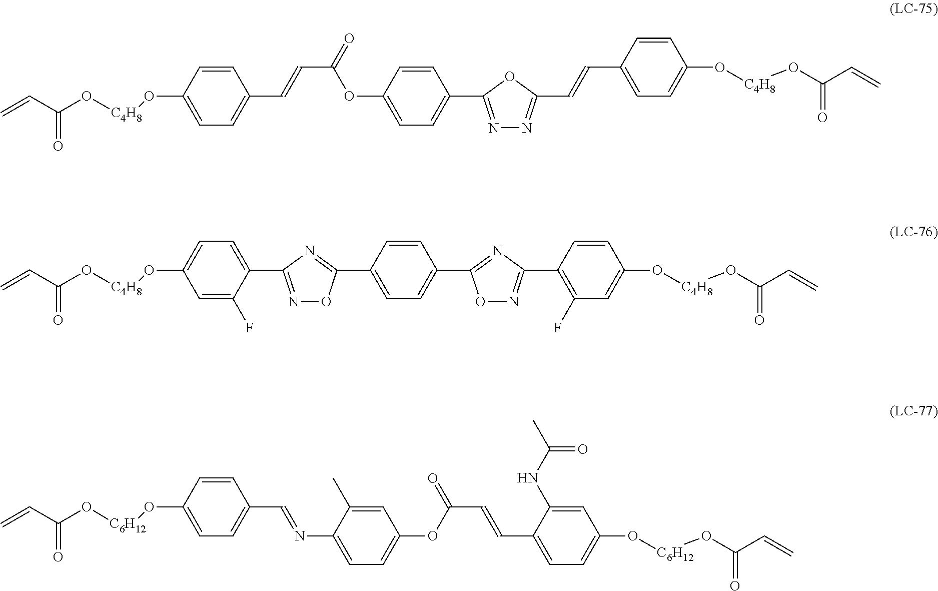

### <High-Molecular-Weight Liquid Crystal Compound>

The high-molecular-weight liquid crystal compound is preferably a homopolymer or a copolymer, including a repeating unit described below, and may be any of a random polymer, a block polymer, a graft polymer, or a star polymer.

### (Repeating Unit (1))

It is preferable that the high-molecular-weight liquid crystal compound includes a repeating unit represented by Formula (1) (hereinafter, also referred to as “repeating unit (1)”).

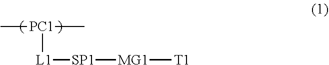

In Formula (1), PC1 represents a main chain of the repeating unit, L1 represents a single bond or a divalent linking group, SP1 represents a spacer group, MG1 represents the mesogen group MG in Formula (LC) described above, and T1 represents a terminal group.

Examples of the main chain of the repeating unit, represented by PC1, include groups represented by Formulae (P1-A) to (P1-D). Among these, from the viewpoint of diversity and handleability of a monomer serving as a raw material, a group represented by Formula (P1-A) is preferable.

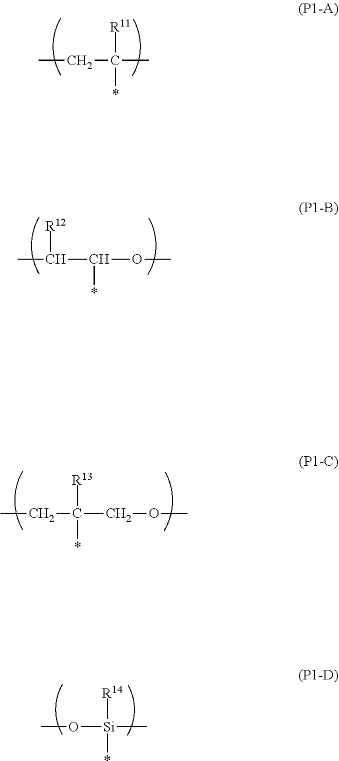

In Formulae (P1-A) to (P1-D), “*” represents a bonding position to L1 in Formula (1). In Formulae (P1-A) to (P1-D), R¹¹, R¹², R¹³, and R¹⁴ each independently represent a hydrogen atom, a halogen atom, a cyano group, an alkyl group having 1 to 10 carbon atoms, or an alkoxy group having 1 to 10 carbon atoms. The above-described alkyl group may be a linear or branched alkyl group, or an alkyl group having a cyclic structure (cycloalkyl group). In addition, the number of carbon atoms in the above-described alkyl group is preferably 1 to 5.

It is preferable that the group represented by Formula (P1-A) is one unit of a partial structure of poly(meth)acrylic acid ester, which is obtained by polymerization of (meth)acrylic acid ester.

It is preferable that the group represented by Formula (P1-B) is an ethylene glycol unit formed by ring-opening polymerization of an epoxy group of a compound having the epoxy group.

It is preferable that the group represented by Formula (P1-C) is a propylene glycol unit formed by ring-opening polymerization of an oxetane group of a compound having the oxetane group.

It is preferable that the group represented by Formula (P1-D) is a siloxane unit of a polysiloxane obtained by polycondensation of a compound having at least one of an alkoxysilyl group or a silanol group. Here, examples of the compound having at least one of an alkoxysilyl group or a silanol group include a compound having a group represented by Formula SiR¹⁴(OR¹⁵)₂—. In the formula, R¹⁴ has the same definition as that for R¹⁴ in Formula (P1-D), and a plurality of R¹⁵'s each independently represent a hydrogen atom or an alkyl group having 1 to 10 carbon atoms.

The divalent linking group represented by L1 is the same divalent linking group as LW in Formula (W1) described above, and examples of preferred aspects thereof include —C(O)O—, —OC(O)—, —O—, —S—, —C(O)NR¹⁶—, —NR¹⁶C(O)—, —S(O)₂—, and —NR¹⁶R¹⁷—. In the formulae, R¹⁶ and R¹⁷ each independently represent a hydrogen atom or an alkyl group having 1 to 6 carbon atoms, which may have a substituent (for example, the substituent W described above). In the specific examples of the divalent linking group, the bonding site on the left side is bonded to PC1 and the bonding site on the right side is bonded to SP1.

In a case where PC1 represents the group represented by Formula (P1-A), it is preferable that L1 is a group represented by —C(O)O— or —C(O)NR¹⁶—.

In a case where PC1 represents the group represented by any of Formulae (P1-B) to (P1-D), it is preferable that L1 is a single bond.

The spacer group represented by SP1 represents the same groups as S1 and S2 in Formula (LC) described above, and from the viewpoint of the alignment degree, a group having at least one structure selected from the group consisting of an oxyethylene structure, an oxypropylene structure, a polysiloxane structure, and an alkylene fluoride structure, or a linear or branched alkylene group having 2 to 20 carbon atoms is preferable. However, the above-described alkylene group may include —O—, —S—, —O—CO—, —CO—O—, —O—CO—O—, —O—CNR— (R represents an alkyl group having 1 to 10 carbon atoms), or —S(O)₂—.

From the reason of easily expressing liquid crystallinity and availability of raw materials, it is more preferable that the spacer group represented by SP1 is a group having at least one structure selected from the group consisting of an oxyethylene structure, an oxypropylene structure, a polysiloxane structure, and an alkylene fluoride structure.

Here, the oxyethylene structure represented by SP1 is preferably a group represented by *—(CH₂—CH₂O)ₙ₁—* is preferable. In the formula, n1 represents an integer of 1 to 20, and * represents a bonding position to L1 or MG1. From the reason that the effect of the present invention is more excellent, n1 is preferably an integer of 2 to 10, more preferably an integer of 2 to 6, and most preferably an integer of 2 to 4.

In addition, the oxypropylene structure represented by SP1 is preferably a group represented by *—(CH(CH₃)—CH₂O)ₙ₂—*. In the formula, n2 represents an integer of 1 to 3, and * represents a bonding position to L1 or MG1.

In addition, the polysiloxane structure represented by SP1 is preferably a group represented by *—(Si(CH₃)₂—O)ₙ₃—*. In the formula, n3 represents an integer of 6 to 10, and * represents a bonding position to L1 or MG1.

In addition, the alkylene fluoride structure represented by SP1 is preferably a group represented by *—(CF₂—CF₂)ₙ₄—*. In the formula, n4 represents an integer of 6 to 10, and * represents a bonding position to L1 or MG1.

Examples of the terminal group represented by T1 include a hydrogen atom, a halogen atom, a cyano group, a nitro group, a hydroxy group, —SH, a carboxyl group, a boronic acid group, —SO₃H, —PO₃H₂, —NR¹¹R¹² (R¹¹ and R¹² each independently represent a hydrogen atom, a substituted or unsubstituted alkyl group having 1 to 10 carbon atoms, a cycloalkyl group, or an aryl group), an alkyl group having 1 to 10 carbon atoms, an alkoxy group having 1 to 10 carbon atoms, an alkylthio group having 1 to 10 carbon atoms, an alkoxycarbonyloxy group having 1 to 10 carbon atoms, an acyloxy group having 1 to 10 carbon atoms, an acylamino group having 1 to 10 carbon atoms, an alkoxycarbonyl group having 1 to 10 carbon atoms, an alkoxycarbonylamino group having 1 to 10 carbon atoms, a sulfonylamino group having 1 to 10 carbon atoms, a sulfamoyl group having 1 to 10 carbon atoms, a carbamoyl group having 1 to 10 carbon atoms, a sulfinyl group having 1 to 10 carbon atoms, a ureido group having 1 to 10 carbon atoms, and a crosslinkable group-containing group.

Examples of the above-described crosslinkable group-containing group include -L-CL described above. L represents a single bond or a linking group. Specific examples of the linking group are the same as those for LW and SPW described above. CL represents a crosslinkable group, examples thereof include the group represented by Q1 or Q2 described above, and the above-described group represented by any of Formulae (P-1) to (P-30) is preferable. In addition, T1 maybe a group obtained by combining two or more of these groups.

From the reason that the effect of the present invention is more excellent, T1 is preferably an alkoxy group having 1 to 10 carbon atoms, more preferably an alkoxy group having 1 to 5 carbon atoms, and still more preferably a methoxy group. These terminal groups may be further substituted with the groups or polymerizable groups described in JP2010-244038A.

From the reason that the effect of the present invention is more excellent, the number of atoms in the main chain of T1 is preferably 1 to 20, more preferably 1 to 15, still more preferably 1 to 10, and particularly preferably 1 to 7. In a case where the number of atoms in the main chain of T1 is 20 or less, the alignment degree of the light absorption anisotropic layer is further improved. Here, the “main chain” of T1 means the longest molecular chain bonded to M1, and the number of hydrogen atoms is not included in the number of atoms in the main chain of T1. For example, in a case where T1 is an n-butyl group, the number of atoms in the main chain is 4, and in a case where T1 is an sec-butyl group, the number of atoms in the main chain is 3.

A content of the repeating unit (1) is preferably 40% to 100% by mass and more preferably 50% to 95% by mass with respect to all repeating units (100% by mass) of the high-molecular-weight liquid crystal compound. In a case where the content of the repeating unit (1) is 40% by mass or more, an excellent light absorption anisotropic layer can be obtained due to favorable aligning properties. In addition, in a case where the content of the repeating unit (1) is 100% by mass or less, an excellent light absorption anisotropic layer can be obtained due to favorable aligning properties.

The high-molecular-weight liquid crystal compound may include only one of the repeating unit (1), or two or more kinds of the repeating units (1). In a case where the high-molecular-weight liquid crystal compound includes two or more kinds of repeating units (1), the above-described content of the repeating unit (1) indicates the total content of the repeating units (1).

### (Log P Value)

In Formula (1), a difference (|log P₁−log P₂|) between a log P value of PC1, L1, and SP1 (hereinafter, also referred to as “log P₁”) and a log P value of MG1 (hereinafter, also referred to as “log P₂”) is 4 or more, and from the viewpoint of further improving the alignment degree of the light absorption anisotropic layer, it is preferably 4.25 or more and more preferably 4.5 or more.

In addition, from the viewpoint of adjusting the liquid crystal phase transition temperature and the synthetic suitability, the upper limit value of the above-described difference is preferably 15 or less, more preferably 12 or less, and still more preferably 10 or less.

Here, the log P value is an index for expressing properties of hydrophilicity and hydrophobicity of a chemical structure, and is also referred to as a hydrophilic-hydrophobic parameter. The log P value can be calculated using software such as ChemBioDraw Ultra or HSPiP (Ver. 4.1.07). In addition, the Iog P value can be acquired experimentally by the method of the OECD Guidelines for the Testing of Chemicals, Sections 1, Test No. 117, or the like. In the present invention, a value calculated by inputting the structural formula of a compound to HSPiP (Ver. 4.1.07) is adopted as the log P value unless otherwise specified.

The above-described log P₁ indicates the log P value of PC1, L1, and SP1 as described above. The expression “log P value of PC1, L1, and SP1” indicates the log P value of a structure in which PC1, L1, and SP1 are integrated, which is not the sum of the log P values of PC1, L1, and SP1. Specifically, the log P₁ is calculated by inputting a series of structural formulae of PC1 to SP1 in Formula (1) into the above-described software.

However, in the calculation of the log P₁, with regard to a part of the group represented by PC1 in the series of structural formulae of PC1 to SP1, the structure of the group represented by PC1 itself (for example, Formulae (P1-A) to (P1-D) described above) may be used, or a structure of a group which can be PC1 after polymerization of a monomer used to obtain the repeating unit represented by Formula (1) may be used.

Here, specific examples of the latter (the group which can be PC1) are as follows. In a case where PC1 is obtained by polymerization of (meth)acrylic acid ester, PC1 is a group represented by CH₂═C(R¹)— (R¹ represents a hydrogen atom or a methyl group). In addition, in a case where PC1 is obtained by polymerization of ethylene glycol, PC1 is ethylene glycol, and in a case where PC1 is obtained by polymerization of propylene glycol, PC1 is propylene glycol. In addition, in a case where PC1 is obtained by condensation polymerization of silanol, PC1 is silanol (a compound represented by Formula Si(R²)₃(OH); a plurality of R²'s each independently represent a hydrogen atom or an alkyl group, and at least one of the plurality of R²'s represents an alkyl group).

In a case where the above-described difference between log P₁ and log P₂ is 4 or more, the log P₁ may be less than the log P₂ or may be more than the log P₂.

Here, the log P value of a general mesogen group (the log P₂ described above) tends to be in a range of 4 to 6. In a case where the log P₁ is less than the log P₂, the value of log P₁ is preferably 1 or less and more preferably 0 or less. On the other hand, in a case where the log P₁ is more than the log P₂, the value of log P₁ is preferably 8 or more and more preferably 9 or more.

In a case where PC1 in Formula (1) is obtained by polymerization of (meth)acrylic acid ester and the log P₁ is less than the log P₂, the log P value of SP1 in Formula (1) is preferably 0.7 or less and more preferably 0.5 or less. On the other hand, in a case where PC1 in Formula (1) is obtained by polymerization of (meth)acrylic acid ester and the log P₁ is more than the log P₂, the log P value of SP1 in Formula (1) is preferably 3.7 or more and more preferably 4.2 or more.

Examples of the structure having a log P value of 1 or less include an oxyethylene structure and an oxypropylene structure. Examples of the structure having a log P value of 6 or more include a polysiloxane structure and an alkylene fluoride structure.

### (Repeating Units (21) and (22))

From the viewpoint of improving the alignment degree, it is preferable that the high-molecular-weight liquid crystal compound has a repeating unit having an electron-donating property and/or an electron-withdrawing property at a terminal. More specifically, it is more preferable that the high-molecular-weight liquid crystal compound includes a repeating unit (21) having a mesogen group and an electron-withdrawing group which is present at the terminal of the mesogen group and has a σp value of more than 0, and a repeating unit (22) having a mesogen group and a group which is present at the terminal of the mesogen group and has a σp value of 0 or less. As described above, in a case where the high-molecular-weight liquid crystal compound includes the repeating unit (21) and the repeating unit (22), the alignment degree of the light absorption anisotropic layer to be formed using the high-molecular-weight liquid crystal compound is further improved as compared with a case where the high-molecular-weight liquid crystal compound has only one of the repeating unit (21) or the repeating unit (22). The details of the reason for this are not clear, but it is presumed as follows.

That is, it is presumed that, since opposite dipole moments generated in the repeating unit (21) and the repeating unit (22) cause intermolecular interactions, an interaction between the mesogen groups in a minor axis direction is strengthened, and an orientation in which the liquid crystals are aligned is more uniform, and as a result, the degree of order of the liquid crystals is considered to be high. Accordingly, it is presumed that the aligning properties of the dichroic substance are enhanced, and thus the alignment degree of the light absorption anisotropic layer to be formed increases.

The repeating units (21) and (22) described above may be the repeating unit represented by Formula (1) described above.

The repeating unit (21) has a mesogen group and an electron-withdrawing group which is present at the terminal of the mesogen group and has a σp value of more than 0.

The above-described electron-withdrawing group is a group which is positioned at the terminal of the mesogen group and has a σp value of more than 0. Examples of the electron-withdrawing group (group having a σp value of more than 0) include a group represented by EWG in Formula (LCP-21) described below, and specific examples thereof are also the same as those described below.

The σp value of the above-described electron-withdrawing group is more than 0, and from the viewpoint of further increasing the alignment degree of the light absorption anisotropic layer, it is preferably 0.3 or more and more preferably 0.4 or more. From the viewpoint that the uniformity of alignment is excellent, the upper limit of the σp value of the above-described electron-withdrawing group is preferably 1.2 or less and more preferably 1.0 or less.

The σp value is a Hammett's substituent constant σp value (also simply referred to as “σp value”) and is a parameter showing the intensity of the electron-withdrawing property and the electron-donating property of a substituent, which numerically expresses the effect of the substituent on the acid dissociation equilibrium constant of substituted benzoic acid. The Hammett's substituent constant σp value in the present specification indicates the substituent constant σ in a case where the substituent is positioned at the para-position of benzoic acid.

As the Hammett's substituent constant σp value of each group in the present specification, a value described in the document “Hansch et al., Chemical Reviews, 1991, Vol, 91, No. 2, pp. 165 to 195” are adopted. With regard to a group in which the Hammett's substituent constant σp value is not described in the document above, the Hammett's substituent constant σp value can be calculated using software “ACD/Chem Sketch (ACD/Labs 8.00 Release Product Version: 8.08)” based on a difference between the pKa of benzoic acid and the pKa of a benzoic acid derivative having a substituent at the para-position.

The repeating unit (21) is not particularly limited as long as it has, at a side chain thereof, the mesogen group and the electron-withdrawing group which present at the terminal of the mesogen group and has a σp value of more than 0, but from the viewpoint of further increasing the alignment degree of the light absorption anisotropic layer, a repeating unit represented by Formula (LCP-21) is preferable.

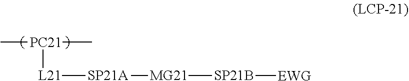

In Formula (LCP-21), PC21 represents a main chain of a repeating unit, and more specifically represents the same structure as that for PC1 in Formula (1) described above; L21 represents a single bond or a divalent linking group, and more specifically represents the same structure as that for L1 in Formula (1) described above; SP21A and SP21B each independently represent a single bond or a spacer group, and more specifically represent the same structure as that for SP1 in Formula (1) described above; MG21 represents a mesogen structure, and more specifically represents the mesogen group MG in Formula (LC) described above; and EWG represents an electron-withdrawing group having a σp value of more than 0.

The spacer group represented by SP21A and SP21B represent the same groups as Formulae S1 and S2 described above, and a group having at least one structure selected from the group consisting of an oxyethylene structure, an oxypropylene structure, a polysiloxane structure, and an alkylene fluoride structure, or a linear or branched alkylene group having 2 to 20 carbon atoms is preferable. However, the above-described alkylene group may include —O—, —O—CO—, —CO—O—, or —O—CO—O—.

From the reason of easily expressing liquid crystallinity and availability of raw materials, it is preferable that the spacer group represented by SP1 has at least one structure selected from the group consisting of an oxyethylene structure, an oxypropylene structure, a polysiloxane structure, and an alkylene fluoride structure.

It is preferable that SP21B is a single bond or a linear or branched alkylene group having 2 to 20 carbon atoms. However, the above-described alkylene group may include —O—, —O—CO—, —CO—O—, or —O—CO—O—.

Among these, from the viewpoint of further increasing the alignment degree of the light absorption anisotropic layer, the spacer group represented by SP21B is preferably a single bond. In other words, it is preferable that the repeating unit (21) has a structure in which EWG which the electron-withdrawing group in Formula (LCP-21) is directly linked to MG21 which is the mesogen group in Formula (LCP-21). In this manner, it is presumed that, in a case where the electron-withdrawing group is directly linked to the mesogen group, the intermolecular interaction due to an appropriate dipole moment works more effectively in the high-molecular-weight liquid crystal compound, and the orientation in which the liquid crystals are aligned is more uniform, and as a result, the degree of order of the liquid crystals and the alignment degree are considered to be high.

EWG represents an electron-withdrawing group having a σp value of more than 0. Examples of the electron-withdrawing group having a σp value of more than 0 include an ester group (specifically, a group represented by *—C(O)O—R^{E}), a (meth)acryloyl group, a (meth)acryloyloxy group, a carboxy group, a cyano group, a nitro group, a sulfo group, —S(O)(O)—OR^{E}, —S(O)(O)—R^{E}, —O—S(O)(O)—R^{E}, an acyl group (specifically, a group represented by *—C(O)R^{E}), an acyloxy group (specifically, a group represented by *—OC(O)R^{E}), an isocyanate group (—N═C(O)), *—C(O)N(R^{F})₂, a halogen atom, and an alkyl group substituted with any of these groups (preferably having 1 to 20 carbon atoms). In each of the above-described groups, * represents a bonding position to SP21B. R^{E} represents an alkyl group having 1 to 20 carbon atoms (preferably 1 to 4 carbon atoms and more preferably 1 or 2 carbon atoms). RF's each independently represents a hydrogen atom or an alkyl group having 1 to 20 carbon atoms (preferably 1 to 4 carbon atoms and more preferably 1 or 2 carbon atoms).

Among the above-described groups, from the viewpoint of further exhibiting the effect of the present invention, it is preferable that EWG is a group represented by *—C(O)O—R^{E}, a (meth)acryloyloxy group, a cyano group, or a nitro group.

From the viewpoint that the high-molecular-weight liquid crystal compound and the dichroic substance can be uniformly aligned while maintaining a high alignment degree of the light absorption anisotropic layer, a content of the repeating unit (21) is preferably 60% by mass or less, more preferably 50% by mass or less, and still more preferably 45% by mass or less with respect to all repeating units (100% by mass) of the high-molecular-weight liquid crystal compound.

From the viewpoint of further exhibiting the effect of the present invention, the lower limit of the content of the repeating unit (21) is preferably 1% by mass or more and more preferably 3% by mass or more with respect to all repeating units (100% by mass) of the high-molecular-weight liquid crystal compound.

In the present invention, the content of each repeating unit included in the high-molecular-weight liquid crystal compound is calculated based on the charged amount (mass) of each monomer used for obtaining each repeating unit.

The high-molecular-weight liquid crystal compound may include only one of the repeating unit (21), or two or more kinds of the repeating units (21). In a case where the high-molecular-weight liquid crystal compound includes two or more kinds of repeating units (21), there is an advantage in that solubility of the high-molecular-weight liquid crystal compound in a solvent is improved and the liquid crystal phase transition temperature is easily adjusted. In the case where the high-molecular-weight liquid crystal compound includes two or more kinds of repeating units (21), it is preferable that the total amount thereof is within the above-described range.

In the case where the high-molecular-weight liquid crystal compound includes two or more kinds of repeating units (21), a repeating unit (21) which does not include a crosslinkable group in EWG and a repeating unit (21) which includes a polymerizable group in EWG may be used in combination. In this manner, curing properties of the light absorption anisotropic layer are further improved. As the crosslinkable group, a vinyl group, a butadiene group, a (meth)acryloyl group, a (meth)acrylamide group, a vinyl acetate group, a fumaric acid ester group, a styryl group, a vinylpyrrolidone group, a maleic acid anhydride, a maleimide group, a vinyl ether group, an epoxy group, or an oxetanyl group is preferable.

In this case, from the viewpoint of balance between the curing properties and the alignment degree of the light absorption anisotropic layer, a content of the repeating unit (21) including a polymerizable group in EWG is preferably 1% to 30% by mass with respect to all repeating units (100% by mass) of the high-molecular-weight liquid crystal compound.

Hereinafter, examples of the repeating unit (21) are shown below, but the repeating unit (21) is not limited to the following repeating units.

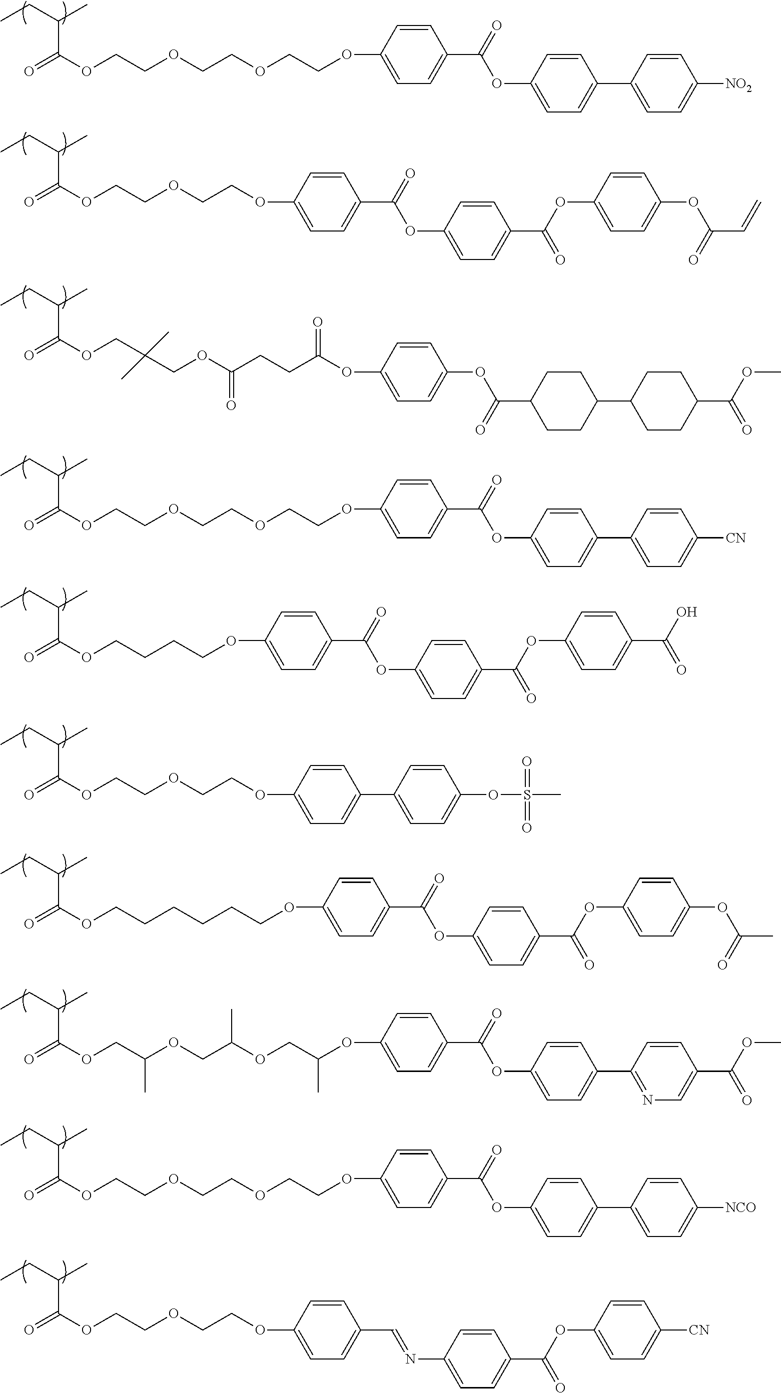

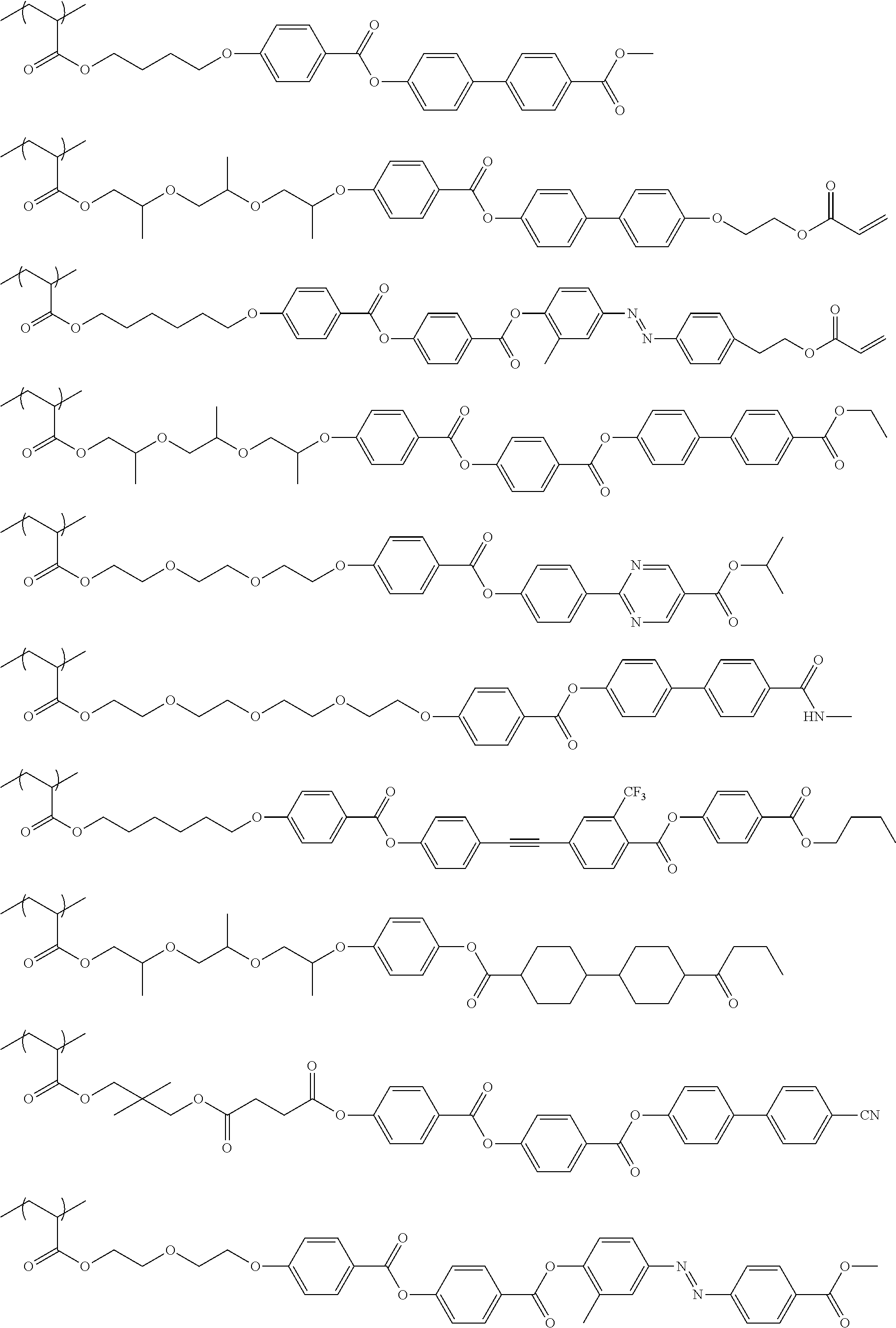

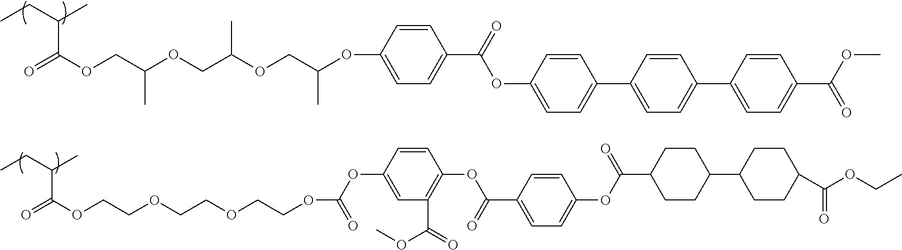

As a result of intensive studies on composition (content ratio) and electron-donating property and electron-withdrawing property of the terminal groups in the repeating unit (21) and the repeating unit (22), the present inventors have found that the alignment degree of the light absorption anisotropic layer is further increased by decreasing the content ratio of the repeating unit (21) in a case where the electron-withdrawing property of the electron-withdrawing group of the repeating unit (21) is high (that is, in a case where the σp value is large) and that the alignment degree of the light absorption anisotropic layer is further increased by increasing the content ratio of the repeating unit (21) in a case where the electron-withdrawing property of the electron-withdrawing group of the repeating unit (21) is low (that is, in a case where the op value is close to 0).

The details of the reason for this are not clear, but it is presumed as follows. That is, it is presumed that, since the intermolecular interaction due to an appropriate dipole moment works in the high-molecular-weight liquid crystal compound, the orientation in which the liquid crystals are aligned is more uniform, and as a result, the degree of order of the liquid crystals and the alignment degree of the light absorption anisotropic layer are considered to be high.

Specifically, the product of the σp value of the above-described electron-withdrawing group (EWG in Formula (LCP-21)) in the repeating unit (21) and the content ratio (on a mass basis) of the repeating unit (21) to the high-molecular-weight liquid crystal compound is preferably 0.020 to 0.150, more preferably 0.050 to 0.130, and particularly preferably 0.055 to 0.125. In a case where the above-described product is within the above-described range, the alignment degree of the light absorption anisotropic layer is further increased.

The repeating unit (22) has a mesogen group and a group which is present at the terminal of the mesogen group and has a σp value of 0 or less. In a case where the high-molecular-weight liquid crystal compound has the repeating unit (22), the high-molecular-weight liquid crystal compound and the dichroic substance can be uniformly aligned.

The mesogen group is a group representing a main skeleton of a liquid crystal molecule which contributes to liquid crystal formation, the details thereof are as described in MG of Formula (LCP-22) described below, and specific examples thereof are also the same as described below.

The above-described group is positioned at the terminal of the mesogen group and has a σp value of 0 or less. Examples of the above-described group (a group having a σp value of 0 or less) include a hydrogen atom having a σp value of 0, and a group (electron-donating group) which has a σp value of less than 0 and is represented by T22 in Formula (LCP-22) described below. Among the above-described groups, specific examples of the group (electron-donating group) having a σp value of less than 0 are the same as those for T22 in Formula (LCP-22) described below.

The σp value of the above-described group is 0 or less, and from the viewpoint that the uniformity of alignment is more excellent, it is preferably less than 0, more preferably −0.1 or less, and particularly preferably −0.2 or less. The lower limit value of the σp value of the above-described group is preferably −0.9 or more and more preferably −0.7 or more.

The repeating unit (22) is not particularly limited as long as it has, at a side chain thereof, the mesogen group and the group which is present at the terminal of the mesogen group and has a σp value of 0 or less, and from the viewpoint of further increasing the uniformity of alignment of liquid crystal, a repeating unit represented by Formula (LCP-22), which does not correspond to the above-described repeating unit represented by Formula (LCP-21), is preferable.

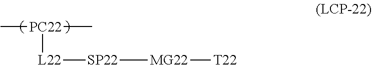

In Formula (LCP-22), PC22 represents a main chain of the repeating unit, and more specifically represents the same structure as that for PC1 in Formula (1) described above; L22 represents a single bond or a divalent linking group, and more specifically represents the same structure as that for L1 in Formula (1) described above; SP22 represents a spacer group, and more specifically represents the same structure as that for SP1 in Formula (1) described above; MG22 represents a mesogen structure, and more specifically represents the same structure as the mesogen group MG in Formula (LC) described above; and T22 represents an electron-donating group having a Hammett's substituent constant σp value of less than 0.

T22 represents an electron-donating group having a σp value of less than 0. Examples of the electron-donating group having a σp value of less than 0 include a hydroxy group, an alkyl group having 1 to 10 carbon atoms, an alkoxy group having 1 to 10 carbon atoms, and an alkylamino group having 1 to 10 carbon atoms.

In a case where the number of atoms in the main chain of T22 is 20 or less, the alignment degree of the light absorption anisotropic layer is further improved. Here, the “main chain” of T22 means the longest molecular chain bonded to MG22, and the number of hydrogen atoms is not included in the number of atoms in the main chain of T22. For example, in a case where T22 is an n-butyl group, the number of atoms in the main chain is 4, and in a case where T22 is an sec-butyl group, the number of atoms in the main chain is 3.

Hereinafter, examples of the repeating unit (22) are shown below, but the repeating unit (22) is not limited to the following repeating units.

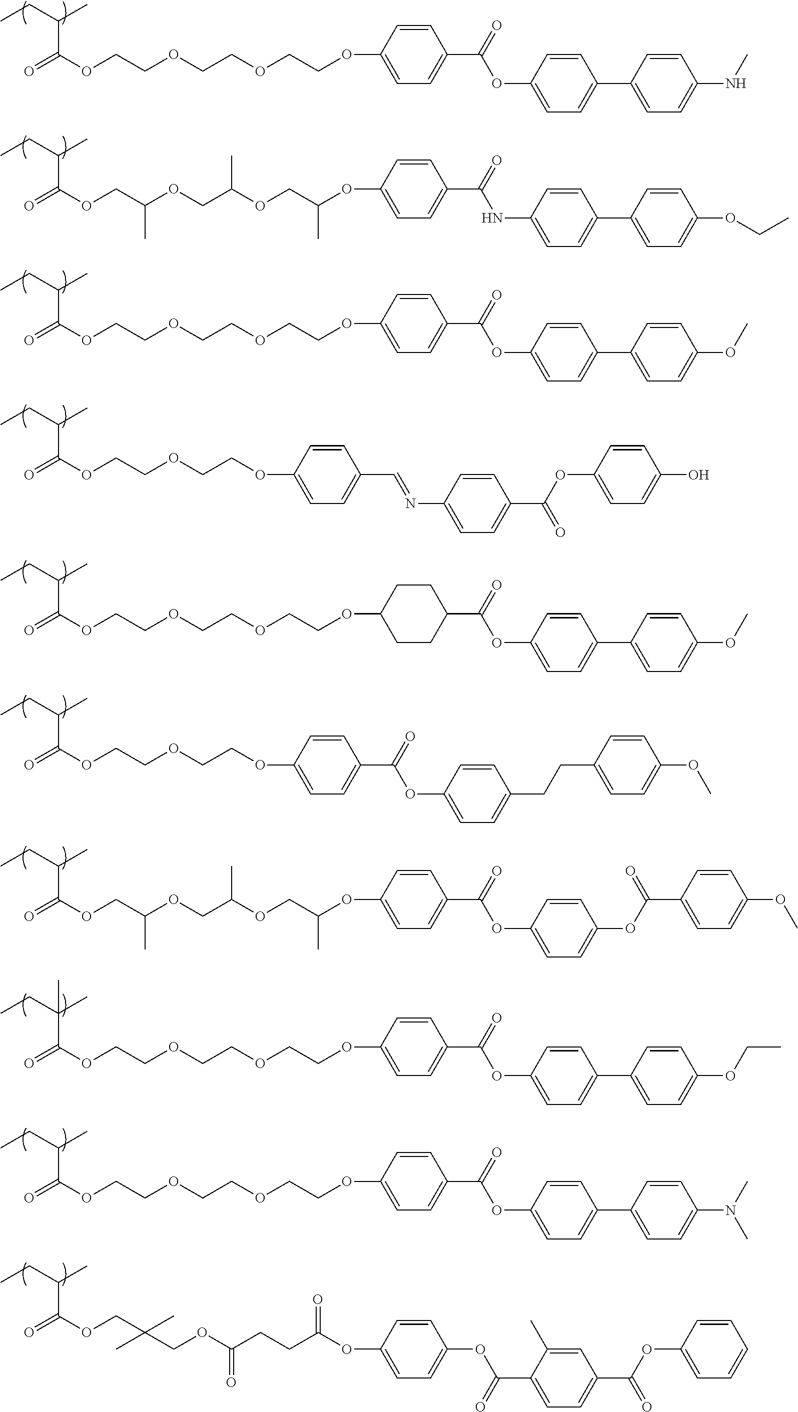

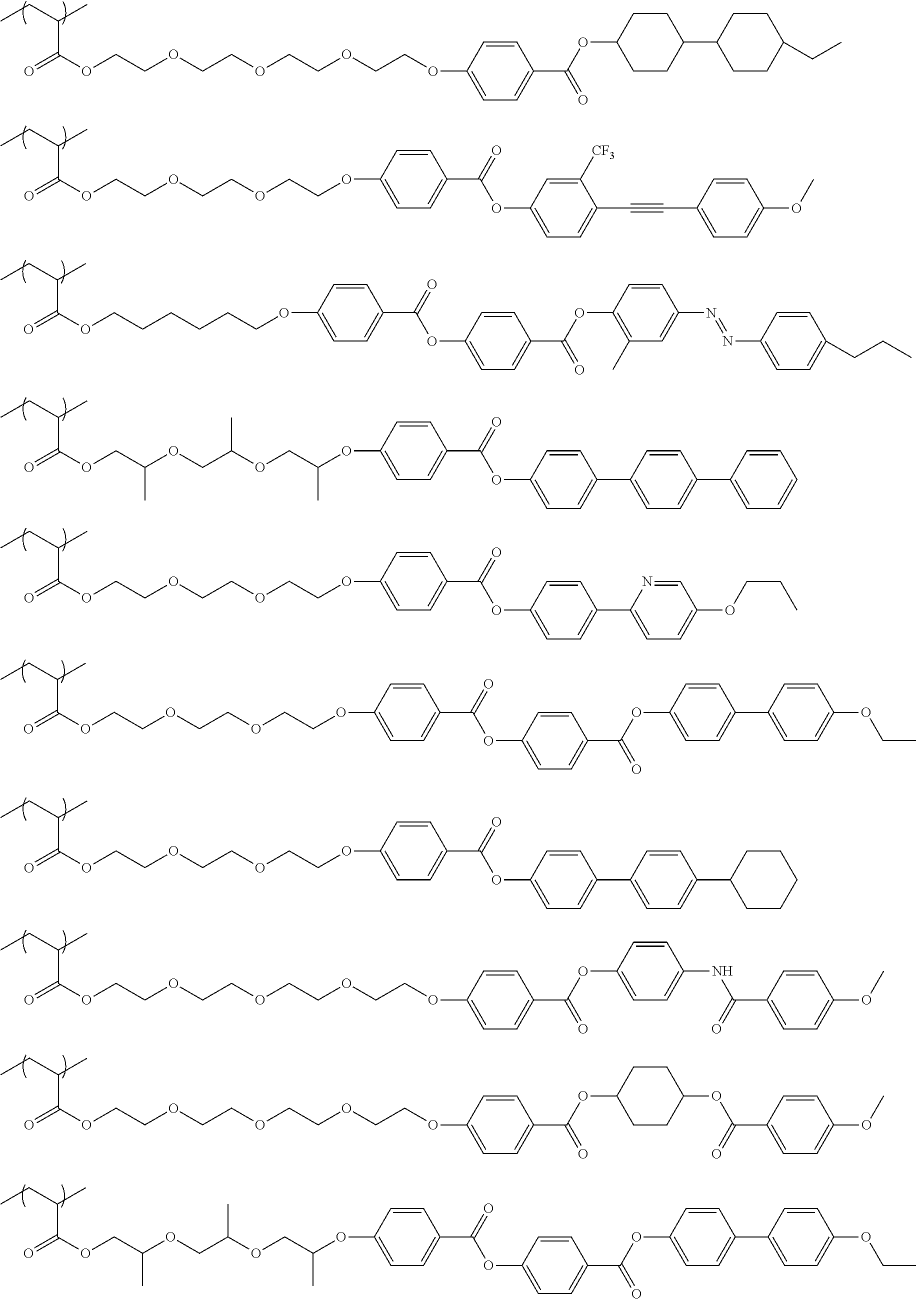

It is preferable that the structures of the repeating unit (21) and the repeating unit (22) have a part in common. It is presumed that the liquid crystals are uniformly aligned as the structures of repeating units are more similar to each other. In this manner, the alignment degree of the light absorption anisotropic layer is further improved.

Specifically, from the viewpoint of further increasing the alignment degree of the light absorption anisotropic layer, it is preferable to satisfy at least one of a condition that SP21A of Formula (LCP-21) has the same structure as that for SP22 of Formula (LCP-22), a condition that MG21 of Formula (LCP-21) has the same structure as that for MG22 of Formula (LCP-22), or a condition that L21 of Formula (LCP-21) has the same structure as that for L22 of Formula (LCP-22); more preferable to satisfy two or more of the conditions; and particularly preferable to satisfy all the conditions.

From the viewpoint that the uniformity of alignment is excellent, a content of the repeating unit (22) is preferably 50% by mass or more, more preferably 55% or more, and particularly preferably 60% or more with respect to all repeating units (100% by mass) of the high-molecular-weight liquid crystal compound.

From the viewpoint of improving the alignment degree, the upper limit value of the content of the repeating unit (22) is preferably 99% by mass or less and more preferably 97% by mass or less with respect to all repeating units (100% by mass) of the high-molecular-weight liquid crystal compound.

The high-molecular-weight liquid crystal compound may include only one of the repeating unit (22), or two or more kinds of the repeating units (22). In a case where the high-molecular-weight liquid crystal compound includes two or more kinds of repeating units (22), there is an advantage in that solubility of the high-molecular-weight liquid crystal compound in a solvent is improved and the liquid crystal phase transition temperature is easily adjusted. In the case where the high-molecular-weight liquid crystal compound includes two or more kinds of repeating units (22), it is preferable that the total amount thereof is within the above-described range.

### (Repeating Unit (3))

From the viewpoint of improving solubility in a general-purpose solvent, the high-molecular-weight liquid crystal compound can include a repeating unit (3) not containing a mesogen group. Particularly, in order to improve the solubility while suppressing a decrease in alignment degree, it is preferable that the repeating unit (3) not containing a mesogen group is a repeating unit having a molecular weight of 280 or less. As described above, the reason why the solubility is improved while a decrease in alignment degree is suppressed by including the repeating unit having a molecular weight of 280 or less, which does not contain a mesogen group, is presumed as follows.

That is, it is considered that, in a case where the high-molecular-weight liquid crystal compound includes the repeating unit (3) not containing a mesogen group in a molecular chain thereof, since a solvent is likely to enter the high-molecular-weight liquid crystal compound, the solubility is improved, but the alignment degree is decreased due to the non-mesogenic repeating unit (3). However, it is presumed that, since the molecular weight of the above-described repeating unit is small, the alignment of the repeating unit (1), the repeating unit (21), or the repeating unit (22) described above, which contains the mesogen group, is unlikely to be disturbed, and thus the decrease in the alignment degree is suppressed.

It is preferable that the above-described repeating unit (3) is a repeating unit having a molecular weight of 280 or less.

The molecular weight of the repeating unit (3) does not indicate a molecular weight of a monomer used to obtain the repeating unit (3), but indicates the molecular weight of the repeating unit (3) in a state of being incorporated into the high-molecular-weight liquid crystal compound by polymerization of the monomer.

The molecular weight of the repeating unit (3) is 280 or less, preferably 180 or less and more preferably 100 or less. The lower limit value of the molecular weight of the repeating unit (3) is commonly 40 or more, and preferably 50 or more. In a case where the molecular weight of the repeating unit (3) is 280 or less, a light absorption anisotropic layer having excellent solubility of the high-molecular-weight liquid crystal compound and having a high alignment degree can be obtained.

On the other hand, in a case where the molecular weight of the repeating unit (3) is more than 280, the alignment of the liquid crystals in the portion of the repeating unit (1), the repeating unit (21), or the repeating unit (22) is disturbed, and thus the alignment degree is decreased. In addition, since the solvent is unlikely to enter the high-molecular-weight liquid crystal compound, the solubility of the high-molecular-weight liquid crystal compound is decreased.

Specific examples of the repeating unit (3) include a repeating unit which does not include a crosslinkable group (for example, an ethylenically unsaturated group) (hereinafter, also referred to as “repeating unit (3-1)”), and a repeating unit which includes the crosslinkable group (hereinafter, also referred to as “repeating unit (3-2)”).

### Repeating Unit (3-1)

Specific examples of a monomer used for polymerization of the repeating unit (3-1) include acrylic acid [72.1], α-alkylacrylic acids (such as methacrylic acid [86.1] and itaconic acid [130.1]), esters and amides derived from these acids (such as N-i-propylacrylamide [113.2], N-n-butylacrylamide [127.2], N-t-butylacrylamide [127.2], N,N-dimethylacrylamide [99.1], N-methylmethacrylamide [99.1], acrylamide [71.1], methacrylamide [85.1], diacetoneacrylamide [169.2], acryloylmorpholine [141.2], N-methylol acrylamide [101.1], N-methylol methacrylamide [115.1], methyl acrylate [86.0], ethyl acrylate [100.1], hydroxyethyl acrylate [116.1], n-propyl acrylate [114.1], i-propyl acrylate [114.2], 2-hydroxypropyl acrylate [130.1], 2-methyl-2-nitropropyl acrylate [173.2], n-butyl acrylate [128.2], i-butyl acrylate [128.2], t-butyl acrylate [128.2], t-pentyl acrylate [142.2], 2-methoxyethyl acrylate [130.1], 2-ethoxyethyl acrylate [144.2], 2-ethoxyethoxyethyl acrylate [188.2], 2,2,2-trifluoroethyl acrylate [154.1], 2,2-dimethylbutyl acrylate [156.2], 3-methoxybutyl acrylate [158.2], ethyl carbitol acrylate [188.2], phenoxyethyl acrylate [192.2], n-pentyl acrylate [142.2], n-hexyl acrylate [156.2], cyclohexyl acrylate [154.2], cyclopentyl acrylate [140.2], benzyl acrylate [162.2], n-octyl acrylate [184.3], 2-ethylhexyl acrylate [184.3], 4-methyl-2-propylpentyl acrylate [198.3], methyl methacrylate [100.1], 2,2,2-trifluoroethyl methacrylate [168.1], hydroxyethyl methacrylate [130.1], 2-hydroxypropyl methacrylate [144.2], n-butyl methacrylate [142.2], i-butyl methacrylate [142.2], sec-butyl methacrylate [142.2], n-octyl methacrylate [198.3], 2-ethylhexyl methacrylate [198.3], 2-methoxyethyl methacrylate [144.2], 2-ethoxyethyl methacrylate [158.2], benzyl methacrylate [176.2], 2-norbornyl methyl methacrylate [194.3], 5-norbornen-2-ylmethyl methacrylate [194.3], and dimethylaminoethyl methacrylate [157.2]), vinyl esters (such as vinyl acetate [86.1]), esters derived from maleic acid or fumaric acid (such as dimethyl maleate [144.1] and diethyl fumarate [172.2]), maleimides (such as N-phenylmaleimide [173.2]), maleic acid [116.1], fumaric acid [116.1], p-styrenesulfonic acid [184.1], acrylonitrile [53.1], methacrylonitrile [67.1], dienes (such as butadiene [54.1], cyclopentadiene [66.1], and isoprene [68.1]), aromatic vinyl compounds (such as styrene [104.2], p-chlorostyrene [138.6], t-butylstyrene [160.3], and α-methylstyrene [118.2]), N-vinylpyrrolidone [111.1], N-vinyloxazolidone [113.1], N-vinyl succinimide [125.1], N-vinylformamide [71.1], N-vinyl-N-methylformamide [85.1], N-vinylacetamide [85.1], N-vinyl-N-methylacetamide [99.1], 1-vinylimidazole [94.1], 4-vinylpyridine [105.2], vinylsulfonic acid [108.1], sodium vinyl sulfonate [130.2], sodium allyl sulfonate [144.1], sodium methallyl sulfonate [158.2], vinylidene chloride [96.9], vinyl alkyl ethers (such as methyl vinyl ether [58.1]), ethylene [28.0], propylene [42.1], 1-butene [56.1], and isobutene [56.1]. The numerical value in [ ] indicates the molecular weight of the monomer.

The above-described monomer may be used alone, or in combination of two or more kinds thereof.

Among the above-described monomers, acrylic acid, α-alkylacrylic acids, esters and amides derived from these acids, acrylonitrile, methacrylonitrile, or aromatic vinyl compounds are preferable.

As monomers other than the above-described monomers, compounds described in Research Disclosure No. 1955 (July, 1980) can be used.

Hereinafter, specific examples of the repeating unit (3-1) and molecular weights thereof are shown below, but the present invention is not limited to these specific examples.

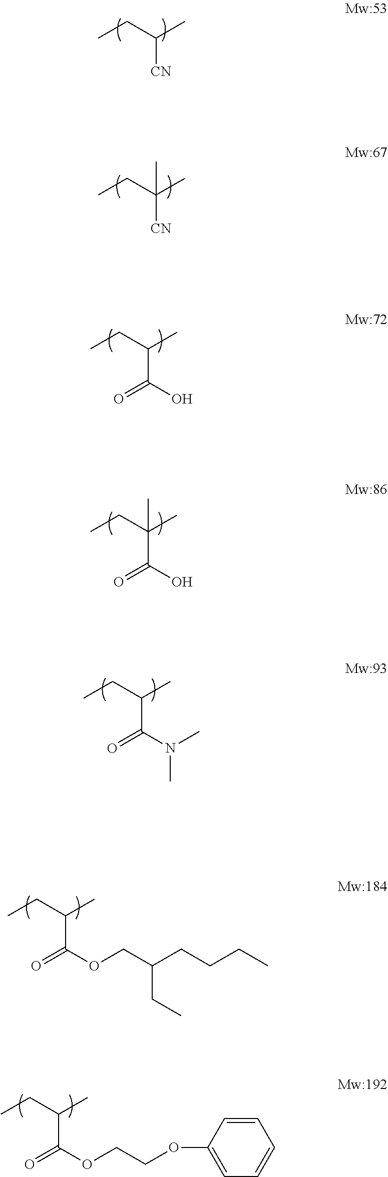

### Repeating Unit (3-2)

Specific examples of the crosslinkable group in the repeating unit (3-2) include the groups represented by Formulae (P-1) to (P-30) described above. Among these, a vinyl group, a butadiene group, a (meth)acryloyl group, a (meth)acrylamide group, a vinyl acetate group, a fumaric acid ester group, a styryl group, a vinylpyrrolidone group, a maleic acid anhydride, a maleimide group, a vinyl ether group, an epoxy group, or an oxetanyl group is more preferable. From the viewpoint of easily carrying out the polymerization, it is preferable that the repeating unit (3-2) is a repeating unit represented by Formula (3).

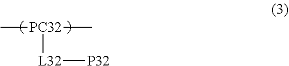

In Formula (3), PC32 represents a main chain of a repeating unit, and more specifically represents the same structure as that for PC1 in Formula (1) described above; L32 represents a single bond or a divalent linking group, and more specifically represents the same structure as that for L1 in Formula (1) described above; and P32 represents a crosslinkable group represented by any of Formulae (P-1) to (P-30) described above.

Hereinafter, specific examples of the repeating unit (3-2) and weight-average molecular weights (Mw) thereof are shown below, but the present invention is not limited to these specific examples.

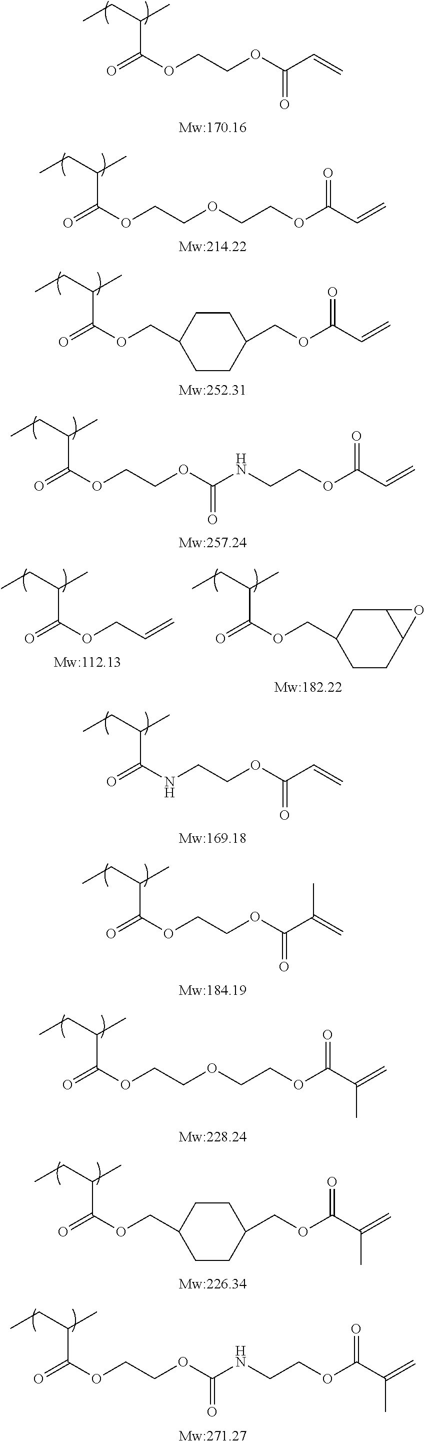

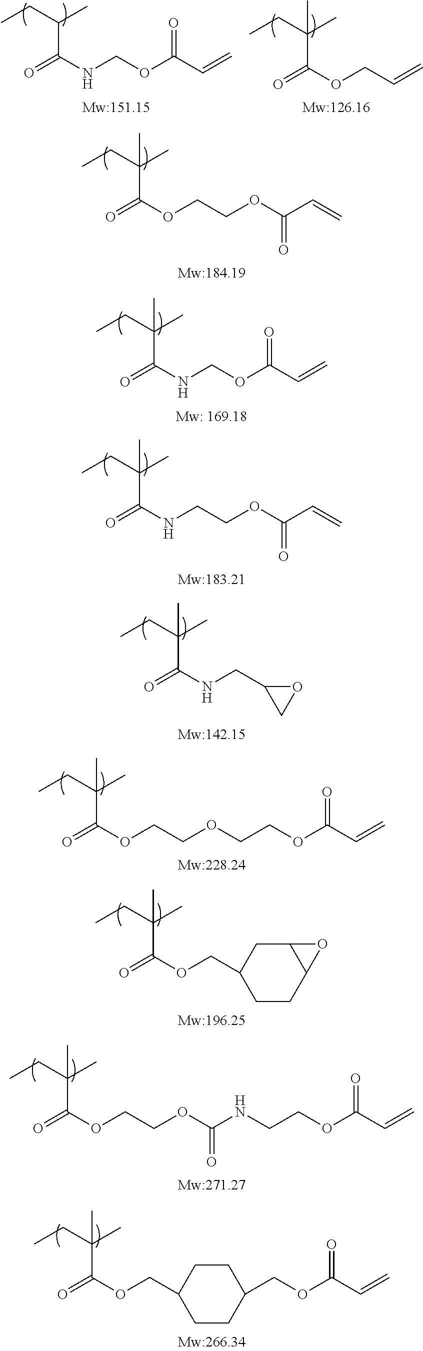

A content of the repeating unit (3) is less than 14% by mass, preferably 7% by mass or less and more preferably 5% by mass or less with respect to all repeating units (100% by mass) of the high-molecular-weight liquid crystal compound. The lower limit value of the content of the repeating unit (3) is preferably 2% by mass or more and more preferably 3% by mass or more with respect to all repeating units (100% by mass) of the high-molecular-weight liquid crystal compound. In a case where the content of the repeating unit (3) is less than 14% by mass, the alignment degree of the light absorption anisotropic layer is further improved. In a case where the content of the repeating unit (3) is 2% by mass or more, the solubility of the high-molecular-weight liquid crystal compound is further improved.

The high-molecular-weight liquid crystal compound may include only one of the repeating unit (3), or two or more kinds of the repeating units (3). In the case where the high-molecular-weight liquid crystal compound includes two or more kinds of repeating units (3), it is preferable that the total amount thereof is within the above-described range.

### (Repeating Unit (4))

From the viewpoint of improving adhesiveness and planar uniformity, the high-molecular-weight liquid crystal compound may include a repeating unit (4) having a flexible structure with a long molecular chain (SP4 in Formula (4) described below). The reason for this is presumed as follows.

That is, in a case where the high-molecular-weight liquid crystal compound has such a flexible structure with a long molecular chain, entanglement of the molecular chains constituting the high-molecular-weight liquid crystal compound is likely to occur, and aggregation destruction of the light absorption anisotropic layer (specifically, destruction of the light absorption anisotropic layer itself) is suppressed. As a result, it is presumed that adhesiveness between the light absorption anisotropic layer and an underlayer (for example, a base material or an alignment film) is improved. In addition, it is considered that a decrease in planar uniformity occurs due to low compatibility between the dichroic substance and the high-molecular-weight liquid crystal compound. That is, it is considered that, in a case where the compatibility between the dichroic substance and the high-molecular-weight liquid crystal compound is not sufficient, a planar defect (alignment defect) having the dichroic substance to be precipitated as a nucleus occurs. On the other hand, it is presumed that, in the case where the high-molecular-weight liquid crystal compound has such a flexible structure with a long molecular chain, a light absorption anisotropic layer in which precipitation of the dichroic substance is suppressed and the planar uniformity is excellent is obtained. Here, the expression “planar uniformity is excellent” denotes that the alignment defect occurring in a case where the liquid crystal composition containing the high-molecular-weight liquid crystal compound is repelled on the underlayer (for example, the base material or the alignment film) is less likely to occur.

The above-described repeating unit (4) is a repeating unit represented by Formula (4).

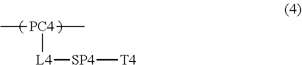

In Formula (4), PC4 represents a main chain of a repeating unit, and more specifically represents the same structure as that for PC1 in Formula (1) described above; L4 represents a single bond or a divalent linking group, and more specifically represents the same structure as that for L1 in Formula (1) described above (preferably a single bond); SP4 represents an alkylene group having 10 or more atoms in the main chain; and T4 represents a terminal group, and more specifically represents the same structure as that for T1 in Formula (1) described above.

Specific examples and suitable aspects of PC4 are the same as those for PC1 in Formula (1), and thus the description thereof will not be repeated.

From the viewpoint of further exhibiting the effect of the present invention, L4 is preferably a single bond.

In Formula (4), SP4 represents an alkylene group having 10 or more atoms in the main chain. Here, one or more of —CH₂-'s constituting the alkylene group represented by SP4 may be replaced with “SP—C” described above, and particularly preferably replaced with at least one group selected from the group consisting of —O—, —S—, —N(R²¹)—, —C(═O)—, —C(═S)—, —C(R²²)═C(R²³)—, an alkynylene group, —Si(R²⁴)(R²³)—, —N═N—, —C(R²⁶)═N—N═C(R²⁷), —C(R²⁸)═N—, and S(═O)₂—. In addition, R²¹ to R²⁸ each independently represent a hydrogen atom, a halogen atom, a cyano group, a nitro group, or a linear or branched alkyl group having 1 to 10 carbon atoms. In addition, the hydrogen atoms included in one or more of —CH₂-'s constituting the alkylene group represented by SP4 may be replaced with “SP—H” described above.

The number of atoms in the main chain of SP4 is 10 or more, and from the viewpoint of obtaining a light absorption anisotropic layer in which at least one of the adhesiveness or the planar uniformity is more excellent, the number of atoms thereof is preferably 15 or more and more preferably 19 or more. In addition, from the viewpoint of obtaining a light absorption anisotropic layer with a more excellent alignment degree, the upper limit of the number of atoms in the main chain of SP2 is preferably 70 or less, more preferably 60 or less, and particularly preferably 50 or less.

Here, the “main chain” of SP4 means a partial structure required for directly linking L4 and T4 to each other, and the “number of atoms in the main chain” means the number of atoms constituting the partial structure. In other words, the “main chain” of SP4 is a partial structure in which the number of atoms linking L4 and T4 to each other is the smallest. For example, in a case where SP4 is a 3,7-dimethyldecanyl group, the number of atoms in the main chain is 10, and in a case where SP4 is a 4,6-dimethyldodecanyl group, the number of atoms in the main chain is 12. In addition, in Formula (4-1), the inside of the frame shown by the dotted quadrangle corresponds to SP4, and the number of atoms in the main chain of SP4 (corresponding to the total number of atoms circled by the dotted line) is 11.

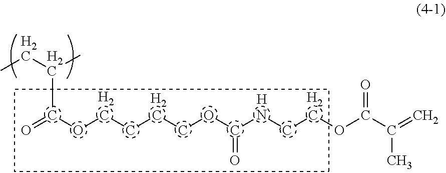

The alkylene group represented by SP4 may be linear or branched.

From the viewpoint of obtaining a light absorption anisotropic layer with a more excellent alignment degree, the number of carbon atoms in the alkylene group represented by SP4 is preferably 8 to 80, more preferably 15 to 80, still more preferably 25 to 70, and particularly preferably 25 to 60.

From the viewpoint of obtaining a light absorption anisotropic layer with more excellent adhesiveness and planar uniformity, it is preferable that one or more of —CH₂-'s constituting the alkylene group represented by SP4 are replaced with “SP—C” described above.

In addition, in a case of a plurality of —CH₂-'s constituting the alkylene group represented by SP4, from the viewpoint of obtaining a light absorption anisotropic layer with more excellent adhesiveness and planar uniformity, it is more preferable that only some of the plurality of —CH₂-'s are replaced with “SP—C” described above.

Among “SP—C”, at least one group selected from the group consisting of —O—, —S—, —N(R²¹)—, —C(═O)—, —C(═S)—, —C(R²²)═C(R²³)—, an alkynylene group, —Si(R²⁴)(R²³)—, —N═N—, —C(R²⁶)═N—N═C(R²⁷)—, —C(R²⁸)═N—, and S(═O)₂— is preferable; and from the viewpoint of obtaining a light absorption anisotropic layer with more excellent adhesiveness and planar uniformity, at least one group selected from the group consisting of —O—, —N(R²¹)—, —C(═O)—, and S(═O)₂— is more preferable, and at least one group selected from the group consisting of —O—, —N(R²¹)—, and C(═O)— is particularly preferable.

Particularly, it is preferable that SP4 is a group having at least one selected from the group consisting of an oxyalkylene structure in which one or more of —CH₂-'s constituting an alkylene group are replaced with —O—, an ester structure in which one or more of —CH₂—CH₂-'s constituting an alkylene group are replaced with —O— or C(═O)—, and a urethane bond in which one or more of —CH₂—CH₂—CH₂-'s constituting an alkylene group are replaced with —O—, —C(═O)—, or NH—.

The hydrogen atoms included in one or more of —CH₂-'s constituting the alkylene group represented by SP4 may be replaced with “SP—H” described above. In this case, one or more hydrogen atoms included in —CH₂— may be replaced with “SP—H”. That is, only one hydrogen atom included in —CH₂— may be replaced with “SP—H”, or all (two) hydrogen atoms included in —CH₂— may be replaced with “SP—H”.

Among “SP—H”, at least one group selected from the group consisting of a halogen atom, a cyano group, a nitro group, a hydroxy group, a linear alkyl group having 1 to 10 carbon atoms, a branched alkyl group having 1 to 10 carbon atoms, and a halogenated alkyl group having 1 to 10 carbon atoms is preferable; and at least one group selected from the group consisting of a hydroxy group, a linear alkyl group having 1 to 10 carbon atoms, and a branched alkyl group having 1 to 10 carbon atoms is still more preferable.

As described above, T4 represents the same terminal group as that for T1, and is preferably a hydrogen atom, a methyl group, a hydroxy group, a carboxy group, a sulfonic acid group, a phosphoric acid group, a boronic acid group, an amino group, a cyano group, a nitro group, a phenyl group which may have a substituent, or -L-CL (L represents a single bond or a divalent linking group, and specific examples of the divalent linking group are the same as those for LW and SPW described above; CL represents a crosslinkable group, examples thereof include the group represented by Q1 or Q2 described above, and a crosslinkable group represented by any of Formulae (P-1) to (P-30) is preferable), in which CL is preferably a vinyl group, a butadiene group, a (meth)acryloyl group, a (meth)acrylamide group, a vinyl acetate group, a fumaric acid ester group, a styryl group, a vinylpyrrolidone group, a maleic acid anhydride, a maleimide group, a vinyl ether group, an epoxy group, or an oxetanyl group.

The epoxy group may be an epoxycycloalkyl group, and from the viewpoint that the effect of the present invention is more excellent, the number of carbon atoms in a cycloalkyl group moiety of the epoxycycloalkyl group is preferably 3 to 15, more preferably 5 to 12, and particularly preferably 6 (that is, it is still more preferable that the epoxycycloalkyl group is an epoxycyclohexyl group).

Examples of a substituent of the oxetanyl group include an alkyl group having 1 to 10 carbon atoms, and from the viewpoint that the effect of the present invention is more excellent, an alkyl group having 1 to 5 carbon atoms is preferable. The alkyl group as the substituent of the oxetanyl group may be linear or branched, but is preferably linear from the viewpoint that the effect of the present invention is more excellent.

Examples of a substituent of the phenyl group include a boronic acid group, a sulfonic acid group, a vinyl group, and an amino group, and from the viewpoint that the effect of the present invention is more excellent, a boronic acid group is preferable.

Specific examples of the repeating unit (4) include the following structures, but the present invention is not limited thereto. In the following specific examples, n1 represents an integer of 2 or more, and n2 represents an integer of 1 or more.

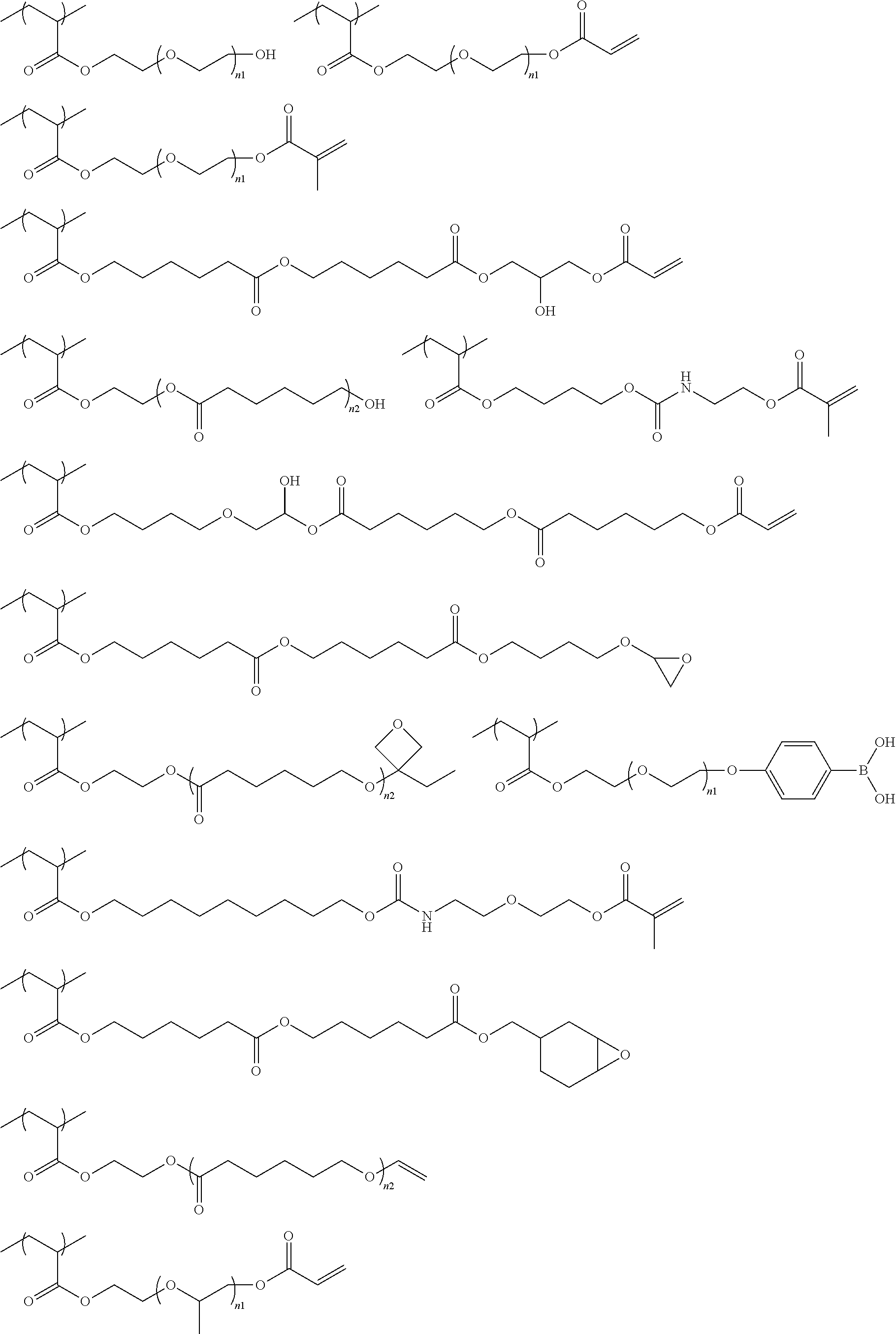

A content of the repeating unit (4) is preferably 2% to 20% by mass and more preferably 3% to 18% by mass with respect to all repeating units (100% by mass) of the high-molecular-weight liquid crystal compound. In a case where the content of the repeating unit (4) is 2% by mass or more, a light absorption anisotropic layer having more excellent adhesiveness is obtained. In addition, in a case where the content of the repeating unit (4) is 20% by mass or less, a light absorption anisotropic layer having more excellent planar uniformity is obtained.

The high-molecular-weight liquid crystal compound may include only one of the repeating unit (4), or two or more kinds of the repeating units (4). In a case where the high-molecular-weight liquid crystal compound includes two or more kinds of repeating units (4), the above-described content of the repeating unit (4) indicates the total content of the repeating units (4).

### (Repeating Unit (5))

From the viewpoint of the planar uniformity, the high-molecular-weight liquid crystal compound can include a repeating unit (5) to be introduced by polymerizing a polyfunctional monomer. Particularly, in order to improve the planar uniformity while suppressing a decrease in alignment degree, it is preferable that the high-molecular-weight liquid crystal compound includes 10% by mass or less of the repeating unit (5) to be introduced by polymerizing a polyfunctional monomer. As described above, the reason why the planar uniformity can be improved while a decrease in alignment degree is suppressed by including 10% by mass or less of the repeating unit (5) is presumed as follows.

The repeating unit (5) is a unit to be introduced to the high-molecular-weight liquid crystal compound by polymerizing a polyfunctional monomer. Therefore, it is considered that the high-molecular-weight liquid crystal compound includes a high-molecular-weight body in which a three-dimensional crosslinking structure is formed by the repeating unit (5). Here, since the content of the repeating unit (5) is small, the content of the high-molecular-weight body including the repeating unit (5) is considered to be very small.

It is presumed that a light absorption anisotropic layer in which cissing of the liquid crystal composition is suppressed and the planar uniformity is excellent is obtained due to the presence of a very small amount of the high-molecular-weight body with the three-dimensional crosslinking structure formed as described above.

In addition, it is presumed that the effect of suppressing a decrease in alignment degree can be maintained because the content of the high-molecular-weight body is very small.

It is preferable that the above-described repeating unit (5) to be introduced by polymerizing a polyfunctional monomer is a repeating unit represented by Formula (5).

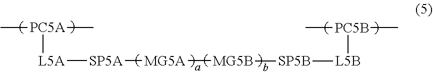

In Formula (5), PC5A and PC5B represent the main chain of the repeating unit, and more specifically represent the same structure as that for PC1 in Formula (1) described above; L5A and L5B represent a single bond or a divalent linking group, and more specifically represents the same structure as that for L1 in Formula (1) described above; SP5A and SP5B represent a spacer group, and more specifically represents the same structure as that for SP1 in Formula (1) described above; MG5A and MG5B represent a mesogen structure, and more specifically represent the same structure as that for the mesogen group MG in Formula (LC) described above; and a and b represent an integer of 0 or 1.

PC5A and PC5B may be the same group or groups different from each other, but from the viewpoint of further improving the alignment degree of the light absorption anisotropic layer, it is preferable that PC5A and PC5B are the same group.

Both L5A and L5B may be a single bond, the same group, or groups different from each other, but from the viewpoint of further improving the alignment degree of the light absorption anisotropic layer, both L5A and L5B are preferably a single bond or the same group, and more preferably the same group.

Both SP5A and SP5B may be a single bond, the same group, or groups different from each other, but from the viewpoint of further improving the alignment degree of the light absorption anisotropic layer, both SP5A and SP5B are preferably a single bond or the same group, and more preferably the same group.

Here, the same group in Formula (5) means that the chemical structures thereof are the same regardless of the orientation in which each group is bonded. For example, even in a case where SP5A is *—CH₂—CH₂—O—** (* represents a bonding position to L5A, and ** represents a bonding position to MG5A) and SP5B is *—O—CH₂—CH₂—** (* represents a bonding position to MG5B, and ** represents a bonding position to L5B), SP5A and SP5B are the same group.

a and b are each independently an integer of 0 or 1, and preferably 1 from the viewpoint of further improving the alignment degree of the light absorption anisotropic layer.

a and b may be the same or different from each other, but from the viewpoint of further improving the alignment degree of the light absorption anisotropic layer, it is preferable that both a and b are 1.

From the viewpoint of further improving the alignment degree of the light absorption anisotropic layer, the sum of a and b is preferably 1 or 2 (that is, the repeating unit represented by Formula (5) has a mesogen group), and more preferably 2.

From the viewpoint of further improving the alignment degree of the light absorption anisotropic layer, it is preferable that the partial structure represented by -(MG5A), -(MG5B)_{b}— has a cyclic structure. In this case, from the viewpoint of further improving the alignment degree of the light absorption anisotropic layer, the number of cyclic structures in the partial structure represented by -(MG5A2)ₐ-(MG5B)_{b}— is preferably 2 or more, more preferably 2 to 8, still more preferably 2 to 6, and particularly preferably 2 to 4.

From the viewpoint of further improving the alignment degree of the light absorption anisotropic layer, the mesogen groups represented by MG5A and MG5B each independently preferably include one or more cyclic structures, more preferably include 2 to 4 cyclic structures, still more preferably include 2 or 3 cyclic structures, and particularly preferably include 2 cyclic structures.

Specific examples of the cyclic structure include an aromatic hydrocarbon group, a heterocyclic group, and an alicyclic group, and among these, an aromatic hydrocarbon group or an alicyclic group is preferable.

MG5A and MG5B may be the same group or groups different from each other, but from the viewpoint of further improving the alignment degree of the light absorption anisotropic layer, it is preferable that MG5A and MG5B are the same group.

As the mesogen group represented by MG5A and MG5B, from the viewpoint of expressing the liquid crystallinity, adjusting a liquid crystal phase transition temperature, availability of raw materials, and synthetic suitability, and from the viewpoint that the effect of the present invention is more excellent, the mesogen group MG in Formula (LC) described above is preferable.

Particularly, in the repeating unit (5), it is preferable that PC5A and PC5B are the same group, both L5A and L5B are a single bond or the same group, both SP5A and SP5B are a single bond or the same group, and MG5A and MG5B are the same group. In this manner, the alignment degree of the light absorption anisotropic layer is further improved.

A content of the repeating unit (5) is preferably 10% by mass or less, more preferably 0.001% to 5% by mass, and still more preferably 0.05% to 3% by mass with respect to the content (100% by mass) of all repeating units of the high-molecular-weight liquid crystal compound.

The high-molecular-weight liquid crystal compound may include only one of the repeating unit (5), or two or more kinds of the repeating units (5). In the case where the high-molecular-weight liquid crystal compound includes two or more kinds of repeating units (5), it is preferable that the total amount thereof is within the above-described range.

### (Star-Shaped Polymer)

The high-molecular-weight liquid crystal compound may be a star-shaped polymer. The star-shaped polymer in the present invention means a polymer having three or more polymer chains extending from the nucleus, and is specifically represented by Formula (6).

The star-shaped polymer represented by Formula (6) as the high-molecular-weight liquid crystal compound can form a light absorption anisotropic layer having a high alignment degree while having high solubility (excellent solubility in a solvent).

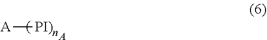

In Formula (6), n_{A} represents an integer of 3 or greater, and preferably an integer of 4 or more. The upper limit value of n_{A} is not limited thereto, but is commonly 12 or less and preferably 6 or less.

A plurality of PI's each independently represent a polymer chain having any of the repeating units represented by Formulae (1), (21), (22), (3), (4), and (5) described above. However, at least one of the plurality of PI's represents a polymer chain having the repeating unit represented by Formula (1) described above.

A represents an atomic group which is the nucleus of the star-shaped polymer. Specific examples of A include structures obtained by removing hydrogen atoms from thiol groups of a polyfunctional thiol compound, described in paragraphs [0052] to [0058] of JP2011-074280A, paragraphs [0017] to [0021] of JP2012-189847A, paragraphs [0012] to [0024] of JP2013-031986A, and paragraphs [0118] to [0142] of JP2014-104631A. In this case, A and PI are bonded to each other through a sulfide bond.

The number of thiol groups in the above-described polyfunctional thiol compound from which A is derived is preferably 3 or more and more preferably 4 or more. The upper limit value of the number of thiol groups in the polyfunctional thiol compound is commonly 12 or less and preferably 6 or less.

Specific examples of the polyfunctional thiol compound are shown below.

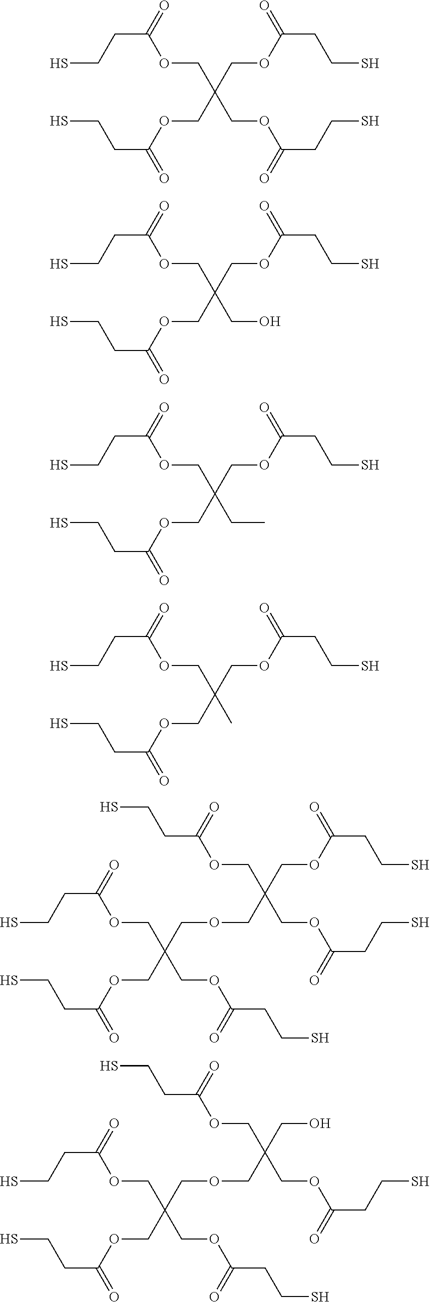

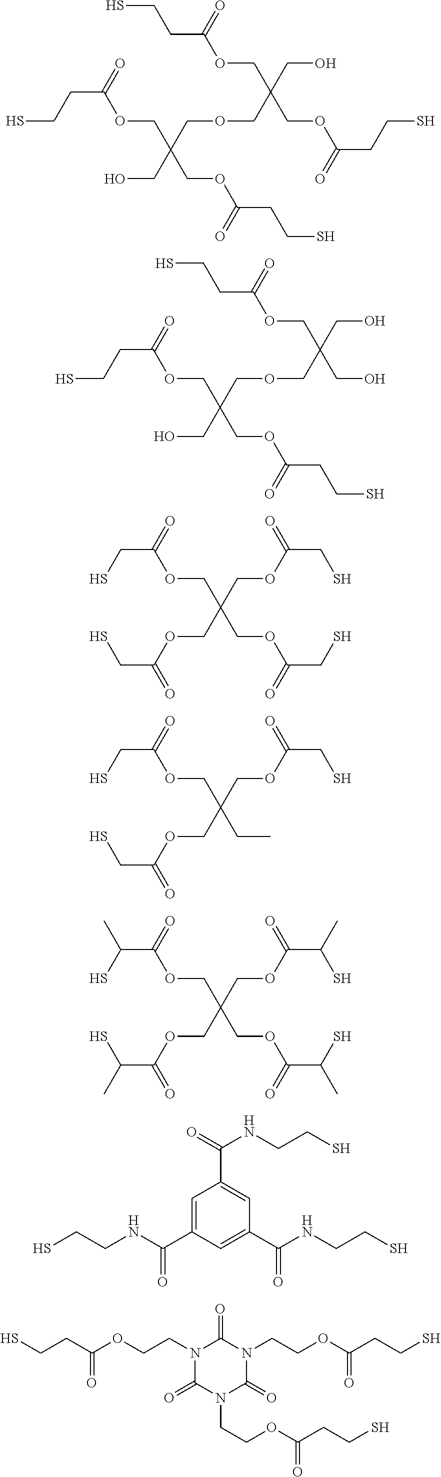

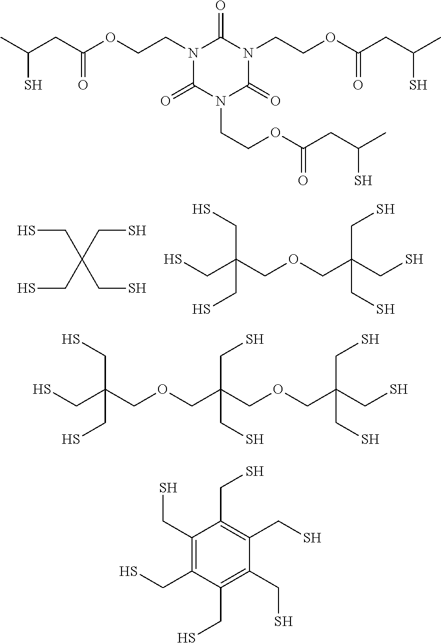

From the viewpoint of improving the alignment degree, the high-molecular-weight liquid crystal compound may be a thermotropic liquid crystal and a crystalline polymer.

### (Thermotropic Liquid Crystal)

A thermotropic liquid crystal is a liquid crystal which shows transition to a liquid crystal phase due to a change in temperature.

The specific compound is the thermotropic liquid crystal, and the thermotropic liquid crystal may exhibit any of a nematic phase or a smectic phase, but from the reason that the alignment degree of the light absorption anisotropic layer is further increased and haze is unlikely to be observed (haze is better), it is preferable that the thermotropic liquid crystal exhibits at least a nematic phase.

A temperature range showing the nematic phase is preferably room temperature (23° C.) to 450° C. from the viewpoint that the alignment degree of the light absorption anisotropic layer is further increased and the haze is unlikely to be observed, and more preferably 40° C. to 400° C. from the viewpoint of handleability and manufacturing suitability.

### (Crystalline Polymer)

The crystalline polymer is a polymer showing a transition to a crystal phase due to a change in temperature. The crystalline polymer may show a glass transition other than the transition to the crystal phase.

From the viewpoint that the alignment degree of the light absorption anisotropic layer is further increased and the haze is unlikely to be observed, it is preferable that the crystalline polymer is a high-molecular-weight liquid crystal compound which has a transition from a crystal phase to a liquid crystal phase in a case of being heated (glass transition may be present in the middle of the transition), or a high-molecular-weight liquid crystal compound which has a transition to a crystal phase in a case where the temperature is lowered after entering a liquid crystal state by being heated (glass transition may be present in the middle of the transition).

The presence or absence of crystallinity of the high-molecular-weight liquid crystal compound is evaluated as follows.

Two light absorption anisotropic layers of an optical microscope (ECLIPSE E600 POL, manufactured by Nikon Corporation) are arranged to be orthogonal to each other, and a sample table is set between the two light absorption anisotropic layers. A small amount of the high-molecular-weight liquid crystal compound is placed on slide glass, and the slide glass is set on a hot stage placed on the sample table. While the state of the sample is observed, the temperature of the hot stage is increased to a temperature at which the high-molecular-weight liquid crystal compound exhibits liquid crystallinity, and the high-molecular-weight liquid crystal compound is allowed to enter a liquid crystal state. After the high-molecular-weight liquid crystal compound enters the liquid crystal state, the behavior of the liquid crystal phase transition is observed while the temperature of the hot stage is gradually lowered, and the temperature of the liquid crystal phase transition is recorded. In a case where the high-molecular-weight liquid crystal compound exhibits a plurality of liquid crystal phases (for example, a nematic phase and a smectic phase), all the transition temperatures are also recorded.

Next, approximately 5 mg of a sample of the high-molecular-weight liquid crystal compound is put into an aluminum pan, and the pan is covered and set on a differential scanning calorimeter (DSC) (an empty aluminum pan is used as a reference). The high-molecular-weight liquid crystal compound measured in the above-described manner is heated to a temperature at which the compound exhibits a liquid crystal phase, and the temperature is maintained for 1 minute. Thereafter, the calorific value is measured while the temperature is lowered at a rate of 10° C./min. An exothermic peak is confirmed from the obtained calorific value spectrum.

As a result, in a case where an exothermic peak is observed at a temperature other than the liquid crystal phase transition temperature, it can be said that the exothermic peak is a peak due to crystallization and the high-molecular-weight liquid crystal compound has crystallinity.

On the other hand, in a case where an exothermic peak is not observed at a temperature other than the liquid crystal phase transition temperature, it can be said that the high-molecular-weight liquid crystal compound does not have crystallinity.

A method of obtaining the crystalline polymer is not particularly limited, but as a specific example, a method of using a high-molecular-weight liquid crystal compound including the above-described repeating unit (1) is preferable, and a method of using a suitable aspect among high-molecular-weight liquid crystal compounds having the described above repeating unit (1) is more preferable.

### Crystallization Temperature

From the viewpoint that the alignment degree of the light absorption anisotropic layer is further increased and the haze is unlikely to be observed, the crystallization temperature of the high-molecular-weight liquid crystal compound is preferably −50° C. or higher and lower than 150° C., more preferably 120° C. or lower, still more preferably −20° C. or higher and lower than 120° C., and particularly preferably 95° C. or lower. From the viewpoint of reducing haze, the above-described crystallization temperature of the high-molecular-weight liquid crystal compound is preferably lower than 150° C.

The crystallization temperature is a temperature of an exothermic peak due to crystallization in the above-described DSC.

### (Molecular Weight)

From the viewpoint that the effect of the present invention is more excellent, a weight-average molecular weight (Mw) of the high-molecular-weight liquid crystal compound is preferably 1000 to 500,000 and more preferably 2,000 to 300,000. In a case where the Mw of the high-molecular-weight liquid crystal compound is within the above-described range, the high-molecular-weight liquid crystal compound is easily handled.

In particular, from the viewpoint of suppressing cracking during coating, the weight-average molecular weight (Mw) of the high-molecular-weight liquid crystal compound is preferably 10,000 or more and more preferably 10,000 to 300,000.

In addition, from the viewpoint of temperature latitude of the alignment degree, the weight-average molecular weight (Mw) of the high-molecular-weight liquid crystal compound is preferably less than 10,000 and preferably 2,000 or more and less than 10,000.

Here, the weight-average molecular weight and the number-average molecular weight in the present invention are values measured by a gel permeation chromatography (GPC) method.
Solvent (eluent): N-methylpyrrolidone
Device name: TOSOH HLC-8220GPC
Column: using three columns of TOSOH TSKgel Super AWM-H (6 mm×15 cm) connected
Column temperature: 25° C.
Sample concentration: 0.1% by mass
Flow rate: 0.35 mL/min
Calibration curve: TSK standard polystyrene (manufactured by TOSOH Corporation), calibration curves of 7 samples with Mw of 2,800,000 to 1,050 (Mw/Mn=1.03 to 1.06) are used

The high-molecular-weight liquid crystal compound may exhibit nematic or smectic liquid crystallinity, but it is preferable that the high-molecular-weight liquid crystal compound exhibits at least the nematic liquid crystallinity.

The temperature range at which the nematic phase is exhibited is preferably 0° C. to 450° C., and from the viewpoint of handleability and manufacturing suitability, preferably 30° C. to 400° C.

### <Content>

From the viewpoint that the effect of the present invention is more excellent, a content of the liquid crystal compound is preferably 10% to 97% by mass, more preferably 40% to 95% by mass, and still more preferably 60% to 95% by mass with respect to the total solid content (100% by mass) of the liquid crystal composition.

In a case where the liquid crystal compound includes a high-molecular-weight liquid crystal compound, a content of the high-molecular-weight liquid crystal compound is preferably 10% to 99% by mass, more preferably 30% to 95% by mass, and still more preferably 40% to 90% by mass with respect to the total mass (100% by mass) of the liquid crystal compound.

In a case where the liquid crystal compound includes a low-molecular-weight liquid crystal compound, a content of the low-molecular-weight liquid crystal compound is preferably 1% to 90% by mass, more preferably 5% to 70% by mass, and still more preferably 10% to 60% by mass with respect to the total mass (100% by mass) of the liquid crystal compound.

In a case where the liquid crystal compound includes both the high-molecular-weight liquid crystal compound and the low-molecular-weight liquid crystal compound, from the viewpoint that the effect of the present invention is more excellent, a mass ratio (low-molecular-weight liquid crystal compound/high-molecular-weight liquid crystal compound) of the content of the low-molecular-weight liquid crystal compound to the content of the high-molecular-weight liquid crystal compound is preferably 5/95 to 70/30 and more preferably 10/90 to 50/50.

Here, the “solid content in the liquid crystal composition” denotes a component excluding a solvent, and specific examples of the solid content include the above-described liquid crystal compound, and a dichroic substance, a polymerization initiator, an interface improver described later.

### <Dichroic Substance>

The liquid crystal composition further contains a dichroic substance.

In the present invention, the dichroic substance means a coloring agent having different absorbances depending on directions. The dichroic substance may or may not exhibit liquid crystallinity.

The dichroic substance is not particularly limited, and examples thereof include a visible light absorbing material (dichroic coloring agent), a light emitting material (such as a fluorescent material or a phosphorescent material), an ultraviolet absorbing material, an infrared absorbing material, a non-linear optical material, a carbon nanotube, and an inorganic material (for example, a quantum rod). In addition, known dichroic substances (dichroic coloring agents) of the related art can be used.

Specific examples thereof include those described in paragraphs [0067] to [0071] of JP2013-228706A, paragraphs [0008] to [0026] of JP2013-227532A, paragraphs [0008] to [0015] of JP2013-209367A, paragraphs [0045] to [0058] of JP2013-14883A, paragraphs [0012] to [0029] of JP2013-109090A, paragraphs [0009] to [0017] of JP2013-101328A, paragraphs [0051] to [0065] of JP2013-37353A, paragraphs [0049] to [0073] of JP2012-63387A, paragraphs [0016] to [0018] of JP1999-305036A (JP-H11-305036A), paragraphs [0009] to [0011] of JP2001-133630A, paragraphs [0030] to [0169] of JP2011-215337A, paragraphs [0021] to [0075] of JP2010-106242A, paragraphs [0011] to [0025] of JP2010-215846A, paragraphs [0017] to [0069] of JP2011-048311A, paragraphs [0013] to [0133] of JP2011-213610A, paragraphs [0074] to [0246] of JP2011-237513A, paragraphs [0005] to [0051] of JP2016-006502A, paragraphs [0014] to [0032] of JP2018-053167A, paragraphs [0014] to [0033] of JP2020-11716A, paragraphs [0005] to [0041] of WO2016/060173A, paragraphs [0008] to [0062] of WO2016/136561A, paragraphs [0014] to [0033] of WO2017/154835A, paragraphs [0014] to [0033] of WO2017/154695A, paragraphs [0013] to [0037] of WO2017/195833A, paragraphs [0014] to [0034] of WO2018/164252A, paragraphs [0021] to [0030] of WO2018/186503A, paragraphs [0043] to [0063] of WO2019/189345A, paragraphs [0043] to [0085] of WO2019/225468A, paragraphs [0050] to [0074] of WO2020/004106A, and paragraphs [0015] to [0038] of WO2021/044843A.

In the present invention, it is preferable to use a dichroic organic coloring agent as the dichroic substance.

The dichroic organic coloring agent is not particularly limited, but a dichroic azo coloring agent compound is preferable, and a dichroic azo coloring agent compound used for a so-called coating-type polarizer is suitably used.

The dichroic azo coloring agent compound is not particularly limited, and known dichroic azo coloring agents in the related art can be used.

Here, the dichroic azo coloring agent compound means a coloring agent having different absorbances depending on directions.

The dichroic azo coloring agent compound may or may not exhibit liquid crystallinity.

In a case where the dichroic azo coloring agent compound exhibits liquid crystallinity, any of nematic properties or smectic properties may be exhibited. The temperature range at which the liquid crystal phase is exhibited is preferably room temperature (approximately 20° C. to 28° C.) to 300° C., and from the viewpoint of handleability and manufacturing suitability, more preferably 50° C. to 200° C.

In the present invention, two or more kinds of dichroic substances may be used in combination. For example, from the viewpoint of making the color of the light absorption anisotropic layer to be formed closer to black, it is preferable that at least one dichroic substance having a maximal absorption wavelength in a wavelength range of 370 to 550 nm and at least one dichroic substance having a maximal absorption wavelength in a wavelength range of 500 to 700 nm are used in combination.

A content of the dichroic substance is not particularly limited, but from the reason that the alignment degree of the formed light absorption anisotropic layer is further increased, it is preferably 5% by mass or more, more preferably 8% by mass or more, still more preferably 10% by mass or more, and particularly preferably 10% to 30% by mass with respect to the total solid content mass of the liquid crystal composition. In a case where a plurality of dichroic substances are used in combination, it is preferable that the total amount of the plurality of dichroic substances is within the above-described range.

### <Alignment Agent>

It is preferable that the liquid crystal composition further contains an alignment agent.

Examples of the alignment agent include those described in paragraphs [0042] to [0076] of JP2013-543526A, paragraphs [0089] to [0097] of JP2016-523997A, paragraphs [0153] to [0170] of JP2020-076920A, and the like, and these may be used alone or in combination of two or more.

In the present invention, from the reason that the alignment degree of the formed light absorption anisotropic layer is increased, it is preferable that the above-described alignment agent is an onium compound represented by Formula (B1).

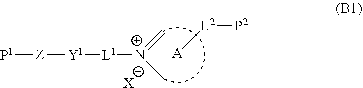

In Formula (B1), a ring A represents a quaternary ammonium ion consisting of a nitrogen-containing heterocyclic ring.

In addition, X represents an anion.

In addition, L¹ represents a divalent linking group.

In addition, L² represents a single bond or a divalent linking group.

In addition, Y¹ represents a divalent linking group having a 5-membered ring or a 6-membered ring as a partial structure.

In addition, Z represents a divalent linking group having an alkylene group having 2 to 20 carbon atoms as a partial structure.

In addition, P¹ and P² each independently represent a monovalent substituent having a polymerizable ethylenically unsaturated bond.

The ring A represents a quaternary ammonium ion consisting of a nitrogen-containing heterocyclic ring. Examples of the ring A include a pyridine ring, a picoline ring, a 2,2′-bipyridyl ring, a 4,4′-bipyridyl ring, a 1,10-phenanthroline ring, a quinoline ring, an oxazole ring, a thiazole ring, an imidazole ring, a pyrazine ring, a triazole ring, and a tetrazole ring, and the ring A is preferably a quaternary imidazolium ion or a quaternary pyridinium ion.

X represents an anion. Examples of X include a halogen anion (for example, a fluorine ion, a chlorine ion, a bromine ion, an iodine ion, and the like), a sulfonate ion (for example, a methanesulfonate ion, a trifluoromethanesulfonate ion, a methylsulfate ion, a vinylsulfonate ion, an allylsulfonate ion, a p-toluenesulfonate ion, a p-chlorobenzenesulfonate ion, a p-vinylbenzenesulfonate ion, a 1,3-benzenedisulfonate ion, a 1,5-naphthalenedisulfonate ion, a 2,6-naphthalenedisulfonate ion, and the like), a sulfate ion, a carbonate ion, a nitrate ion, a thiocyanate ion, a perchlorate ion, a tetrafluoroborate ion, a picrate ion, an acetate ion, a benzoate ion, a p-vinyl benzoate ion, a formate ion, a trifluoroacetate ion, a phosphate ion (for example, hexafluorophosphate ion), and a hydroxide ion. X is preferably a halogen anion, a sulfonate ion, or a hydroxide ion. In addition, a chlorine ion, a bromine ion, an iodine ion, a methanesulfonate ion, a vinylsulfonate ion, a p-toluenesulfonate ion, or a p-vinylbenzenesulfonate ion is particularly preferable.

L¹ represents a divalent linking group. Examples of L¹ include a divalent linking group having 1 to 20 carbon atoms, consisting of a combination of an alkylene group, —O—, —S—, —CO—, —SO₂—, —NRa— (here, Ra is an alkyl group having 1 to 5 carbon atoms or a hydrogen atom), an alkenylene group, an alkynylene group, and an arylene group. L¹ is preferably -AL-, —O-AL-, —CO—O-AL-, or —O—CO-AL-, each of which has 1 to 10 carbon atoms, more preferably -AL- or —O-AL-, each of which has 1 to 10 carbon atoms, and most preferably -AL- or —O-AL-, each of which has 1 to 5 carbon atoms. AL represents an alkylene group.

L² represents a single bond or a divalent linking group. Examples of L² include a divalent linking group having 1 to 10 carbon atoms, consisting of a combination of an alkylene group, —O—, —S—, —CO—, —SO₂—, —NRa— (here, Ra is an alkyl group having 1 to 5 carbon atoms or a hydrogen atom), an alkenylene group, an alkynylene group, and an arylene group; a single bond, —O—, —O—CO—, —CO—O—, —O-AL-O—, —O-AL-O—CO—, —O-AL-CO—O—, —CO—O-AL-O—, —CO—O-AL-O—CO—, —CO—O-AL-CO—O—, —O—CO-AL-O—, —O—CO-AL-O—CO—, and —O—CO-AL-CO—O—. AL represents an alkylene group. L² is preferably a single bond, -AL-, —O-AL-, or —NRa-AL-O—, each of which has 1 to 10 carbon atoms, more preferably a single bond, -AL-, —O-AL-, or —NRa-AL-O—, each of which has 1 to 5 carbon atoms, and most preferably a single bond, —O-AL-, or —NRa-AL-O—, each of which has 1 to 5 carbon atoms.

Y¹ represents a divalent linking group having a 5- or 6-membered ring as a partial structure. Examples of Y¹ include a cyclohexyl ring, an aromatic ring, or a heterocyclic ring. Examples of the aromatic ring include a benzene ring, an indene ring, a naphthalene ring, a fluorene ring, a phenanthrene ring, an anthracene ring, a biphenyl ring, and a pyrene ring, and a benzene ring, a biphenyl ring, or a naphthalene ring is particularly preferable. As a heteroatom constituting the heterocyclic ring, a nitrogen atom, an oxygen atom, or a sulfur atom is preferable, and examples of the heterocyclic ring include a furan ring, a thiophene ring, a pyrrole ring, a pyrroline ring, a pyrrolidine ring, an oxazole ring, an isoxazole ring, a thiazole ring, an isothiazole ring, an imidazole ring, an imidazoline ring, an imidazolidine ring, a pyrazole ring, a pyrazoline ring, a pyrazolidine ring, a triazole ring, a furazan ring, a tetrazole ring, a pyran ring, a dioxane ring, a dithiane ring, a thiane ring, a pyridine ring, a piperidine ring, an oxazine ring, a morpholine ring, a thiazine ring, a pyridazine ring, a pyrimidine ring, a pyrazine ring, a piperazine ring, and a triazine ring. The heterocyclic ring is preferably a 6-membered ring. The divalent linking group represented by Y¹, having a 5- or 6-membered ring as a partial structure, may further have a substituent (for example, the above-described substituent W).

The divalent linking group represented by Y¹ is preferably a divalent linking group having two or more 5- or 6-membered rings, and more preferably has a structure in which two or more rings are linked to each other through a linking group. Examples of the linking group include the examples of the linking group represented by L¹ and L, —C═C—, —CH═CH—, —CH═N—, —N═CH—, and —N═N—.

Z represents a divalent linking group which has an alkylene group having 2 to 20 carbon atoms as a partial structure and consists of a combination of —O—, —S—, —CO—, and —SO₂—, in which the alkylene group may have a substituent. Examples of the above-described divalent linking group include an alkyleneoxy group and a polyalkyleneoxy group. The number of carbon atoms in the alkylene group represented by Z is more preferably 2 to 16, still more preferably 2 to 12, and particularly preferably 2 to 8.

P1 and P2 each independently represent a monovalent substituent having a polymerizable ethylenically unsaturated bond. Examples of the above-described monovalent substituent having a polymerizable ethylenically unsaturated bond include Formulae (M-1) to (M-8). That is, the monovalent substituent having a polymerizable ethylenically unsaturated bond may be a substituent consisting of only an ethenyl group as in Formula (M-8).

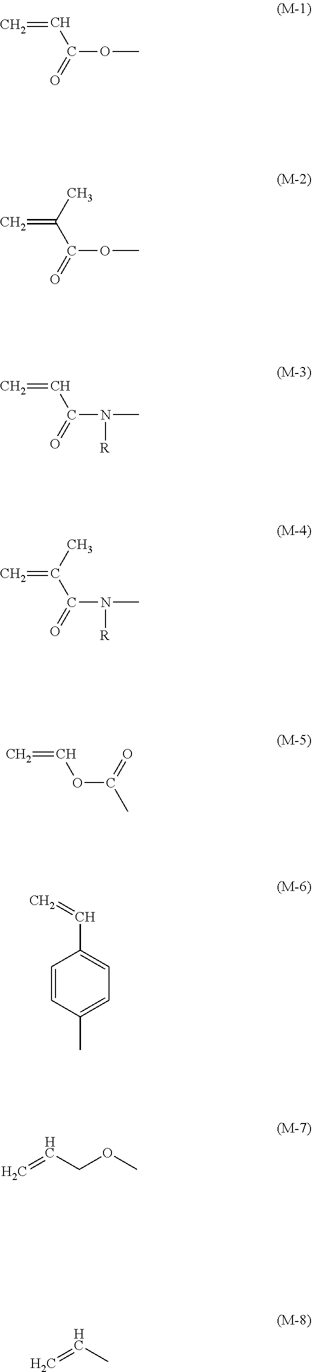

In Formulae (M-3) and (M4), R represents a hydrogen atom or an alkyl group, and a hydrogen atom or a methyl group is preferable. Among Formulae (M-1) to (M-8), (M-1), (M-2), or (M-8) is preferable, and (M-1) or (M-8) is more preferable. In particular, P1 is preferably (M-1). In addition, P2 is preferably (M-1) or (M-8), and in a compound in which the ring A is quaternary imidazolium ion, P2 is preferably (M-8) or (M-1), and in a compound in which the ring A is a quaternary pyridinium ion, P2 is preferably (M-1).

Examples of the onium compound represented by Formula (B1) include onium salts described in paragraphs 0052 to 0058 of JP2012-208397A, onium salts described in paragraphs 0024 to 0055 of JP2008-026730A, and onium salts described in JP2002-37777A.

In the present invention, from the reason that the alignment degree of the formed light absorption anisotropic layer is increased, it is preferable that the above-described alignment agent is a boronic acid compound represented by Formula (B2).

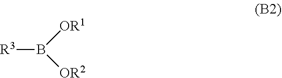

In Formula (B2), R¹ and R² each independently represent a hydrogen atom, an aliphatic hydrocarbon group which may have a substituent, an aryl group which may have a substituent, or a heterocyclic group which may have a substituent.

In addition, R³ represents a substituent.

Examples of the aliphatic hydrocarbon group represented by one aspect of R¹ and R² include a linear or branched alkyl group having 1 to 20 carbon atoms, which may be substituted or unsubstituted, (for example, a methyl group, an ethyl group, an iso-propyl group, and the like), a substituted or unsubstituted cyclic alkyl group having 3 to 20 carbon atoms (for example, a cyclohexyl group and the like), and an alkenyl group having 2 to 20 carbon atoms (for example, a vinyl group and the like).

In addition, examples of the aryl group represented by one aspect of R¹ and R² include a substituted or unsubstituted phenyl group having 6 to 20 carbon atoms (for example, a phenyl group, a tolyl group, and the like), and a substituted or unsubstituted naphthyl group having 10 to 20 carbon atoms.

In addition, examples of the heterocyclic group represented by one aspect of R¹ and R² include a substituted or unsubstituted 5-membered or 6-membered ring group including at least one heteroatom (for example, a nitrogen atom, an oxygen atom, a sulfur atom, and the like), and specific examples thereof include a pyridyl group, an imidazolyl group, a furyl group, a piperidyl group, and a morpholino group.

R¹ and R² may be linked to each other to form a ring. For example, isopropyl groups of R¹ and R² may be linked to each other to form a 4,4,5,5-tetramethyl-1,3,2-dioxaborolane ring.

As R¹ and R², a hydrogen atom, a linear or branched alkyl group having 1 to 3 carbon atoms, or an aspect in which these groups are linked to each other to form a ring is preferable, and a hydrogen atom is more preferable.

As the substituent represented by R³, a substituent including a functional group which can be bonded to a (meth)acrylic group is preferable.

Here, examples of the functional group which can be bonded to a (meth)acrylic group include a vinyl group, an acrylate group, a methacrylate group, an acrylamide group, a styryl group, a vinyl ketone group, a butadiene group, a vinyl ether group, an oxiranyl group, an aziridinyl group, and an oxetane group. Among these, a vinyl group, an acrylate group, a methacrylate group, a styryl group, an oxiranyl group, or an oxetane group is preferable, and a vinyl group, an acrylate group, an acrylamide group, or a styryl group is more preferable.

R³ is preferably a substituted or unsubstituted aliphatic hydrocarbon group, aryl group, or heterocyclic group having the functional group which can be bonded to a (meth)acrylic group.

Examples of the aliphatic hydrocarbon group include a substituted or unsubstituted linear or branched alkyl group having 1 to 30 carbon atoms (for example, a methyl group, an ethyl group, an iso-propyl group, an n-propyl group, a butyl group, a pentyl group, a hexyl group, a heptyl group, an octyl group, a nonyl group, a decyl group, an undecyl group, a dodecyl group, a tridecyl group, a hexadecyl group, an octadecyl group, an eicosyl group, an isopropyl group, an isobutyl group, an sec-butyl group, a tert-butyl group, an isopentyl group, a neopentyl group, a 1-methylbutyl group, an isohexyl group, a 2-methylhexyl group, and the like), a substituted or unsubstituted cyclic alkyl group having 3 to 20 carbon atoms (for example, a cyclopentyl group, a cyclohexyl group, a 1-adamantyl group, a 2-norbornyl group, and the like), and an alkenyl group having 2 to 20 carbon atoms (for example, a vinyl group, a 1-propenyl group, a 1-butenyl group, a 1-methyl-1-propenyl group, and the like).

Examples of the aryl group include a substituted or unsubstituted phenyl group having 6 to 50 carbon atoms (for example, a phenyl group, a tolyl group, a styryl group, a 4-benzoyloxyphenyl group, a 4-phenoxycarbonylphenyl group, a 4-biphenyl group, a 4-(4-octyloxybenzoyloxy)phenoxycarbonylphenyl group, and the like), and a substituted or unsubstituted naphthyl group having 10 to 50 carbon atoms (for example, an unsubstituted naphthyl group and the like).

The heterocyclic group is, for example, a substituted or unsubstituted 5-membered or 6-membered ring group including at least one heteroatom (for example, a nitrogen atom, an oxygen atom, a sulfur atom, and the like), and examples thereof include groups of pyrrole, furan, thiophene, pyrazole, imidazole, triazole, oxazole, isoxazole, oxadiazole, thiazole, thiadiazole, indole, carbazole, benzofuran, dibenzofuran, thianaphthene, dibenzothiophene, indazole, benzimidazole, anthranil, benzisoxazole, benzoxazole, benzothiazole, purine, pyridine, pyridazine, pyrimidine, pyrazine, triazine, quinoline, acridine, isoquinoline, phthalazine, quinazoline, quinoxaline, naphthyridine, phenanthroline, pteridine, morpholine, and piperidine, and the like.

Examples of the boronic acid compound represented by Formula (B2) include a boronic acid compound represented by General Formula (I) described in paragraphs 0023 to 0032 of JP2008-225281A.

As the compound represented by Formula (B2), compounds exemplified below are also preferable.

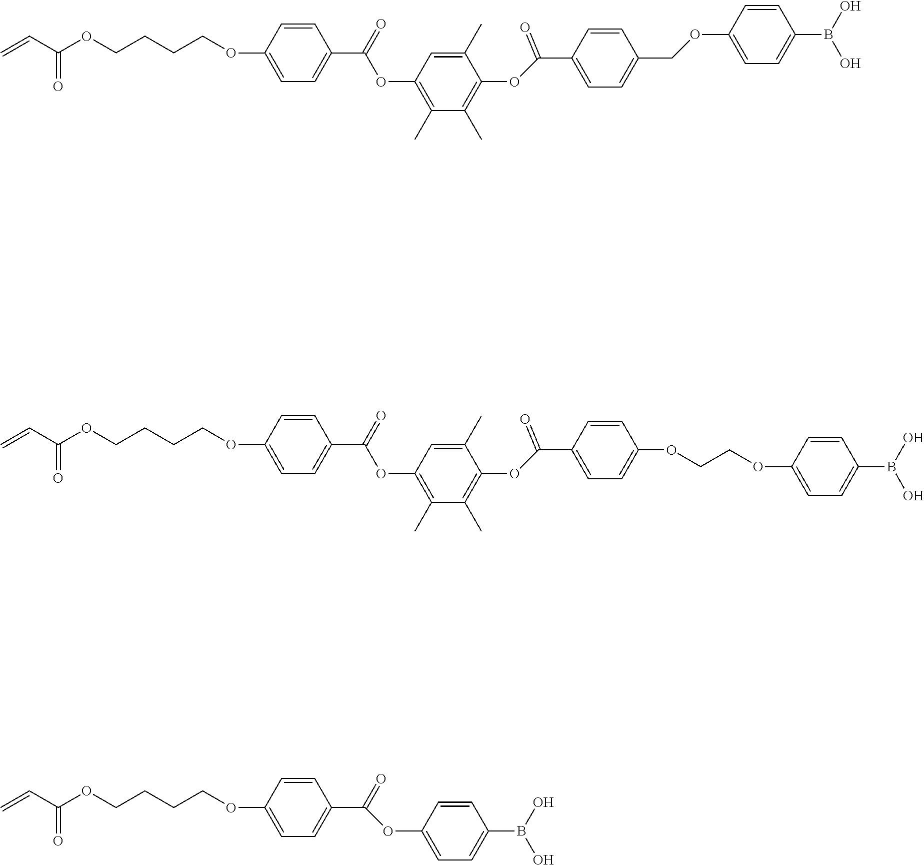 [SMILES: C=CC(=O)OCCCCOc1ccc(C(=O)Oc2cc(C)c(OC(=O)c3ccc(COc4ccc(B(O)O)cc4)cc3)c(C)c2C)cc1 ; C=CC(=O)OCCCCOc1ccc(C(=O)Oc2cc(C)c(OC(=O)c3ccc(OCCOc4ccc(B(O)O)cc4)cc3)c(C)c2C)cc1 ; C=CC(=O)OCCCCOc1ccc(C(=O)Oc2ccc(B(O)O)cc2)cc1]

In a case where the liquid crystal composition contains an alignment agent, a content of the alignment agent is preferably 0.2 to 20 parts by mass and more preferably 1 to 10 parts by mass with respect to the total of 100 parts by mass of the liquid crystal compound and the dichroic substance contained in the liquid crystal composition.

### <Solvent>

From the viewpoint of workability and the like, it is preferable that the liquid crystal composition contains a solvent.

Examples of the solvent include organic solvents such as ketones (such as acetone, 2-butanone, methyl isobutyl ketone, cyclopentanone, cyclohexanone, and acetylacetone), ethers (such as dioxane, tetrahydrofuran, tetrahydropyran, dioxolane, tetrahydrofurfuryl alcohol, cyclopentyl methyl ether, and dibutyl ether), aliphatic hydrocarbons (such as hexane), alicyclic hydrocarbons (such as cyclohexane), aromatic hydrocarbons (such as benzene, toluene, xylene, tetralin, and trimethylbenzene), halogenated carbons (such as dichloromethane, trichloromethane (chloroform), dichloroethane, dichlorobenzene, 1,1,2,2-tetrachloroethane, and chlorotoluene), esters (such as methyl acetate, ethyl acetate, butyl acetate, diethyl carbonate, ethyl acetoacetate, n-pentyl acetate, ethyl benzoate, benzyl benzoate, butyl carbitol acetate, diethylene glycol monoethyl ether acetate, and isoamyl acetate), alcohols (such as ethanol, isopropanol, butanol, cyclohexanol, furfuryl alcohol, 2-ethylhexanol, octanol, benzyl alcohol, ethanolamine, ethylene glycol, propylene glycol, diethylene glycol, diethylene glycol monomethyl ether, diethylene glycol monoethyl ether, and diethylene glycol monobutyl ether), phenols (such as phenol and cresol), cellosolves (such as methyl cellosolve, ethyl cellosolve, and 1,2-dimethoxyethane), cellosolve acetates, sulfoxides (such as dimethyl sulfoxide), amides (such as dimethylformamide, dimethylacetamide, N-methylpyrrolidone, N-ethylpyrrolidone, and 1,3-dimethyl-2-imidazolidinone), and heterocyclic compounds (such as pyridine and 2,6-lutidine); and water.

These solvents may be used alone or in combination of two or more kinds thereof.

In a case where the liquid crystal composition contains a solvent, a content of the solvent is preferably 60% to 99.5% by mass, more preferably 70% to 99% by mass, and particularly preferably 75% to 98% by mass with respect to the total mass (100% by mass) of the liquid crystal composition.

### <Polymerization Initiator>

The liquid crystal composition may contain a polymerization initiator.

The polymerization initiator is not particularly limited, but a compound having photosensitivity, that is, a photopolymerization initiator is preferable.

As the photopolymerization initiator, various compounds can be used without any particular limitation. Examples of the photopolymerization initiator include α-carbonyl compounds (U.S. Pat. Nos. 2,367,661A and 2,367,670A), acyloin ether (U.S. Pat. No. 2,448,828A), α-hydrocarbon-substituted aromatic acyloin compounds (U.S. Pat. No. 2,722,512A), polynuclear quinone compounds (U.S. Pat. Nos. 3,046,127A and 2,951,758A), a combination of a triarylimidazole dimer and a p-aminophenyl ketone (U.S. Pat. No. 3,549,367A), acridine and phenazine compounds (JP1985-105667A (JP-S60-105667A) and U.S. Pat. No. 4,239,850A), oxadiazole compounds (U.S. Pat. No. 4,212,970A), o-acyloxime compounds ([0065] of JP2016-27384A), and acylphosphine oxide compounds (JP1988-40799B (JP-S63-40799B), JP1993-29234B (JP-H5-29234B), JP1998-95788A (JP-H10-95788A), and JP1998-29997A (JP-H10-29997A)).

Commercially available products can also be used as such a photopolymerization initiator, and examples thereof include IRGACURE-184, IRGACURE-907, IRGACURE-369, IRGACURE-651, IRGACURE-819, IRGACURE-OXE-01, and IRGACURE-OXE-02, manufactured by BASF SE.

In a case where the liquid crystal composition contains a polymerization initiator, a content of the polymerization initiator is preferably 0.01% to 30% by mass and more preferably 0.1% to 15% by mass with respect to the total solid content mass of the liquid crystal composition.

### <Polymerizable Compound>

The liquid crystal composition may contain a polymerizable compound.

Examples of the polymerizable compound include a compound including an acrylate (such as a (meth)acrylate monomer).

In a case where the liquid crystal composition contains a polymerizable compound, a content of the polymerizable compound is preferably 0.5% to 50% by mass and more preferably 1.0% to 40% by mass with respect to the total solid content mass of the liquid crystal composition.

### <Interface Improver>

The liquid crystal composition may contain an interface improver.

The interface improver is not particularly limited, and a polymer-based interface improver or a low-molecular-weight interface improver can be used, and compounds described in paragraphs [0253] to [0293] of JP2011-237513A can also be used.

In addition, fluorine (meth)acrylate-based polymers described in paragraphs [0018] to [0043] of JP2007-272185A can also be used as the interface improver.

In addition, examples of the interface improver include compound described in paragraphs [0079] to [0102] of JP2007-069471A, polymerizable liquid crystal compounds represented by Formula (4) described in JP2013-047204A (particularly, compounds described in paragraphs [0020] to [0032]), polymerizable liquid crystal compounds represented by Formula (4) described in JP2012-211306A (particularly, compounds described in paragraphs [0022] to [0029]), liquid crystal alignment promoters represented by Formula (4) described in JP2002-129162A (particularly, compounds described in paragraphs [0076] to [0078] and paragraphs [0082] to [0084]), compounds represented by Formulae (4), (II), and (III) described in JP2005-099248A (particularly, compounds described in paragraphs [0092] to [0096]), compounds described in paragraphs [0013] to [0059] of JP4385997B, compounds described in paragraphs [0018] to [0044] of JP5034200B, and compounds described in paragraphs [0019] to [0038] of JP4895088B.

The interface improvers may be used alone or in combination of two or more kinds thereof.

In a case where the liquid crystal composition contains an interface improver, a content of the interface improver is preferably 0.005% to 15% by mass, more preferably 0.01% to 5% by mass, and still more preferably 0.015% to 3% by mass with respect to the total solid content mass of the liquid crystal composition. In a case where a plurality of interface improvers are used in combination, it is preferable that the total amount of the plurality of interface improvers is within the above-described range.

A thickness of the light absorption anisotropic layer according to the embodiment of the present invention is not particularly limited, but from the viewpoint of reducing the size and the weight, it is preferably 100 to 8,000 nm and more preferably 300 to 5,000 nm.

### <Method of Forming Light Absorption Anisotropic Layer>

A method of forming the light absorption anisotropic layer is not particularly limited, and examples thereof include a method including, in the following order, a step of applying the above-described liquid crystal composition (hereinafter, also referred to as “composition for forming a light absorption anisotropic layer”) to form a coating film (hereinafter, also referred to as “coating film forming step”) and a step of aligning the liquid crystalline component contained in the coating film (hereinafter, also referred to as “alignment step”).

In a case where the above-described dichroic substance has liquid crystallinity, the liquid crystalline component is a component which also includes the dichroic substance having liquid crystallinity in addition to the above-described liquid crystal compound.

In addition, in a case where the light absorption anisotropic layer is not a layer fixed in a liquid crystal state of a smectic phase (that is, in a case where a liquid crystal compound which exhibits smectic properties is not used as the liquid crystal compound contained in the liquid crystal composition), or in a case of not containing fine particles, from the viewpoint of adjusting the haze value, it is preferable that the light absorption anisotropic layer is formed by a manufacturing method of a light absorption anisotropic layer according to the embodiment of the present invention, which will be described later.

### (Coating Film Forming Step)

The coating film forming step is a step of applying the composition for forming a light absorption anisotropic layer to form a coating film.

The composition for forming a light absorption anisotropic layer can be easily applied by using a composition for forming a light absorption anisotropic layer, which contains the above-described solvent, or using a liquid such as a melt obtained by heating the composition for forming a light absorption anisotropic layer.

Specific examples of a method of applying the composition for forming a light absorption anisotropic layer include known methods such as a roll coating method, a gravure printing method, a spin coating method, a wire bar coating method, an extrusion coating method, a direct gravure coating method, a reverse gravure coating method, a die coating method, a spraying method, and an ink jet method.

### (Alignment Step)

The alignment step is a step of aligning a liquid crystalline component contained in the coating film. In this manner, even in a case where the above-described dichroic substance does not have liquid crystallinity, a light absorption anisotropic layer in which the dichroic substance is aligned along the alignment of the liquid crystal compound is obtained.

The alignment step may include a drying treatment. Components such as a solvent can be removed from the coating film by performing the drying treatment. The drying treatment may be performed by a method of allowing the coating film to stand at room temperature for a predetermined time (for example, natural drying) or a method of heating the coating film and/or blowing air to the coating film.

Here, the liquid crystalline component contained in the composition for forming a light absorption anisotropic layer may be aligned by the coating film forming step or the drying treatment described above. For example, in an aspect in which the composition for forming a light absorption anisotropic layer is prepared as a coating liquid containing a solvent, a coating film having light absorption anisotropy (that is, a light absorption anisotropic layer) is obtained by drying the coating film and removing the solvent from the coating film.

In a case where the drying treatment is performed at a temperature higher than or equal to a transition temperature of the liquid crystalline component contained in the coating film to the liquid crystal phase, a heat treatment described below may not be performed.

From the viewpoint of manufacturing suitability or the like, the transition temperature of the liquid crystalline component contained in the coating film to the liquid crystal phase is preferably 10° C. to 250° C. and more preferably 25° C. to 190° C. In a case where the above-described transition temperature is 10° C. or higher, a cooling treatment or the like for lowering the temperature to a temperature range in which the liquid crystal phase is exhibited is not necessary, which is preferable. In addition, in a case where the above-described transition temperature is 250° C. or lower, a high temperature is not required even in a case of setting an isotropic liquid state at a temperature higher than the temperature range in which the liquid crystal phase is temporarily exhibited, and waste of thermal energy and deformation and deterioration of a substrate can be reduced, which is preferable.

It is preferable that the alignment step includes a heat treatment. In this manner, since the liquid crystalline component contained in the coating film can be aligned, the coating film after being subjected to the heat treatment can be suitably used as the light absorption anisotropic layer.

From the viewpoint of the manufacturing suitability or the like, the heat treatment is performed at a temperature of preferably 10° C. to 250° C. and more preferably 25° C. to 190° C. In addition, the heating time is preferably 1 to 300 seconds and more preferably 1 to 60 seconds.

The alignment step may include a cooling treatment performed after the heat treatment. The cooling treatment is a treatment of cooling the heated coating film to room temperature (20° C. to 25° C.). In this manner, the alignment of the liquid crystalline component contained in the coating film can be fixed. A cooling unit is not particularly limited, and the cooling treatment can be performed according to a known method.

The light absorption anisotropic layer can be obtained by performing the above-described steps.

In the present embodiment, examples of a method of aligning the liquid crystalline component contained in the coating film include the drying treatment and the heat treatment, but the present invention is not limited thereto, and the liquid crystalline component can be aligned by a known alignment treatment.

### (Other Steps)

The method of forming the light absorption anisotropic layer may include a step of curing the light absorption anisotropic layer after the above-described alignment step (hereinafter, also referred to as “curing step”).

The curing step is performed by heating the light absorption anisotropic layer and/or irradiating the light absorption anisotropic layer with light (exposing the light absorption anisotropic layer to light), for example, in a case where the light absorption anisotropic layer has a crosslinkable group (polymerizable group). Among these, it is preferable that the curing step is performed by irradiating the light absorption anisotropic layer with light.

Various light sources such as infrared rays, visible light, and ultraviolet rays can be used as a light source for curing, but ultraviolet rays are preferable. In addition, ultraviolet rays may be applied while the layer is heated during curing, or ultraviolet rays may be applied through a filter which transmits only a specific wavelength.

In a case where the exposure is performed while the layer is heated, the heating temperature during the exposure depends on the transition temperature of the liquid crystalline component contained in the liquid crystal film to the liquid crystal phase, but it is preferably 25° C. to 140° C.

In addition, the exposure may be performed under a nitrogen atmosphere. In a case where the curing of the liquid crystal film proceeds by radical polymerization, since inhibition of polymerization by oxygen is reduced, it is preferable that the exposure is performed in a nitrogen atmosphere.

### [Interlayer]

The interlayer included in the optical film according to the embodiment of the present invention is a layer disposed between the plurality of light absorption anisotropic layers described above.

Here, the interlayer refers to all layers disposed between the plurality of light absorption anisotropic layers, but in a case where three or more layers of the light absorption anisotropic layers are included, a light absorption anisotropic layer disposed between the plurality of light absorption anisotropic layers does not correspond to the interlayer. That is, for example, in a case where the optical film according to the embodiment of the present invention has a layer configuration in which a light absorption anisotropic layer A, an alignment layer X, a light absorption anisotropic layer B, an alignment layer Y, and a light absorption anisotropic layer C are provided in this order, the alignment layer X and the alignment layer Y correspond to the interlayer, and the light absorption anisotropic layer B does not correspond to the interlayer.

In addition, the interlayer included in the optical film according to the embodiment of the present invention is a layer in which an in-plane retardation at a wavelength of 550 nm is 25 nm or less and an absolute value of a thickness-direction retardation at the wavelength of 550 nm is 25 nm or less. The above-described provision regarding the retardation is a provision that applies to any interlayer in a case of a plurality of interlayers.

Examples of such an interlayer include an alignment layer, a barrier layer, a refractive index adjusting layer, a pressure-sensitive adhesive layer, an adhesive layer, and a support.

Among these, the interlayer is preferably an alignment layer or a barrier layer.

Hereinafter, any alignment layer, barrier layer, refractive index adjusting layer, pressure-sensitive adhesive layer, adhesive layer, and support, which may be included in the optical film according to the embodiment of the present invention, will be described. However, these are provided between the plurality of light absorption anisotropic layers described above, and correspond to an interlayer in a case of satisfying the above-described provision regarding the retardation.

### [Alignment Layer]

In a case where the above-described light absorption anisotropic layer of the optical film according to the embodiment of the present invention is a layer formed of the liquid crystal composition, it is preferable that the optical film includes an alignment layer as an adjacent layer.

Here, specific examples of the alignment layer include a layer formed of polyvinyl alcohol, polyimide, or the like, which has been or has not been subjected to a rubbing treatment; and a photoalignment layer formed of polyvinyl cinnamate, an azo-based dye, or the like, which has been or has not been subjected to a polarized light exposure treatment.

In addition, a thickness of the alignment layer is preferably 0.01 to 10 μm and more preferably 0.01 to 1 μm.

In addition, the alignment layer may be a layer which also serves as a barrier layer described later.

### [Barrier Layer (Oxygen-Shielding Layer)]

The optical film according to the embodiment of the present invention preferably includes a barrier layer.

Here, the barrier layer is also referred to as a gas-shielding layer (oxygen-shielding layer), and has a function of protecting from a gas such as oxygen in the air, moisture, a compound contained in an adjacent layer, or the like.

The barrier layer can refer to, for example, the description in paragraphs [0014] to [0054] of JP2014-159124A, paragraphs [0042] to [0075] of JP2017-121721A, paragraphs [0045] to [0054] of JP2017-115076A, paragraphs [0010] to [0061] of JP2012-213938A, and paragraphs [0021] to [0031] of JP2005-169994A.

### [Refractive Index Adjusting Layer]

From the viewpoint of suppressing influence of internal reflection caused by the high refractive index of the light absorption anisotropic layer, the optical film according to the embodiment of the present invention may include a refractive index adjusting layer.

The refractive index adjusting layer is a layer disposed in contact with the light absorption anisotropic layer, and has an in-plane average refractive index of 1.55 or more and 1.70 or less at a wavelength of 550 nm. It is preferable that the refractive index adjusting layer is a refractive index adjusting layer for performing so-called index matching.

### [Pressure-Sensitive Adhesive Layer]

The optical film according to the embodiment of the present invention may include a pressure-sensitive adhesive layer.

It is preferable that the pressure-sensitive adhesive layer is a transparent and optically isotropic pressure sensitive adhesive similar to that used in a typical image display device, and a pressure-sensitive type adhesive is typically used.

The pressure-sensitive adhesive layer may be blended with appropriate additives such as a crosslinking agent (such as an isocyanate-based crosslinking agent or an epoxy-based crosslinking agent), a viscosity imparting agent (such as a rosin derivative resin, a polyterpene resin, a petroleum resin, an oil-soluble phenol resin, and the like), a plasticizer, a filler, an antiaging agent, a surfactant, an ultraviolet absorbing agent, a light stabilizer, and an antioxidant in addition to a parent material (pressure sensitive adhesive), conductive particles, and thermally expandable particles used as necessary.

### [Adhesive Layer]

The optical film according to the embodiment of the present invention may include an adhesive layer.

The adhesive layer exhibits adhesiveness due to drying or a reaction after bonding.

A polyvinyl alcohol-based adhesive (PVA-based adhesive) exhibits adhesiveness due to drying, and is capable of bonding materials to each other.

Specific examples of the curable adhesive which exhibits adhesiveness due to reaction include an active energy ray-curable adhesive such as a (meth) acrylate-based adhesive and a cationic polymerization curable adhesive. The (meth)acrylate denotes acrylate and/or methacrylate. Examples of the curable component in the (meth)acrylate-based adhesive include a compound having a (meth)acryloyl group and a compound having a vinyl group. In addition, as the cationic polymerization curable adhesive, a compound having an epoxy group or an oxetanyl group can also be used. The compound having an epoxy group is not particularly limited as long as the compound has at least two epoxy groups in a molecule, and various generally known curable epoxy compounds can be used. Preferred examples of the epoxy compound include a compound (aromatic epoxy compound) having at least two epoxy groups and at least one aromatic ring in the molecule and a compound (alicyclic epoxy compound) having at least two epoxy groups in the molecule, in which at least one of the epoxy groups is formed between two adjacent carbon atoms constituting an alicyclic ring.

Among these, from the viewpoint of heat deformation resistance, an ultraviolet curable adhesive which is cured by irradiation with ultraviolet rays is preferably used.

### [Support]

The optical film according to the embodiment of the present invention may include a support.

The type of the support is not particularly limited, and a known support can be used. In particular, a transparent support is preferable. The transparent support is intended to be a support in which the transmittance of visible light is 60% or more, and the transmittance is preferably 80% or more and more preferably 90% or more.

Examples of the support include a glass substrate and a polymer film.

Examples of a material of the polymer film include cellulose-based polymers; acrylic polymers having an acrylic acid ester polymer such as polymethyl methacrylate and a lactone ring-containing polymer; thermoplastic norbornene-based polymers; polycarbonate-based polymers; polyester-based polymers such as polyethylene terephthalate and polyethylene naphthalate; styrene-based polymers such as polystyrene and an acrylonitrile-styrene copolymer; polyolefin-based polymers such as polyethylene, polypropylene, and an ethylene-propylene copolymer; vinyl chloride-based polymers; amide-based polymers such as nylon and aromatic polyamide; imide-based polymers; sulfone-based polymers; polyether sulfone-based polymers; polyether ether ketone-based polymers; polyphenylene sulfide-based polymers; vinylidene chloride-based polymers; vinyl alcohol-based polymers; vinyl butyral-based polymers; arylate-based polymers; polyoxymethylene-based polymers; epoxy-based polymers; and polymers obtained by mixing these polymers.

In addition, the support is preferably a peelable support.

### [Viewing Angle Control System]

The viewing angle control system according to the embodiment of the present invention includes a polarizer having an absorption axis in an in-plane direction, and the above-described optical film according to the embodiment of the present invention.

### [Polarizer]

The polarizer included in the viewing angle control system according to the embodiment of the present invention is not particularly limited as long as the polarizer is a member having an absorption axis in the in-plane direction and having a function of converting light into specific linearly polarized light, and a known polarizer in the related art can be used.

As the polarizer, an iodine-based polarizer, a dye-based polarizer using a dichroic dye, a polyene-based polarizer, or the like is used. Examples of the iodine-based polarizer and the dye-based polarizer include a coating type polarizer and a stretching type polarizer, and both polarizers can be applied. As the coating type polarizer, a polarizer in which a dichroic organic coloring agent is aligned by using alignment of the liquid crystal compound is preferable, and as the stretching type polarizer, a polarizer produced by adsorbing iodine or a dichroic dye on polyvinyl alcohol and stretching the polyvinyl alcohol is preferable.

In addition, examples of the method of obtaining a polarizer by stretching and dyeing a laminated film in which a polyvinyl alcohol layer is formed on a base material include methods described in JP5048120B, JP5143918B, JP5048120B, JP4691205B, JP4751481B, and JP4751486B, and known techniques related to these polarizers can also be preferably used.

Among these, from the viewpoint of availability and excellent polarization degree, a polarizer containing a polyvinyl alcohol-based resin (a polymer having —CH₂—CHOH— as a repeating unit; particularly at least one selected from the group consisting of polyvinyl alcohol and an ethylene-vinyl alcohol copolymer) is preferable.

In the present invention, a thickness of the polarizer is not particularly limited, but is preferably 3 μm to 60 μm, more preferably 5 μm to 20 μm, and still more preferably 5 μm to 10 μm.

In the viewing angle control system according to the embodiment of the present invention, the above-described optical film according to the embodiment of the present invention and the above-described polarizer may be laminated through the above-described pressure-sensitive adhesive layer or the above-described adhesive layer, or the above-described alignment film, the above-described light absorption anisotropic layer, the above-described interlayer, and the above-described light absorption anisotropic layer may be coated and laminated directly on the above-described polarizer.

### [Image Display Device]

The image display device according to the embodiment of the present invention includes a display element and the above-described viewing angle control system according to the embodiment of the present invention, in which the viewing angle control system is disposed on at least one main surface of the display element.

In addition, in the image display device according to the embodiment of the present invention, it is preferable that the plurality of light absorption anisotropic layers included in the viewing angle control system are all arranged on a viewing side with respect to the polarizer included in the viewing angle control system, that is, it is preferable that the image display device includes the light absorption anisotropic layer, the interlayer, the light absorption anisotropic layer, the polarizer, and the display element in this order from the viewing side.

The display element used in the image display device according to the embodiment of the present invention is not particularly limited, and examples thereof include a liquid crystal cell, an organic electroluminescence (hereinafter, abbreviated as “EL”) display panel, and a plasma display panel.

Among these, a liquid crystal cell or an organic EL display panel is preferable. That is, as the display device according to the embodiment of the present invention, a liquid crystal display device obtained by using a liquid crystal cell as a display element or an organic EL display device obtained by using an organic EL display panel as a display element is preferable.

Some image display devices are thin and can be formed into a curved surface. Since a light absorption anisotropic layer used in the present invention is thin and easily bent, the light absorption anisotropic layer can be suitably applied to an image display device having a curved display surface.

In addition, some image display devices have a pixel density of more than 250 ppi and are capable of high-definition display. The light absorption anisotropic film used in the present invention can be suitably applied to such a high-definition image display device without causing moire.

### [Liquid Crystal Display Device]

Preferred examples of the liquid crystal display device which is an example of the display device according to the embodiment of the present invention include an aspect in which the liquid crystal display device includes the above-described viewing angle control system according to the embodiment of the present invention and a liquid crystal cell.

Examples of the specific configuration thereof include a configuration in which the viewing angle control system according to the embodiment of the present invention is disposed on a front-side polarizing plate or a rear-side polarizing plate. In these configurations, the viewing angle at which the vertical direction or the horizontal direction is light-shielded can be controlled.

In addition, the viewing angle control system according to the embodiment of the present invention may be disposed on both the front-side polarizing plate and the rear-side polarizing plate. With such a configuration, it is possible to control the viewing angle in which omniazimuth is light-shielded and light is transmitted only in the front direction.

Hereinafter, the liquid crystal cell constituting the liquid crystal display device will be described in detail.

### <Liquid Crystal Cell>

It is preferable that the liquid crystal cell used for the liquid crystal display device is in a vertical alignment (VA) mode, an optically compensated bend (OCB) mode, an in-plane-switching (IPS) mode, or a twisted nematic (TN) mode, but the present invention is not limited thereto.

In the liquid crystal cell in a TN mode, rod-like liquid crystalline molecules are substantially horizontally aligned at the time of no voltage application and further twisted aligned at 60° to 120°. The liquid crystal cell in a TN mode is most frequently used as a color TFT liquid crystal display device and is described in a plurality of documents.

In the liquid crystal cell in a VA mode, rod-like liquid crystalline molecules are substantially vertically aligned at the time of no voltage application. The concept of the liquid crystal cell in a VA mode includes (1) a liquid crystal cell in a VA mode in a narrow sense where rod-like liquid crystalline molecules are aligned substantially vertically at the time of no voltage application and substantially horizontally at the time of voltage application (described in JP1990-176625A (JP-H2-176625A)), (2) a liquid crystal cell (in an MVA mode) (SID97, described in Digest of tech. Papers (proceedings) 28 (1997) 845) in which the VA mode is formed to have multi-domain in order to expand the viewing angle, (3) a liquid crystal cell in a mode (n-ASM mode) in which rod-like liquid crystalline molecules are substantially vertically aligned at the time of no voltage application and twistedly multi-domain aligned at the time of voltage application (described in proceedings of Japanese Liquid Crystal Conference, pp. 58 to 59 (1998)), and (4) a liquid crystal cell in a SURVIVAL mode (presented at LCD International 98). In addition, the liquid crystal cell may be of any of a patterned vertical alignment (PVA) type, a photo-alignment (optical alignment) type, or a polymer-sustained alignment (PSA) type. The details of these modes are described in JP2006-215326A and JP2008-538819A.

In the liquid crystal cell in an IPS mode, liquid crystal compounds are aligned substantially parallel to the substrate, and the liquid crystalline molecules respond planarly through application of an electric field parallel to the substrate surface. That is, the liquid crystal compounds are aligned in the plane in a state where no electric field is applied. In the IPS mode, black display is carried out in a state where no electric field is applied, and absorption axes of a pair of upper and lower polarizing plates are orthogonal to each other. A method of reducing light leakage during black display in an oblique direction and improve the viewing angle using an optical compensation sheet is disclosed in JP1998-54982A (JP-H10-54982A), JP1999-202323A (JP-H11-202323A), JP1997-292522A (JP-H9-292522A), JP1999-133408A (JP-H11-133408A), JP1999-305217A (JP-H11-305217A), and JP1998-307291A (JP-H10-307291A).

### [Organic EL Display Device]

Suitable examples of the organic EL display device which is an example of the display device according to the embodiment of the present invention include an aspect of including the above-described viewing angle control system according to the embodiment of the present invention, a λ/4 plate, and an organic EL display panel in this order from the viewing side.

In addition, the organic EL display panel is a display panel formed of an organic EL element obtained by sandwiching an organic light emitting layer (organic electroluminescence layer) between electrodes (between a cathode and an anode). The configuration of the organic EL display panel is not particularly limited, and a known configuration is employed.

[Image Display Device Capable of Switching Viewing Angle Switched (Image Display Device in which Viewing Angle can be Switched)]

By using the optical film according to the embodiment of the present invention, it is possible to narrow an emission angle of light. Various methods for an image display device capable of switching a viewing angle have been known, and the optical film according to the embodiment of the present invention can be used for the purpose of generating light having a narrow emission angle.

For example, it is possible to switch between narrow viewing angle and wide viewing angle by generating light having a narrow emission angle using the optical film according to the embodiment of the present invention, and then passing the light through an element which controls whether light is diffused or not, as described in JP1997-105907A (JP-H9-105907A).

Alternatively, as described in JP2017-098246A, in a narrow viewing angle/wide viewing angle switching backlight system including, from a viewing side, a reverse prism sheet, a first light guide plate (a light emitted from the reverse prism sheet has a narrow viewing angle) to which light is incident at a relatively large incidence angle, an optical filter element which absorbs light incident obliquely and emits light at a narrow emission angle, the light being incident on the reverse prism sheet at a relatively small incidence angle, and a second light guide plate (a light emitted from the reverse prism sheet has a narrow viewing angle), the optical film according to the embodiment of the present invention can be used as the optical filter element.

In addition, in a backlight system in which the first light guide plate, an optical filter that absorbs light incident obliquely and emits light at a narrow angle, and the second light guide plate are laminated in this order from the viewing side, and the viewing angle is wide in a case where light is emitted from the first light guide plate and the viewing angle is narrow in a case where light is emitted from the second light guide plate, the optical film according to the embodiment of the present invention can be used as the optical filter.

In addition, it is also possible to dispose a phase difference modulation element such as a liquid crystal cell between the optical film according to the embodiment of the present invention and the horizontal alignment polarizer to switch between the narrow viewing angle and the wide viewing angle. For example, in a case where a liquid crystal cell in a VA mode or an ECB mode is used as a phase difference modulation cell, the viewing angle is narrow in a state in which the liquid crystal in the liquid crystal cell is vertically aligned, and the viewing angle is wide in a case where the liquid crystal in the liquid crystal cell is tilt-aligned, and the narrow viewing angle and the wide viewing angle can be controlled by the presence or absence of a voltage application to the cell.

In addition, it is also possible to use a liquid crystal cell in an IPS mode as the phase difference modulation cell. The alignment direction of the liquid crystal cell at the time of non-voltage application and the absorption axis direction of the horizontal alignment polarizer are made parallel or perpendicular to each other, and the alignment direction of the liquid crystal cell is changed by applying a voltage, so that the viewing angle can be switched from the narrow viewing angle to the wide viewing angle.

Furthermore, as the phase difference modulation cell, use of a liquid crystal cell in a twisted nematic (TN) mode is also considered. It is preferable that the liquid crystal cell is a cell in which A twisted angle (twist angle) of the alignment can be switched between 0° and 90° or between 0° and 270° by turning on and off the voltage.

In addition, in the image display device according to the embodiment of the present invention, a viewing angle of a plurality of regions in the display screen may be switched independently.

### [Optical Device/Head-Mounted Display]

The optical film according to the embodiment of the present invention can be used for an optical device (head-mounted display) including a light guide plate on which a diffraction element is disposed on a surface.

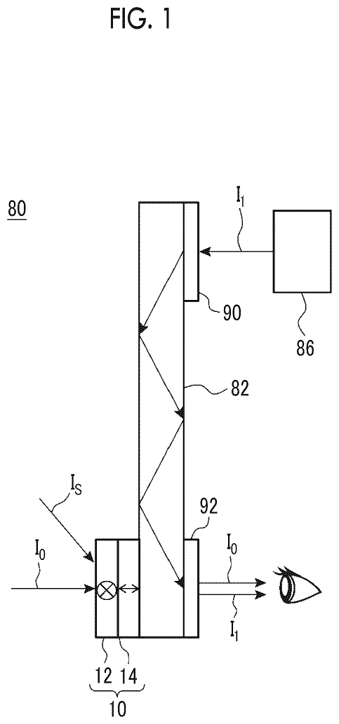

FIG. 1 shows a schematic view of an example of the head-mounted display according to the embodiment of the present invention.

A head-mounted display 80 shown in FIG. 1 is an example of an AR glass, and includes a light guide plate 82, an incidence diffraction element 90 and an emission diffraction element 92 which are arranged on one surface of the light guide plate 82, an optical filter 10, and an image display element 86. The light guide plate 82, the incidence diffraction element 90, the emission diffraction element 92, and the optical filter 10 constitute the optical device according to the embodiment of the present invention.

As shown in FIG. 1, the incidence diffraction element 90 is disposed on a surface (main surface) of the light guide plate 82 on one end part side. In addition, the emission diffraction element 92 is disposed on the surface of the light guide plate 82 on the other end part side.

The disposition position of the incidence diffraction element 90 corresponds to an incidence position of a video light I₁ from the image display element 86 to the light guide plate 82. On the other hand, the disposition position of the emission diffraction element 92 corresponds to an emission position of the video light I₁ from the light guide plate 82, that is, an observation position of the video light I₁ by the user. In addition, the incidence diffraction element 90 and the emission diffraction element 92 are arranged on the same surface of the light guide plate 82.

In addition, the optical filter 10 is disposed on a surface of the light guide plate 82, the surface facing the emission diffraction element 92 and being opposite to the surface on which the emission diffraction element 92 of the light guide plate 82 is disposed.

As shown in FIG. 1, the optical filter 10 has the same shape as the emission diffraction element 92.

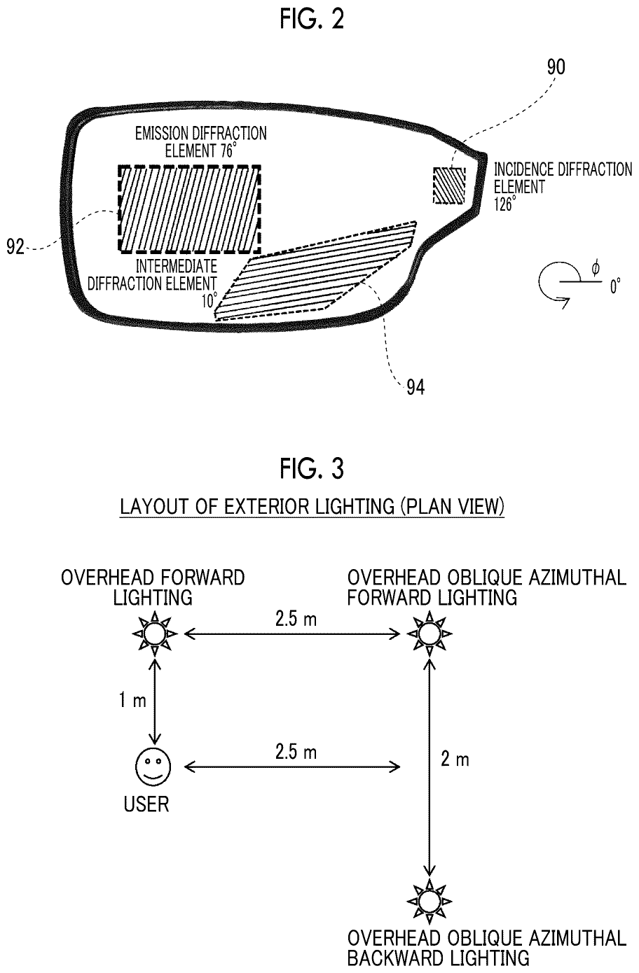

An intermediate diffraction element 94 may be provided in the light guide plate 82 (see FIG. 2).

In addition, the disposition position of each diffraction element is not limited to the end part of the light guide plate, and various positions can be used depending on the shape of the light guide plate, or the like.

In the head-mounted display 80 (AR glass) having such a configuration, the video light I₁ displayed by the image display element 86 is incident into the light guide plate 82 at an angle at which the video light I₁ is diffracted by the incidence diffraction element 90 and totally reflected at an interface between the light guide plate 82 and air.

The video light I₁ incident into the light guide plate 82 is totally reflected by both surfaces of the light guide plate 82, guided inside the light guide plate 82, and incident into the emission diffraction element 92.

The video light I₁ incident into the emission diffraction element 92 is diffracted by the emission diffraction element 92 in a direction perpendicular to the surface of the emission diffraction element 92.

The video light I₁ diffracted by the emission diffraction element 92 is emitted to an observation position by the user outside the light guide plate 82 to be observed by the user.

It is preferable that the optical filter 10 and the light guide plate 82 have an air gap therebetween. In a case where there is no air gap, the video light I₁ which has advanced in the light guide plate 82 is incident on the optical filter 10, so that the video light I₁ is attenuated by absorption in a case where the video light I₁ is propagated in the optical filter 10, totally reflected on the surface of the optical filter 10 on the side opposite to the light guide plate 82, and propagated again in the optical filter 10. By providing the air gap between the optical filter 10 and the light guide plate 82, the video light I₁ from the light guide plate is not incident on the optical filter, and the above-described problem can be solved.

In addition, as shown in FIG. 1, an external light I₀ incident into the head-mounted display 80 from a front direction, that is, a background is transmitted through the optical filter 10, incident on the light guide plate 82, transmitted through the emission diffraction element 92, and reaches the observation position by the user. In the following description, the external light incident into the head-mounted display 80 from the front direction is also referred to as a front external light I₀.

As a result, the head-mounted display 80 displays a virtual video superimposed on the actual scene viewed by the user by propagating the video displayed by the image display element 86 by being incident on one end of the light guide plate 82 and being emitted from the other end.

A shape of the optical filter 10 is not limited to the same shape as the diffraction element and may be a different shape, and a size thereof may also be different. However, in order to suitably external light incident on the diffraction element from an oblique direction, that is, an oblique external light Iₛ, and to suppress unnecessary shielding of the background, that is, the front external light I₀, it is preferable that the diffraction element and the optical filter have the same shape and size.

The light guide plate 82 is not particularly limited, and a known light guide plate used in an image display device or the like in the related art, such as a light guide plate used in various AR glasses and a light guide plate used in a backlight unit of a liquid crystal display device, can be used.

The image display element 86 is not limited, and various known image display elements (displays) used in various image display devices such as AR glass can be used.

Examples of the image display element 86 include a liquid crystal display (including liquid crystal on silicon (LCOS)), an organic electroluminescent display, an inorganic electroluminescent display, a digital light processing (DLP), a micro-electro-mechanical systems (MEMS)-type display, and a micro light-emitting diode (LED) display.

The image display element 86 may display a monochrome image, a two-color image, or a color image.

In the optical device according to the embodiment of the present invention, an optical filter including the laminate according to the embodiment of the present invention, which covers the diffraction element, is preferably provided, and as shown in the illustrated example, an optical filter including a laminate 14 and a polarizer 12 is provided.

The optical device according to the embodiment of the present invention includes the optical filter 10 (10 m) as described above, and thus, in a case of being used for a head-mounted display such as AR glass, the light transmittance in the front direction (front external light I₀) is high, that is, the visibility of the background is excellent, and rainbow-like unevenness caused by the external light (oblique external light Iₛ) incident from the front overhead (diagonally forward overhead) of the observer can be suppressed. Furthermore, with the optical device according to the embodiment of the present invention, it is preferable that not only rainbow-like unevenness caused by the external light incident from the front of the observer's head above, but also rainbow-like unevenness caused by the external light incident from the oblique front above of the observer (oblique upward direction front) can be suppressed.

In the laminate 14 constituting the optical filter 10 of the optical device according to the embodiment of the present invention, an angle between an absorption axis (alignment direction of the liquid crystal compound) and a normal direction of the laminate 14 is 0° to 45°. That is, the laminate 14 has an absorption axis extending in a normal direction of the main surface of the laminate 14 and a normal direction of the main surface of the light guide plate 82.

On the other hand, the polarizer 12 constituting the optical filter 10 is a polarizer having an absorption axis in the main surface. That is, the polarizer has an absorption axis parallel to the main surface of the laminate 14 and the main surface of the light guide plate 82.

In the present invention, in a case where the optical filter includes the laminate 14 and the polarizer 12, from the viewpoint of improving light resistance, it is preferable that the laminate 14 is disposed on the light guide plate 82 side.

### EXAMPLES

Hereinafter, the present invention will be described in more detail with reference to Examples. Materials, used amounts, ratios, treatment contents, treatment procedures, and the like described in Examples can be appropriately changed without departing from the spirit of the present invention. Therefore, the scope of the present invention should not be construed as being limited to Examples.

### Comparative Example 1

### [Formation of Alignment Layer Serving as Barrier Layer]

A surface of a cellulose acylate film 1 (TAC base material with a thickness of 40 μm; TG40 of FUJIFILM Corporation) as a support was saponified with an alkaline solution, and coated with a coating liquid 1 for forming an alignment layer using a wire bar. The support on which the coating film had been formed was dried with hot air at 60° C. for 60 seconds and further dried with hot air at 100° C. for 120 seconds to form an alignment layer serving as a barrier layer (hereinafter, abbreviated as “alignment layer/barrier layer”). A film thickness of the alignment layer/barrier layer was 1 μm.

(Coating liquid 1 for forming alignment layer)

| | |
|---|---|
| Modified polyvinyl alcohol shown below | 3.80 parts by mass |
| Initiator Irg2959 | 0.20 parts by mass |
| Water | 70 parts by mass |
| Methanol | 30 parts by mass |

### Modified Polyvinyl Alcohol

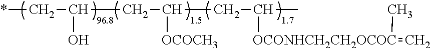

### [Formation of Light Absorption Anisotropic Layer P1]

The following composition P1 for forming a light absorption anisotropic layer was continuously applied onto the alignment layer/barrier layer formed on the support using a wire bar to form a coating layer P1.

Next, the coating layer P1 was heated at 140° C. for 30 seconds, and the coating layer P1 was cooled to room temperature (23° C.).

Next, the coating layer P1 was heated at 80° C. for 60 seconds and cooled to room temperature again.

Thereafter, the coating layer P1 was irradiated with a light emitting diode (LED) lamp (central wavelength of 365 nm) for 2 seconds under an irradiation condition of an illuminance of 200 mW/cm², thereby producing a light absorption anisotropic layer P1 on the alignment layer 1.

A film thickness of the coating layer P1 was 3 μm, and an alignment degree of the light absorption anisotropic layer P1 at a wavelength of 550 nm was 0.96.

A numerical value obtained by multiplying the ratio of the total mass of the dichroic substances D-1, D-2, and D-3, which was 1.18 parts by mass, with respect to the total mass of solid contents (excluding the organic solvent) in the composition of the composition P1 for forming a light absorption anisotropic layer, which was 5.015 parts by mass, by the film thickness of the coating layer P1, which was 3 μm, was 1.42 μm.

Formulation of composition P1 for forming light absorption anisotropic layer

| | | |
|---|---|---|
| Dichroic substance D-1 shown below | 0.40 | parts by mass |
| Dichroic substance D-2 shown below | 0.15 | parts by mass |
| Dichroic substance D-3 shown below | 0.63 | parts by mass |
| High-molecular-weight liquid crystal compound P-1 shown below | 3.65 | parts by mass |
| Polymerization initiator | 0.040 | parts by mass |
| IRGACURE OXE-02 (manufactured by BASF SE) | | |
| Compound E-1 shown below | 0.060 | parts by mass |
| Compound E-2 shown below | 0.060 | parts by mass |
| Surfactant F-1 shown below | 0.010 | parts by mass |
| Surfactant F-2 shown below | 0.015 | parts by mass |
| Cyclopentanone | 47.00 | parts by mass |
| Tetrahydrofuran | 47.00 | parts by mass |
| Benzyl alcohol | 1.00 | part by mass |

Dichroic substance D-1 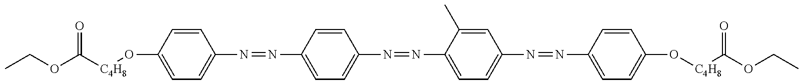
Dichroic substance D-2 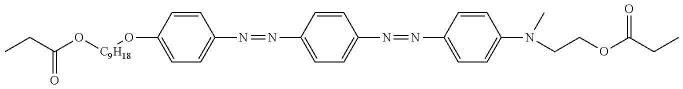
Dichroic substance D-3 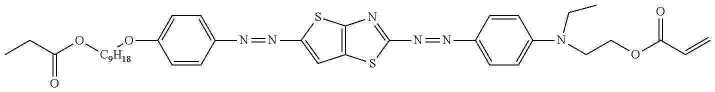
High-molecular-weight liquid crystal compound P-1 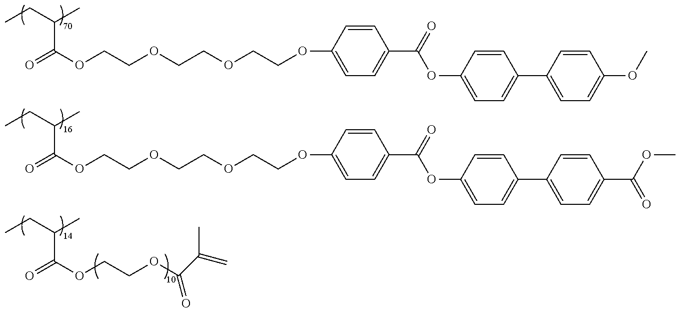
Compound E-1 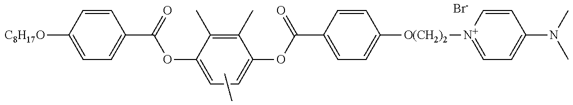
Compound E-2 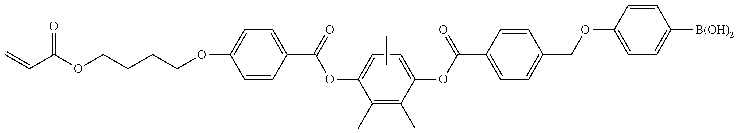
Surfactant F-1 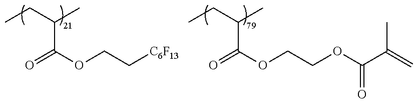
Surfactant F-2

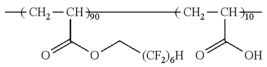

### [Formation of Alignment Layer/Barrier Layer]

The surface of the light absorption anisotropic layer P1 was subjected to a corona treatment, and then the above-described coating liquid 1 for forming an alignment layer was continuously applied thereto using a wire bar. Thereafter, the coating liquid was dried with hot air at 100° C. for 2 minutes to form an alignment layer/barrier layer 1 consisting of polyvinyl alcohol (PVA) on the light absorption anisotropic layer P1, with a thickness of 1.0 μm, thereby producing an optical film 1.

### [Production of Polarizing Plate]

A PVA film having a film thickness of 30 μm, an average degree of polymerization of 2400, and a degree of saponification of 99.9 mol % was immersed in warm water at 25° C. for 120 seconds to swell the film. Next, the PVA film was dyed while being immersed in an aqueous solution having a concentration of 0.6% by weight of iodine/potassium iodide (weight ratio=2/3) and stretched 2.1 times. Thereafter, the film was stretched in a boric acid ester aqueous solution at 55° C. such that a total stretching ratio reached 5.5 times, washed with water, and dried to produce a polarizer. A thickness of the polarizer was 8 μm.

Both surfaces of the above-described polarizer were bonded to a saponified cellulose acylate film (TAC base material with a thickness of 40 μm; TG40 of FUJIFILM Corporation) using the following PVA adhesive 1 to produce a polarizing plate 1.

### <Preparation of PVA Adhesive 1>

20 parts by mass of methylol melamine with respect to 100 parts by mass of a polyvinyl alcohol-based resin containing an acetoacetyl group (average degree of polymerization: 1200, degree of saponification: 98.5% by mole, degree of acetoacetylation: 5% by mole) was dissolved in pure water under a temperature condition of 30° C. to prepare an aqueous solution in which the concentration of solid contents was adjusted to 3.7% by mass.

### [Production of Viewing Angle Control System]

The support side of the optical film 1 produced above and the polarizer side of the polarizing plate 1 were bonded to each other with the following pressure sensitive adhesive N1 to produce a viewing angle control system 1.

### <Production of Pressure Sensitive Adhesive N1>

An acrylate-based polymer was prepared according to the following procedure.

95 parts by mass of butyl acrylate and 5 parts by mass of acrylic acid were polymerized by a solution polymerization method in a reaction container equipped with a cooling pipe, a nitrogen introduction pipe, a thermometer, and a stirrer, thereby obtaining an acrylate-based polymer (NA1) with an average molecular weight of 2,000,000 and a molecular weight distribution (Mw/Mn) of 3.0.

Next, an acrylate-based pressure sensitive adhesive was produced with the following composition using the obtained acrylate-based polymer (NA1). Each separate film which had been subjected to a surface treatment with a silicone-based release agent was coated with the composition using a die coater, dried in an environment of 90° C. for 1 minute, and irradiated with ultraviolet rays (UV) under the following conditions, thereby obtaining the following acrylate-based pressure sensitive adhesive N1 (pressure-sensitive adhesive layer). The composition and the film thickness of the acrylate-based pressure sensitive adhesive are shown below.

### <UV Irradiation Conditions>

Electrodeless lamp H bulb (Fusion Co., Ltd.)
Illuminance: 600 mW/cm², light dose: 150 mJ/cm²
The UV illuminance and the light dose were measured using “UVPF-36” (manufactured by Eye Graphics Co., Ltd.).

Acrylate-based pressure sensitive adhesive N1 (film thickness:
5 μm, storage elastic modulus: 2.6 MPa)

| | |
|---|---|
| Acrylate-based polymer (NA1) | 100 parts by mass |
| (A) Polyfunctional acrylate-based monomer | 11.1 parts by mass |
| shown below | |
| (B) Photopolymerization initiator shown below | 1.1 parts by mass |
| (C) Isocyanate-based crosslinking agent shown | 1.0 part by mass |
| below | |
| (D) Silane coupling agent shown below | 0.2 parts by mass |

(A) Polyfunctional acrylate-based monomer: tris(acryloyloxyethyl) isocyanurate, molecular weight=423, trifunctional type (manufactured by Toagosei Co., Ltd., trade name “ARONIX M-315”)

(B) Photopolymerization initiator: mixture of benzophenone and 1-hydroxycyclohexyl phenyl ketone at mass ratio of 1:1, “IRGACURE 500” manufactured by Ciba Specialty Chemicals Corp.

(C) Isocyanate-based crosslinking agent: trimethylolpropane-modified tolylene diisocyanate (“CORONATE L” manufactured by Nippon Polyurethane Industry Co., Ltd.)

(D) Silane coupling agent: 3-glycidoxypropyltrimethoxysilane (“KBM-403” manufactured by Shin-Etsu Chemical Co., Ltd.)

### Comparative Example 2

A viewing angle control system 2 of Comparative Example 2 was produced in the same manner as in Comparative Example 1, except that the film thickness of the coating layer P1 was changed to 6 μm.

### Example 1

The light absorption anisotropic layer P1 and the alignment layer/barrier layer 1 were further formed on the alignment layer/barrier layer 1 of the optical film 1 of Comparative Example 1 to produce an optical film 3.

Next, the polarizing plate 1 was bonded to the cellulose acylate film 1 surface side of the optical film 3 with the pressure sensitive adhesive N1 to produce a viewing angle control system 3.

### Example 2

A viewing angle control system 4 was produced in the same manner as in Example 1, except that the light absorption anisotropic layer P1 (two layers) of Example 1 was changed to a light absorption anisotropic layer P2 formed by the following method.

### [Formation of Light Absorption Anisotropic Layer P2]

The following composition P2 for forming a light absorption anisotropic layer was continuously applied onto the alignment layer/barrier layer using a wire bar to form a coating layer P2.

Next, the coating layer P2 was heated at 140° C. for 30 seconds, and the coating layer P2 was cooled to room temperature (23° C.).

Next, the coating layer P2 was heated at 80° C. for 60 seconds and cooled to room temperature again.

Thereafter, the coating layer P2 was irradiated with an LED lamp (central wavelength of 365 nm) for 2 seconds under an irradiation condition of an illuminance of 200 mW/cm², thereby producing a light absorption anisotropic layer P2 on the alignment layer 1.

A film thickness of the coating layer P2 was 3 μm, and an alignment degree of the light absorption anisotropic layer P2 at a wavelength of 550 nm was 0.96.

Formulation of composition P2 for forming light absorption
anisotropic layer

| | |
|---|---|
| Dichroic substance D-1 shown above | 0.60 parts by mass |
| Dichroic substance D-2 shown above | 0.225 parts by mass |
| Dichroic substance D-3 shown above | 0.945 parts by mass |
| High-molecular-weight liquid crystal | 3.06 parts by mass |
| compound P-1 shown above | |
| Polymerization initiator IRGACURE | 0.040 parts by mass |
| OXE-02 (manufactured by BASF SE) | |
| Compound E-1 shown above | 0.060 parts by mass |
| Compound E-2 shown above | 0.060 parts by mass |
| Surfactant F-1 shown above | 0.010 parts by mass |
| Surfactant F-2 shown above | 0.015 parts by mass |
| Cyclopentanone | 47.00 parts by mass |
| Tetrahydrofuran | 47.00 parts by mass |
| Benzyl alcohol | 1.00 part by mass |

### Example 3

The light absorption anisotropic layer P1 and the alignment layer/barrier layer 1 were further formed on the alignment layer/barrier layer 1 of the optical film 3 of Example 1, disposed on the air interface side, to produce an optical film 5.

Next, the polarizing plate 1 was bonded to the cellulose acylate film 1 surface side of the optical film 5 with the pressure sensitive adhesive N1 to produce a viewing angle control system 5.

### Example 4

The light absorption anisotropic layer P1 and the alignment layer/barrier layer 1 were further formed on the alignment layer/barrier layer 1 of the optical film 5 of Example 3, disposed on the air interface side, to produce an optical film 6.

Next, the polarizing plate 1 was bonded to the cellulose acylate film 1 surface side of the optical film 6 with the pressure sensitive adhesive N1 to produce a viewing angle control system 6.

### Example 5

A viewing angle control system 7 was produced in the same manner as in Example 3, except that the light absorption anisotropic layer P1 (three layers) of the optical film 3 of Example 3 was changed to a light absorption anisotropic layer P5 formed by the following method.

### [Formation of Light Absorption Anisotropic Layer P5]

The following composition P5 for forming a light absorption anisotropic layer was continuously applied onto the alignment layer/barrier layer using a wire bar to form a coating layer P5.

Next, the coating layer P5 was heated at 140° C. for 30 seconds, and the coating layer P5 was cooled to room temperature (23° C.).

Next, the coating layer P5 was heated at 60° C. for 60 seconds and cooled to room temperature again.

Thereafter, the coating layer P5 was irradiated with an LED lamp (central wavelength of 365 nm) for 2 seconds under an irradiation condition of an illuminance of 200 mW/cm², thereby producing a light absorption anisotropic layer P5 on the alignment layer 1.

A film thickness of the coating layer P5 was 3 μm, and an alignment degree of the light absorption anisotropic layer P5 at a wavelength of 550 nm was 0.90.

Formulation of composition P5 for forming light absorption
anisotropic layer

| | |
|---|---|
| Dichroic substance D-1 shown above | 0.40 parts by mass |
| Dichroic substance D-2 shown above | 0.15 parts by mass |
| Dichroic substance D-3 shown above | 0.63 parts by mass |
| High-molecular-weight liquid crystal | 3.65 parts by mass |
| compound P-1 shown above | |
| Polymerization initiator IRGACURE | 0.040 parts by mass |
| OXE-02 (manufactured by BASF SE) | |
| Compound E-1 shown above | 0.060 parts by mass |
| Compound E-2 shown above | 0.060 parts by mass |
| Surfactant F-1 shown above | 0.010 parts by mass |
| Surfactant F-2 shown above | 0.015 parts by mass |
| Cyclopentanone | 47.00 parts by mass |
| Tetrahydrofuran | 47.00 parts by mass |
| Benzyl alcohol | 1.00 part by mass |

### Comparative Example 3

A viewing angle control system 8 was produced by the same method as in Example 1 described in paragraphs [0137] to [0140] of JP2008-165201A.

### Comparative Example 4

A viewing angle control system 9 was produced by the same method as in Example 1 described in paragraphs [0110] to [0125] of WO2019/054099A.

With the viewing angle control systems produced in Examples 1 to 5 and Comparative Examples 1 to 4, the thickness and the alignment degree of each light absorption anisotropic layer, the retardation value of the alignment layer/barrier layer, the total thickness of the light absorption anisotropic layers, the dichroic substance-converted total film thickness, the alignment degree, and evaluation results described below are shown in Table 1 below.

### EVALUATION

The viewing angle control systems produced in Examples 1 to 5 and Comparative Examples 1 to 4 were placed on a backlight of a D65 light source, and the transmittance was measured by setting a normal direction of the viewing angle control film to a polar angle of 0°, and changing the polar angle from 0° to 880 at intervals of 10 and the azimuthal angle from 0° to 3590 at intervals of 1°. The transmittance was calculated from the brightness of the D65 light source in a state of not being provided with the viewing angle control film being 100% and the brightness in a state of being provided with the viewing angle control system.

In a plane of the viewing angle control film, a value of the azimuthal angle having the lowest transmittance at the polar angle of 25° was defined as an oblique 25-degree transmittance in the light shielding direction.

In addition, the transmittance of a total of 25 points, 5 points at intervals of 10 mm in the width direction and 5 points at intervals of 10 mm in the longitudinal direction, was measured, and the difference between the maximum value and the minimum value was defined as transmittance variation.

In addition, a tint (presence or absence of coloration) of the transmitted light at an oblique 25 degrees in the light shielding direction was visually observed.

TABLE 1

| | | | | | | Comparative | Comparative | Comparative | Comparative |
|---|---|---|---|---|---|---|---|---|---|
| | Example 1 | Example 2 | Example 3 | Example 4 | Example 5 | Example 1 | Example 2 | Example 3 | Example 4 |
| | viewing angle | viewing angle | viewing angle | viewing angle | viewing angle | viewing angle | viewing angle | viewing angle | viewing angle |
| | control system 3 | control system 4 | control system 5 | control system 6 | control system 7 | control system 1 | control system 2 | control system 8 | control system 9 |
| Layer configuration | | | | | | | | | Light absorption |
| | | | | | | | | | anisotropic layer |
| | | | | | | | | | thickness: 2 μm, |
| | | | | | | | | | alignment degree: 0.96 |
| | | | | Alignment | | | | | Alignment layer |
| | | | | layer/barrier layer | | | | | Re = 1 nm, |
| | | | | Re = 1 nm, | | | | | Rth = 1 nm |
| | | | | Rth = 1 nm | | | | | |
| | | | | Light absorption | | | | | Support |
| | | | | anisotropic layer | | | | | |
| | | | | thickness: 3 μm, | | | | | |
| | | | | alignment | | | | | |
| | | | | degree: 0.96 | | | | | |
| | | | Alignment | Alignment | Alignment | | | | Pressure-sensitive |
| | | | layer/barrier layer | layer/barrier layer | layer/barrier layer | | | | adhesive layer |
| | | | Re = 1 nm, | Re = 1 nm, | Re = 1 nm, | | | | |
| | | | Rth = 1 nm | Rth = 1 nm | Rth = 1 nm | | | | |
| | | | Light absorption | Light absorption | Light absorption | | | Light absorption | Second retardation |
| | | | anisotropic layer | anisotropic layer | anisotropic layer | | | anisotropic layer | layer |
| | | | thickness: 3 μm, | thickness: 3 μm, | thickness: 3 μm, | | | thickness: 2.5 μm | Re = 135 nm, |
| | | | alignment | alignment | alignment | | | | Rth = 68 nm |
| | | | degree: 0.96 | degree: 0.96 | degree: 0.90 | | | | |
| | Alignment | Alignment | Alignment | Alignment | Alignment | | | Alignment layer | Pressure-sensitive |
| | layer/barrier layer | layer/barrier layer | layer/barrier layer | layer/barrier layer | layer/barrier layer | | | Re = 1 nm, | adhesive layer |
| | Re = 1 nm, | Re = 1 nm, | Re = 1 nm, | Re = 1 nm, | Re = 1 nm, | | | Rth = 1 nm | |
| | Rth = 1 nm | Rth = 1 nm | Rth = 1 nm | Rth = 1 nm | Rth = 1 nm | | | | |
| | Light absorption | Light absorption | Light absorption | Light absorption | Light absorption | | | Retardantion layer | First retardation layer |
| | anisotropic layer | anisotropic layer | anisotropic layer | anisotropic layer | anisotropic layer | | | Re = 275 nm | Re = 127 nm, tilt angle: |
| | thickness: 3 μm, | thickness: 3 μm, | thickness: 3 μm, | thickness: 3 μm, | thickness: 3 μm, | | | | 45° |
| | alignment | alignment | alignment | alignment | alignment | | | | |
| | degree: 0.96 | degree: 0.96 | degree: 0.96 | degree: 0.96 | degree: 0.90 | | | | |
| | Alignment | Alignment | Alignment | Alignment | Alignment | Alignment | Alignment | Alignment layer | Alignment layer |
| | layer/barrier layer | layer/barrier layer | layer/barrier layer | layer/barrier layer | layer/barrier layer | layer/barrier layer | layer/barrier layer | Re = 1 nm, | |
| | Re = 1 nm, | Re = 1 nm, | Re = 1 nm, | Re = 1 nm, | Re = 1 nm, | Re = 1 nm, | Re = 1 nm, | Rth = 1 nm | |
| | Rth = 1 nm | Rth = 1 nm | Rth = 1 nm | Rth = 1 nm | Rth = 1 nm | Rth = 1 nm | Rth = 1 nm | | |
| | Light absorption | Light absorption | Light absorption | Light absorption | Light absorption | Light absorption | Light absorption | Light absorption | Glass substrate |
| | anisotropic layer | anisotropic layer | anisotropic layer | anisotropic layer | anisotropic layer | anisotropic layer | anisotropic layer | anisotropic layer | |
| | thickness: 3 μm, | thickness: 3 μm, | thickness: 3 μm, | thickness: 3 μm, | thickness: 3 μm, | thickness: 3 μm, | thickness: 3 μm, | thickness: 2.5 μm | |
| | alignment | alignment | alignment | alignment | alignment | alignment | alignment | | |
| | degree: 0.96 | degree: 0.96 | degree: 0.96 | degree: 0.96 | degree: 0.90 | degree: 0.96 | degree: 0.6 | | |
| | Alignment | Alignment | Alignment | Alignment | Alignment | Alignment | Alignment | | Pressure-sensitive |
| | layer/barrier layer | layer/barrier layer | layer/barrier layer | layer/barrier layer | layer/barrier layer | layer/barrier layer | layer/barrier layer | | adhesive layer |
| | Re = 1 nm, | Re = 1 nm, | Re = 1 nm, | Re = 1 nm, | Re = 1 nm, | Re = 1 nm, | Re = 1 nm, | | |
| | Rth = 1 nm | Rth = 1 nm | Rth = 1 nm | Rth = 1 nm | Rth = 1 nm | Rth = 1 nm | Rth = 1 nm | | |
| | Support | Support | Support | Support | Support | Support | Support | | Light absorption |
| | | | | | | | | | anisotropic layer |
| | | | | | | | | | thickness: 2 μm, |
| | | | | | | | | | alignment degree: 0.96 |
| | Pressure-sensitive | Pressure-sensitive | Pressure-sensitive | Pressure-sensitive | Pressure-sensitive | Pressure-sensitive | Pressure-sensitive | | Alignment layer |
| | adhesive layer | adhesive layer | adhesive layer | adhesive layer | adhesive layer | adhesive layer | adhesive layer | | Re = 1 nm, |
| | | | | | | | | | Rth = 1 nm |
| | Polarizer | Polarizer | Polarizer | Polarizer | Polarizer | Polarizer | Polarizer | | Support |
| Total thickness of | 6 | 6 | 9 | 12 | 9 | 3 | 6 | 5 | 4 |
| light absorption | | | | | | | | | |
| anisotropic | | | | | | | | | |
| layers (μm) | | | | | | | | | |
| Dichroic substance- | 1.42 | 2.13 | 2.13 | 2.84 | 2.13 | 0.71 | 1.42 | 0.18 | 1.16 |
| converted total film | | | | | | | | | |
| thickness (μm) | | | | | | | | | |
| Alignment degree | 0.96 | 0.96 | 0.96 | 0.96 | 0.90 | 0.96 | 0.7 | 0.7 | 0.96 |
| Oblique 25-degree | 1.8 | 1 | 1 | 0.6 | 1.5 | 3.6 | 10 | 7 | 2 |
| transmittance in light | | | | | | | | | |
| shielding | | | | | | | | | |
| direction (%) | | | | | | | | | |
| Oblique 25-degree | 0.4 | 0.2 | 0.2 | 0.1 | 0.3 | 0.8 | 4 | 2 | 0.5 |
| transmittance | | | | | | | | | |
| variation in light | | | | | | | | | |
| shielding | | | | | | | | | |
| direction (%) | | | | | | | | | |
| Oblique 25-degree | Not colored | Not colored | Not colored | Not colored | Not colored | Not colored | Not colored | Colored | Colored |
| tint in light shielding | | | | | | | | | |
| direction | | | | | | | | | |

From the results shown in Table 1, it was found that, in a case where the total thickness of the light absorption anisotropic layers was less than 4.0 pin and the dichroic substance-converted total film thickness was less than 1.10 μm, the oblique 25-degree transmittance in the light shielding direction was increased (Comparative Example 1).

In addition, it was found that, in a case where the light absorption anisotropic layer having a thickness of 3.0 μm or less was not provided, the oblique 25-degree transmittance in the light shielding direction was increased (Comparative Example 2).

In addition, it was found that, in a case where the dichroic substance-converted total film thickness was less than 1.10 μm and the retardation layer was provided between the plurality of light absorption anisotropic layers, the oblique 25-degree transmittance in the light shielding direction was increased, and the colored light leakage was observed (Comparative Example 3).

In addition, it was found that, in a case where the retardation layer was provided between the plurality of light absorption anisotropic layers, the colored light leakage was observed (Comparative Example 4).

On the other hand, it was found that, by using the optical film including the plurality of light absorption anisotropic layers having an absorption axis parallel to a thickness direction, in which the thickness of each layer was 3.0 μm or less, the total thickness was 4.0 μm or more, and the dichroic substance-converted total film thickness was 1.10 μm or more, and an interlayer satisfying a predetermined retardation, in a case of being viewed from a predetermined azimuthal angle at an angle inclined by 250 from the normal direction of the laminate in which the polarizer having an absorption axis in an in-plane direction was laminated, the transmittance was lowered and the coloration of the light leakage was suppressed (Examples 1 to 4).

In addition, from the comparison between Example 3 and Example 5, it was found that, in a case where the alignment degrees of the plurality of light absorption anisotropic layers were all 0.93 or more, the transmittance was further lowered in a case of being viewed from a predetermined azimuthal angle at an angle inclined by 25° from the normal direction of the laminate in which the polarizer having an absorption axis in an in-plane direction was laminated.

### EXPLANATION OF REFERENCES

10: optical filter
12: polarizer
14: laminate
80: head-mounted display
82: light guide plate
90: incidence diffraction element
92: emission diffraction element
94: intermediate diffraction element
I₀: front external light
I₁: video light
Iₛ: oblique external light

What is claimed is:

1. An optical film comprising:
a plurality of light absorption anisotropic layers containing a dichroic substance; and
at least one interlayer disposed between the plurality of light absorption anisotropic layers,
wherein all of the plurality of light absorption anisotropic layers have an absorption axis parallel to a thickness direction,
thicknesses of the plurality of light absorption anisotropic layers are all 3.0 μm or less,
a total thickness of the plurality of light absorption anisotropic layers is 4.0 μm or more,
with regard to the plurality of light absorption anisotropic layers, a total value calculated by multiplying a ratio of a content of the dichroic substance with respect to a mass of the light absorption anisotropic layer by the thickness of the light absorption anisotropic layer is 1.10 μm or more, and
the interlayer is a layer in which an in-plane retardation at a wavelength of 550 nm is 25 nm or less and an absolute value of a thickness-direction retardation at the wavelength of 550 nm is 25 nm or less.

2. The optical film according to claim 1,
wherein alignment degrees of the plurality of light absorption anisotropic layers are all 0.93 or more.

3. The optical film according to claim 1,
wherein the interlayer is an alignment layer or a barrier layer.

4. A viewing angle control system comprising:
the optical film according to claim 1; and
a polarizer having an absorption axis in an in-plane direction.

5. An image display device comprising:
a display element; and
the viewing angle control system according to claim 4,
wherein the viewing angle control system is disposed on at least one main surface of the display element.

6. The image display device according to claim 5,
wherein the plurality of light absorption anisotropic layers included in the viewing angle control system are arranged on a viewing side with respect to the polarizer included in the viewing angle control system.

7. The optical film according to claim 2,
wherein the interlayer is an alignment layer or a barrier layer.

8. A viewing angle control system comprising:
the optical film according to claim 2; and
a polarizer having an absorption axis in an in-plane direction.

9. A viewing angle control system comprising:
the optical film according to claim 3; and
a polarizer having an absorption axis in an in-plane direction.
